(19) United States
(12) Patent Application Publication
(10) Pub. No.: US 2024/0264113 A1
(43) Pub. Date: Aug. 8, 2024

(54) DEVICE AND METHODS FOR CHARACTERIZATION OF SEMICONDUCTOR FILMS

(71) Applicant: Arizona Board of Regents on Behalf of the University of Arizona, Tucson, AZ (US)

(72) Inventors: Michel De Keersmaecker, Tucson, AZ (US); Erin L. Ratcliff, Tucson, AZ (US); Neal R. Armstrong, Tucson, AZ (US)

(21) Appl. No.: 18/567,985

(22) PCT Filed: Jun. 10, 2022
(86) PCT No.: PCT/US22/33102

§ 371 Date: Dec. 7, 2023

Related U.S. Application Data
(60) Provisional application No. 63/209,339, filed on Jun. 10, 2021.
(60) Provisional application No. 63/320,698, filed on Mar. 17, 2022.

(51) Int. Cl. G01N 27/333; G01N 27/30; G01N 27/406; H01L 21/67

(52) U.S. Cl. CPC G01N 27/3335; G01N 27/301; G01N 27/406; H01L 21/67288

(57) ABSTRACT

An apparatus for characterizing a substructure of a semiconductor device includes a potentiostat; a counter electrode electrically connected to the potentiostat; a solid electrolyte attached to a surface of the counter electrode; a reference electrode embedded within at least a portion of the solid electrolyte and electrically connected to the potentiostat; and a probe electrically connected to the potentiostat. The solid electrolyte includes a solid porous material and an ionic liquid disposed within the solid porous material. A method of characterizing a substructure of a semiconductor device includes contacting at least a portion of a surface of the substructure of the semiconductor device with a second surface of a solid electrolyte.

### CROSS REFERENCE TO RELATED APPLICATIONS

This present application claims priority benefit to U.S. Provisional Patent Application No. 63/209,339, filed on Jun. 10, 2021, and to U.S. Provisional Patent Application No. 63/320,698, filed on Mar. 17, 2022, the content of each of which is incorporated herein by reference.

### STATEMENT REGARDING FEDERALLY FUNDED RESEARCH

This invention was made with government support under Grant No. N00014-20-1-2440 awarded by the Office of Naval Research. The government has certain rights in the invention.

### TECHNICAL FIELD

Embodiments of the present invention relate to systems, devices, and methods for analyzing an electronic material, a semiconductor device, and/or a substructure of a semiconductor device.

### BACKGROUND

Interest in metal halide perovskites has increased significantly recently due at least in part to their enormous potential for use in various electronic devices, such as, optoelectronic devices including solar cells, light-emitting diodes (LEDs), detectors etc. Metal halide perovskites have unique combinations of properties, including high absorption coefficient, long charge-carrier diffusion lengths, and high defect tolerance. Due at least in part to these properties, there has been a tremendous development in perovskite-based solar cells and light-emitting diodes (LEDs). However, it has been discovered that interfaces and defects in metal halide perovskites have a critical influence on the properties and operational stability of their use in optoelectronic devices.

Interface and defect engineering can play a role in controlling the behavior of the charge carriers and growing high quality, substantially defect-free perovskite crystals. While there have been developments in methods for analyzing various defects in metal halide perovskites, most of the conventional methods show low sensitivity. Conventional electrochemical analysis methods have shown lower detection limits, but require a solvent. Unfortunately, metal halide perovskites are soluble in most solvents, and therefore solvent based electrochemical analysis may be difficult.

Some of the key shortcomings in conventional manufacturing processes of electronic devices or semiconductor films include, but are not limited to, in situ characterization (observe processes under conditions that replicate real-world and real-time conditions) and operando characterization (direct visualization and characterization of processes in real time under applied electric fields and flux conditions). Such methods that allow in situ and/or operando characterization of electronic devices and/or semiconductor materials during manufacturing and/or operation, respectively, can promote stronger ties between basic and applied research, and enhance rates of commercialization of viable technologies based on these optoelectronic materials. Besides knowledge, these techniques may be essential analytical tools that can follow chemical reactions, physical processes, microstructural changes, and interfacial phenomena in real-world conditions.

For the high-throughput production of (opto)electronic devices (ex. solar cells), state-of-the-art multi-model characterization capabilities, as well as novel inline sensors, are needed to follow (electro)chemical (e.g., intermolecular interactions, interfacial processes, defects, etc.) and/or physical (drying, crystal formation, surface tension, etc.) processes during the roll-to-roll, blade coating, slot-die, ink-jet, and/or various forms of spray printing, manufacturing operation across length and time scales, or to understand device-transport layer interactions.

To date, progress in operando and in situ characterization capabilities for the inspection of manufacturing lines for optoelectronic devices such as solar cells based on organic semiconductors or organic-inorganic hybrid perovskites has been demonstrated using optical approaches, such as ellipsometry, absorbance/reflection/transmission, and/or (time-resolved) photoluminescence ((TR)PL) testing or incorporating processing with X-ray scattering/diffraction techniques. These methods identify material coating heterogeneities, and can identify impurities or defects, and obtained data can be used to optimize existing manufacturing processes by characterizing the individual layers or multilayers (e.g., photoactive layer in solar cells), which helps set blade or slot-die coating parameters such as blade speed and height or pumping rate and coating speed. However, many questions remain unanswered using these approaches. For example, what are the interfacial and/or surface interactions between layers, how does one evaluate (electro)chemical processes, physical and structural changes under real-world conditions, what is the defect concentration, and does this defect concentration depend on the underlying layers (ex. transport layer), and are the defects mobile under operating conditions, when the active layer is taken away from equilibrium conditions?

Accordingly, there remains a need for a device and a method that allow more detailed operando and/or in situ characterization of electronic devices and/or semiconductors during their manufacturing processes and for a solvent-free electrochemical method of analyzing metal halide perovskites. Complementing these approaches is the ability to assess materials properties during stress testing including but not limited to light, temperature, humidity, and/or applied bias (ex. voltage).

### SUMMARY

Metal halide perovskites have emerged as useful materials in low-dimensional semiconductors of great significance in many fields such as photovoltaics, photonics, and optoelectronics. Extensive efforts on the controlled synthesis of metal halide perovskite nanostructures have been made towards potential device applications. Unfortunately, it is believed that defects form easily in metal halide perovskites due at least in part to their soft, polarizable, and dynamically disordered lattices, and because the ionic bond between the halide anion and divalent cation is not strong. These defects can seriously affect the properties and operational stability of metal-halide-perovskite optoelectronic devices. For example, defects in the perovskite solar cells can result in a major loss of efficiency and long-term stability. The defects also cause significant luminescence quenching in perovskite-based LEDs.

Some embodiments of the invention provide methods for determining concentrations and energetics of reactive defects and provide approaches to substantially reducing the number of defects in metal halide perovskites. In particular, methods, according to some embodiments of the invention, utilize solid electrolytes for electrochemical analysis of metal halide perovskites.

One particular aspect of an embodiment of the invention provides a method for determining a characteristic of an electronic material. In some embodiments, the electronic material includes a metal halide perovskite, an organic semiconductor, a quantum dot thin film, a nanomaterial film, a semiconductor material, a material blend or a device stack. The method includes:
a) conducting an electrochemical experiment of a composition comprising:
   (i) a working electrode (“WE”) comprising the electronic material under study:
   (ii) a solid electrolyte (“SE”) comprising a combination of polymer and ionic liquid that are stable when interfaced to the perovskite or comparable semiconductor film, including within a reference electrode (“RE”), wherein the solid electrolyte/reference electrode combination is removably attached to the working electrode; and
   (iii)) a counter electrode (“CE”) operatively connected to the working electrode, and
b) analyzing the result of the electrochemical experiment to determine a characteristic of the electronic material.

In some embodiments, electrochemical experiment or analysis can be combined with a spectroscopic analysis or experiment. Exemplary spectroscopic analysis that can be combined with electrochemical analysis includes UV-Vis(-NIR) spectroscopy, Fourier Transform Infrared spectroscopy (FTIR), X-ray photoelectron spectroscopy (“XPS”), UV photoelectron spectroscopy (UPS), photoluminescence spectroscopy (PL), photoemission spectroscopy (PES), Raman spectroscopy, wide angle X-ray scattering (WAXS), deep-level transient spectroscopy (DLTS), or a combination thereof.

Yet in other embodiments, the method can be used to determine various characteristics of the electronic material. Exemplary characteristics that can be determined include, but are not limited to, chemical speciation and quantification of a defect, stability, surface composition, band gap, physical structure, electroactivity, band bending, migration/diffusion processes, charging effects, as well as other useful characteristics known to one skilled in the art.

Still in other embodiments, the solid electrolyte includes a polymer, an ionic liquid, and optionally a redox probe compound. Exemplary polymers that can be used in solid electrolyte include, but are not limited to, a chemically inert polymer or copolymer with low oxygen transport, high solubility, low molecular weight, and/or high dielectric constant (or high-K). Particular examples of suitable polymers include poly(vinylidene fluoride) (PVDF), hexafluoropropylene (“HFP”), tetrafluoroethylene (TFE), poly(ethyleneoxide) (PEO), poly (acrylonitrile) (PAN), poly (methylmethacrylate) (PMMA), nafion, polyacrylic acid (PAA), polyallylamine hydrochloride (PAH), or a combination thereof, as well as other polymers known to one skilled in the art.

Ionic liquids are non-volatile and non-flammable. In addition, ionic liquids have a wide electrochemical stability window and high ionic conductivity. These properties make ionic liquids (e.g., salts with melting points below 100° C., typically below 50° C., and often below: 25° C.) useful for a wide variety of applications, including electrolytes. Ionic liquids are well known to one skilled in the art. Generally, ionic liquids exist as a combination of an organic cation, such as cationic ammonium or imidazolium, in combination with an anion such as BF₄⁻, PF₆⁻ or TFSI⁻. Exemplary ionic liquids that can be used in solid electrolytes include, but are not limited to, 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF₆]”), 1-Ethyl-3-methylimidazolium tetrafluoroborate (“[EMIM][BF₄]”) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof, as well as other ionic liquids known to one skilled in the art. It should be appreciated that the scope of the invention is not limited to these particular ionic liquids. In fact, any ionic liquid known to one skilled in the art can be used in the invention.

In further embodiments, the solid electrolyte includes a redox probe compound. Exemplary redox probe compounds that can be used in solid electrolytes of the invention include, but are not limited to, ferrocene, other metallocenes, benzoquinones, (hydro)quinones, phthalocyanines, ruthenium(II)/(III)complexes, tetracyanoquinones, and other redox probes known to one skilled in the art.

Still yet in other embodiments, the electronic material is a thin film. In one particular embodiment, the electronic material includes a thin film of printable metal halide perovskite.

Another aspect of the invention provides a method for probing defects in an electronic material. In one particular embodiment, the electronic material includes a metal halide perovskite. Methods of the invention for probing defects include:
(i) attaching a solid electrolyte to a surface of the metal halide perovskite to produce an electronic component:
(ii) subjecting the electronic component to an electrochemical process; and
(iii) removing the solid electrolyte from the electronic component.

Still in other aspects of embodiments of the invention provides an electronic device comprising an electronic material that has been subject to the method of reducing defects as described herein. In some embodiments, the electronic device includes a solar cell, a light-emitting diode (“LED”), or an X-ray detector, a photodiode, a laser, a transistor, and/or a battery.

Some embodiments of the invention provide a solid-state-based electrochemical device that can analyze and measure semiconductor film quality in device manufacturing. In some embodiments, the device and method can be used in combination with X-ray and/or photoluminescence (“PL”) characterization, which can include variables in space and time. In an embodiment, the device can replicate real-time operating conditions, study chemical processes under load (applied current or voltage), measure the influence of external environmental factors (such as H₂O and O₂) and evaluate photoactive layers or photoactive/transport layer device stacks off-line. This device can also act as a reliable, operando, in inline sensor for quality control.

In some embodiments, the device allows one skilled in the art to study microstructural responses and changes at the local scale with nanometer spatial resolution, e.g., resolution of about 500 nm or less, typically about 250 nm or less, often about 100 nm or less, more often about 50 nm or less, and most often about 25 nm or less under process conditions by using pipette- or needle-based electrochemical cells.

Still in other embodiments, the device allows one skilled in the art to study microstructural responses and changes at the local scale ranging from within microseconds (i.e., less than about 1 millisecond, typically within about 800 μsec or less, often within about 500 μsec or less, more often within about 250 μsec or less, still more often within 100 μsec or less, and most often within 50 μsec or less) to the amount of time electric field is applied for analysis. When methods of the invention are combined with other analytical techniques, a much longer period of change can be observed. For example, X-ray scattering can easily allow analysis of semiconductor films ranging from seconds to minutes, hours and even days: and time-resolved PL can analyze changes in semiconductor films ranging from picoseconds or milliseconds (i.e. carrier lifetimes) to minutes, hours and even days.

One particular aspect of an embodiment of the invention provides an electrochemical probe (10) for analyzing a semiconductor active layer. The electrochemical probe (10) typically includes a base unit (100), a counter electrode layer (200), and a solid electrolyte layer (300), and a probe (500) attached to the base unit (100).

The counter electrode layer (200) has a top surface and a bottom surface, where the top surface of the counter electrode layer (200) is attached to the base unit (100) and the counter electrode layer (200) includes a counter electrode (“CE”) electrical connector (204) that is adapted to electrically connect the counter electrode (200) to a potentiostat (600).

The solid electrolyte layer (300) includes a top surface and a bottom surface, where the top surface of the solid electrolyte layer (300) is attached to the bottom surface of the counter electrode layer (200). The solid electrolyte layer (300) includes an embedded reference electrode (400) that includes a reference electrode (“RE”) electrical connector (404) that is adapted to electrically connect the RE (400) to the potentiostat (600).

The probe (500) is attached to the base unit (100) and includes a needle-, push-pin-or a pipette-tip (504). The probe (500) further includes a working electrode (“WE”) electrical connector (508) that is adapted to electrically connect the probe (500) to the potentiostat (600).

When the solid electrolyte layer (300) of the electrochemical probe (10) contacts a semiconductor active layer (700), the needle tip (504) penetrates the semiconductor layer (704) and contacts a conductive substrate (708) thereby forming a closed electrical circuit. This completes the electrical circuit thereby allowing one to analyze the semiconductor active layer (700) electrochemically.

In some embodiments, the solid electrolyte layer (300) further includes a conductive salt. In some instances, the conductive salt is an ionic liquid. The ionic liquid can be any non-volatile ionic liquid. Typically, the ionic liquid includes a large nonvolatile organic cation and a corresponding nonvolatile anion. Exemplary ionic liquids that can be used include, but not limited to, 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF₆]”), 1-Ethyl-3-methylimidazolium tetrafluoroborate (“[EMIM][BF₄]”) 1-hexyl-3-methylimidazolium bis(trifluoromethanesulfonyl)-imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

In other embodiments, the solid electrolyte layer (300) further includes a molecular redox probe. Useful molecular redox probes are molecules that undergo one-electron oxidation or reduction to create stable products that can be electrochemically quantified. Exemplary molecular redox probes that can be used in the invention include, but are not limited to, metallocenes (e.g., ferrocene), benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from the semiconductor active layer, in the dark or under illumination, which can be subsequently quantified using simple electrochemical approaches, and any combination thereof.

Yet in other embodiments, the solid electrolyte layer (300) also includes a polymer. Typical polymers used in the solid electrolyte layer (300) is (i) a chemically inert polymer or (ii) copolymer of a chemically inert polymer with low oxygen transport, high solubility, low molecular weight, high dielectric constant (or high-K), or a combination thereof. Particular examples of polymers that can be used in the invention include, but are not limited to, poly (vinylidene fluoride) (PVDF), hexafluoropropylene (“HFP”), tetrafluoroethylene (TFE), poly(ethylene oxide) (PEO), poly(acrylonitrile) (PAN), poly (methyl methacrylate) (PMMA), and a combination thereof.

In further embodiments, the counter electrode (200) includes gold, indium tin oxide (ITO), glassy carbon, platinum, or any highly conductive metal or material (e.g., having a conductivity of at least about 0.001 S/cm, typically at least about 10 S/cm, often at least about 100 S/cm, more often at least from about 4000 S/cm to about 5,000 S/cm, and most often at least about 4000 S/cm), metal oxide or polymer conductor, or a combination thereof.

Still in other embodiments, the reference electrode (400) includes any metal conductor or inorganic or organic semiconductor in electrochemical equilibrium with a salt thin film, which readily equilibrates electronically with the solid electrolyte, and creates an electrochemical potential which is stable for hours or longer, when only low currents are allowed to flow across the interface between the reference electrode and the solid electrolyte—a condition easily achieved with modern electrochemical instrumentation. Typical reference electrodes that might be used in this application include silver (wire or thin film) coated with silver chloride (Ag/AgCl). It should be appreciated, however, that any metal, semiconductor or polymeric conductor (thin film, wire, nanometer-scale probe, etc.), in contact with a salt and/or redox couple in the solid electrolyte, which equilibrates readily to provide a stable reference potential, can be used as a reference electrode in the invention. Other examples of suitable reference electrode materials include, but are not limited to, platinum, silver, an inert metallic or polymeric conductor. The term “inert” when referring to a reference electrode means nonvolatile, non-dissolving, and nonreactive.

Another aspect of an embodiment of the invention provides a method for analyzing a semiconductor active layer (700) using the device disclosed herein. The method includes contacting an electrical probe (10) to a semiconductor surface or a surface of a semiconductor layer (704) in contact with a conductive substrate (700). The step of contacting the electrical probe (10) to the semiconductor (704) surface results in a needle tip (504) penetrating the semiconductor layer without creating an electrical short, (704) and contacting the conductive substrate (708) thereby forming a closed electrical circuit.

Once the closed electric circuit is formed, current flow is determined by the potential applied using a potentiostat (600), or other suitable power supply, and allows the analysis of at least one characteristic of the semiconductor active layer (700). In general, any characteristics based on the dependence of current versus applied potential, or the dependence of potential versus applied current, known to one skilled in the art, can be determined using the method of the invention. Exemplary characteristics that can be determined using the method include, but are not limited to, surface composition and deviations from expected stoichiometries, defect energetics, defect concentrations, band edge energies (conduction and valence band energy), band gap, migration/diffusion processes of reactive species, current or voltage excursions due to displacement of ions or reactions at interfaces (charging effects), degradation mechanisms, and changes in physical structure at nanometer to micron length scales that correlate with these characteristics, and a combination thereof.

In some embodiments, the semiconductor material (704) includes inorganic semiconductors such as Si, Ge, CdS, CdSe, CdTe, GaAs, GaₓAl_{y}As_{z}N_{zz} compositions, and multilayer stacks of these semiconductors, metal oxide semiconductors such as TiO₂, ZnO, SnO₂, and NiOₓ, conducting and semiconducting polymers such as substituted polythiophenes, thin film nanocrystalline materials (e.g., based on quantum dots or semiconductor nanorods, nanoplatelets, etc.), blends of semiconductor nanomaterials based on combinations of compound semiconductors (e.g., CdTe, CdSe, CdS, PbS, PbSe) and semiconducting oxides, donor/acceptor blends of semiconducting polymers and/or molecules such as PM6 (Poly[[4,8-bis[5-(2-ethylhexyl)-4-fluoro-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]-2,5-thiophenediyl]) blended with either a polymer PNDI-2T (Poly {[N,N′-bis(2-octyldodecyl)-naphthalene-1,4,5,8-bis(dicarboximide)-2,6-diyl]-alt-5,5′-(2,2′-bithiophene)}) or a non-fullerene acceptor-donor-acceptor type small molecule acceptor such as Y6 (2,2′-((2Z,2′Z)-((12,13-bis(2-ethylhexyl)-3,9-diundecyl-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile) or a hybrid organic-inorganic metal halide perovskite. Hybrid organic-inorganic metal halide perovskites are well known to one skilled in the art. See, for example, doi.org/10.1080/21663831.2018.1500951, (Zhou et al., in “Organic-inorganic metal halide hybrids beyond perovskites,” Mater. Res. Lett., 2018, 6(10), pp. 552-569): and doi.org/10.1016/B978-0-12-811479-7.00011-7 (Bhandari et al. A Comprehensive Guide to Solar Energy Systems, Academic Press, 2018, pp. 233-254), which are incorporated herein by reference in their entirety.

Still in other embodiments, the hybrid organic-inorganic metal halide perovskite includes a combination of organic and inorganic cations, including single (e.g., CsPbBr₃, MAPbI₃, MAPbI₃₋ₓClₓ, FAPbI₃), double (e.g., MA_{0.3}FA_{0.7}Pb_{0.5}Sn_{0.5}I₃, FA_{0.85}PEA_{0.15}SnI₃) and triple cation (e.g., Cs_{0.05}(FA_{0.92}MA_{0.08})_{0.95} Pb(I_{0.92}Br_{0.08})₃ or CsFAMA) perovskites, with additives (DMSO, formic acid, amines, [EMIM][TFSI], LiTFSI and other ionic liquids) designed to control microstructure and enhance performance and stability, and to control crystalline polytypes, including conversion from three-dimensional to two-dimensional motives, or a combination thereof in the form of material blends or multilayered stacks.

Yet in other embodiments, the conductive substrate includes indium tin oxide (ITO), fluorine- or antimony-doped tin oxide (FTO or ATO), ZnO and its compound oxides such as ZnITO (ZITO), or a combination thereof.

In further embodiments, the step of determining current flow as a function of potential includes linear sweep voltammetry, differential pulse voltammetry, an electrochemical technique which uses transient voltage or current pulse on micro-second to second time scales to enhance contrast between detection of Faradaic and non-Faradaic (ion displacement) electrochemical events, including chronoamperometry and impedance spectroscopies, or a combination thereof.

Still in further embodiments, an oxidation step during the step of determining current flow as a function of potential includes linear sweep voltammetry.

In other embodiments, a reduction step during the step of determining current flow as a function of potential includes differential pulse voltammetry or related techniques which rely upon voltage or current pulses to cause transient electrochemical events.

It should be appreciated: however, linear sweep voltammetry and differential pulse voltammetry can be used in either the oxidation step or the reduction step. The only requirement is that one is used during one step and the other is used during the opposite step. Other applied potential or applied current transients can also be used, monitoring the resultant current or potential transient responses, to enhance contrast between Faradaic and non-Faradaic electrochemical responses, which ultimately enables detection of important reactive defects in the active layer at extremely low concentrations.

Yet still in other embodiments, the semiconductor active layer is analyzed during a manufacturing process. Such a manufacturing process can include a roll-to-roll, blade coating or printing, manufacturing process.

Yet another aspect of the invention provides a method for analyzing a semiconductor active layer (700) using a device or a method disclosed herein. In general, the method includes measuring a current flow using a linear sweep voltammetry during one of a reduction or an oxidation step and measuring a current flow using a differential pulse voltammetry during an opposite or reverse step. In some embodiments, the semiconductor active layer (700) includes inorganic semiconductors such as Si, Ge, CdS, CdSe, CdTe, GaAs, GaₓAl_{y}As_{z}N_{zz} compositions, and multilayer stacks of these semiconductors, metal oxide semiconductors such as TiO₂, ZnO, SnO₂, and NiOₓ, conducting and semiconducting polymers such as substituted polythiophenes, thin film nanocrystalline materials (e.g., based on quantum dots or semiconductor nanorods, nanoplatelets, etc.), blends of semiconductor nanomaterials based on combinations of compound semiconductors (e.g., CdTe, CdSe, CdS, PbS, PbSe) and semiconducting oxides, donor/acceptor blends of semiconducting polymers and/or molecules such as PM6 (Poly[[4,8-bis[5-(2-ethylhexyl)-4-fluoro-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]-2,5-thiophenediyl]) blended with either a polymer PNDI-2T (Poly{[N,N′-bis(2-octyldodecyl)-naphthalene-1,4,5,8-bis(dicarboximide)-2,6-diyl]-alt-5,5′-(2,2′-bithiophene)}) or a non-fullerene acceptor-donor- acceptor type small molecule acceptor such as Y6 (2,2′-((2Z,2′Z)-((12,13-bis(2-ethylhexyl)-3,9-diundecyl-12,13-dihydro-[1,2,5]thiadiazolo[3,4-e]thieno[2″,3″:4′, 5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile) or a hybrid organic-inorganic metal halide perovskite. Still in another embodiment, the hybrid organic-inorganic metal halide perovskite includes a combination of organic and inorganic cations, including but not limited to, single (CsPbBr₃, MAPbI₃, MAPbI₃₋ₓClₓ, FAPbI₃), double (MA_{0.3}FA_{0.7}Pb_{0.5}Sn_{0.5}I₃, FA_{0.85}PEA_{0.15}SnI₃) and triple cation perovskites, with additives (DMSO, formic acid, amines, [EMIM][TFSI], LiTFSI and other ionic liquids) designed to control microstructure and enhance performance and stability, and to control crystalline polytypes, including conversion from three-dimensional to two-dimensional motives, or a combination thereof in the form of material blends or multilayered stacks.

### BRIEF DESCRIPTION OF THE DRAWINGS

Some aspect of various embodiments of the present invention will become more apparent upon consideration of the following description and the appended claims with reference to the accompanying drawings, all of which form a part of this specification. It is to be expressly understood, however, that the drawings are for the purpose of illustration and description only and are not intended as a definition of the limits of the invention.

FIG. 1 is a schematic illustration showing an apparatus for characterizing a substructure of a semiconductor device, according to an embodiment of the present invention.

FIG. 2 is a schematic illustration showing the use of an electrochemical probe of the invention as a in situ sensor in the evaluation of a semiconductor layer during a roll-to-roll manufacturing process, according to an embodiment of the present invention.

FIG. 3 is a schematic illustration of a method for analyzing characteristics of a metal halide perovskite, according to an embodiment of the present invention.

FIG. 4A is a schematic of the MAPbI₃ half-cell stack structure used for electrochemical characterization, according to an embodiment of the present invention.

FIG. 4B shows full conduction band analysis with ▪=A(730 nm) (versus the baseline absorbance A(820 nm)) and ▴=dA/dE in a potential range of −0.6 V to −0.9 V and −1.1 to −1.3 V with 0.1 increments and −0.9 to −1.1 V with 0.02 V increments, taken from in-situ spectroelectrochemical data for the bleaching of MAPbI₃ conduction band for the stack in FIG. 2A, without redox probe, in ambient conditions (inset), the red line being a Gaussian fit with a maximum at 3.71 eV±0.00(1) as a guide for the eye, according to an embodiment of the present invention.

FIG. 4C shows XRD spectra of MAPbI₃ films with and without a SE top layer: peak assignments for lattice spacings are indicated for MAPbI₃ (*), PbI₂ (#), and ITO (+), according to an embodiment of the present invention.

FIG. 4D is a high-resolution Pb 4f core level XPS spectra for a clean MAPbI₃ film, a MAPbI₃ film after solid electrolyte peel, after oxidation to 0.4 V and 0.8 V, according to an embodiment of the present invention.

FIG. 5A shows UV-vis spectra of PbI₂, highly and weakly defective MAPbI₃ films, according to an embodiment of the present invention.

FIG. 5B shows XRD spectra of PbI₂, highly and weakly defective MAPbI₃ films, according to an embodiment of the present invention.

FIG. 5C shows a graph of five consecutive CVs of a highly defective (red) and weakly defective (blue) MAPbI₃ film in contact with a solid electrolyte film without a redox probe in ambient conditions, the red curve being offset by 100 μA for clarity, according to an embodiment of the present invention.

FIG. 6A shows a schematic illustration of the MAPbI₃ half-cell stack structure with a 1 mM Fc/Fc⁺ redox probe in the solid electrolyte, according to an embodiment of the present invention.

FIG. 6B shows a scan rate dependent CVs from 0.005 to 0.5 V s⁻¹ of Au/solid electrolyte+1 mM Fc/Au stack structure, according to an embodiment of the present invention.

FIG. 6C shows CVs of MAPbI₃/solid electrolyte+1 mM Fc stack in FIG. 4A under ambient conditions at a scan rate of 0.05 V s⁻¹, according to an embodiment of the present invention.

FIG. 7A shows CVs as a function of anodic potential endpoints approaching and surpassing E_{VB,onset} (0.4 to 0.9 V), followed by a cathodic sweep in presence of 1 mM Fc at 0.05 V/s in ambient atmosphere, increasingly anodic sweeps yield higher oxidation currents, and on the return sweeps, reduction of “defect states” and reduction of Fc⁺ created on the positive sweeps, according to an embodiment of the present invention.

FIG. 7B shows the defect reduction process presented in FIG. 7A in more detail.

FIG. 7C shows charge (Q) integration following a Coulombic analysis as a function of E_{ox,end} from the data shown in FIG. 7A. The Faradaic processes are separated into (▾) total oxidative charge (Qₒₓ), (*) defect reduction charge (Q_{red,defects}), and (▪) Fc⁺ reduction charge (Q_{red,Fc/Fc+}): (+), according to an embodiment of the present invention.

FIG. 7D shows the expanded defect reduction region of FIG. 7C.

FIG. 7E shows an integration of the Faradaic oxidation and reduction peaks using cyclic voltammetry, the rest charge being considered non-Faradaic charging at the MAPbI₃/electrolyte interface, according to an embodiment of the present invention.

FIGS. 8A-8D show Pb 4f, I 3d, N Is and C Is high-resolution XPS core level spectra of an as-deposited MAPbI₃ film (FIG. 8A), a similar MAPbI₃ film after a solid electrolyte peel (FIG.8B), and similar films after oxidation to 0.4 V and 0.8 V at 0° take-off angle (FIG. 6C and FIG. 8D).

FIG. 9 shows five consecutive cyclic voltametric scans of an over-stoichiometric (ex. PbI₂-rich) (red) and near-stoichiometric (blue) MAPbI₃ film in contact with a solid electrolyte layer without a redox probe in ambient conditions with focus on the iodide/triiodide redox process, upper curve being offset by 100 μA, according to an embodiment of the present invention.

FIGS. 10A and 10B shows band diagram of MAPbI₃, PbI₂ and the Fc/Fc⁺ redox probe in combination with the CVs, according to an embodiment of the present invention.

FIG. 11 shows CVs as a function of anodic potential endpoints approaching E_{VB,onset} (0.4 to 0.5 V), followed by cathodic sweep in presence of 1 mM Fc at 0.05 V/s in ambient, according to an embodiment of the present invention.

FIG. 12 shows CVs as a function of anodic potential endpoints approaching E_{VB,onset} (0.5 to 0.7 V), followed by cathodic sweep in presence of 1 mM Fc at 0.05 V/s in ambient with focus on (inset) the reduction peaks, according to an embodiment of the present invention.

FIG. 13 shows CVs as a function of anodic potential endpoints surpassing E_{VB,onset} (0.7 to 0.9 V), followed by cathodic sweep in presence of 1 mM Fc at 0.05 V/s in ambient with focus on (inset) the reduction peaks, according to an embodiment of the present invention.

FIG. 14 shows a characterization of frontier orbital energetics for MAPbI₃ with UPS. Onset in secondary edge is determined to be 14.7 eV in kinetic energy, or a work function of 4.8 eV with the (inset) showing linear extrapolation of the HKE edge affords the estimation of the E_{VB} at 30.3 eV on the kinetic energy scale, or 0.8 eV below the Fermi level: using a photon energy of 21.22 eV yields an ionization energy of 5.62 eV with respect to surface vacuum, according to an embodiment of the present invention.

FIG. 15 shows full valence band analysis with ▪=A(730 nm) (versus the baseline absorbance A(820 nm)) and ▴=dA/dE in a potential range of −0.6 V to −0.9 V and −1.1 to −1.3 V with 0.1 increments and −0.9 to −1.1 V with 0.02 V increments, taken from in-situ spectro-electrochemical data for the bleaching of MAPbI₃ valence band for the stack in (a), with no redox probe, in ambient conditions (inset); the red line is a Gaussian fit with a maximum at 5.62 eV with an onset at 5.44 eV as a guide for the eye, according to an embodiment of the present invention.

FIGS. 16A-16C show residual plots of the exponential fit following y=A×exp(−x/t)+y₀ for (a) Qₒₓ (FIG. 16A), and (b) Q_{red,Fc/Fc+} (FIG. 16B) and following y=A×exp(−1/2((x−x_{c})/w)²)+y₀ for (c) Q_{red,defects} (FIG. 16C), according to an embodiment of the present invention.

FIG. 17 illustrates an example of inclusion of stamp process within an ultra-high vacuum (UHV) chamber and/or the vacuum deposition of an ionic liquid material to be used with the electrochemical probe, according to an embodiment of the present invention.

FIG. 18 illustrates an operando setup in combination with other spectroscopic analysis techniques, GIWAXS is grazing incidence wide angle X-ray scattering and XPS is X-ray photoelectron spectroscopy, according to an embodiment of the present invention.

FIG. 19 shows degradation analysis of the valence band of a triple cation perovskite film using operando setup in combination with wide angle X-ray scattering, according to an embodiment of the present invention.

FIG. 20 is an overview of calculated and measured defect densities in solution processed, polycrystalline perovskite films using a wide range of methodologies, the numbers representing the corresponding references, the colors, the individual perovskites, and the symbols, the different methodologies, the number in brackets is the MAI/PbI₂ precursor ratio for the single cation perovskites, according to an embodiment of the present invention.

FIG. 21A are UV-vis spectra of near-stoichiometric MAPbI3 (blue) and CsFAMA (red) films on ITO, according to an embodiment of the present invention.

FIG. 21B are XRD spectra of near-stoichiometric MAPbI3 (blue) and CsFAMA (red) films on ITO, according to an embodiment of the present invention.

FIG. 21C is a schematic of the MAPbI3 half-cell stack structure used for electrochemical characterization, according to an embodiment of the present invention.

FIG. 21D shows results of five consecutive CVs as a function of anodic potential (or Eox, end) endpoints approaching and surpassing EVB,onset (0.6 to 0.8 V: 5.3 eV to 5.5 eV) for both near-stoichiometric MAPbI3 (blue) and CsFAMA (red) on ITO, followed by cathodic sweep in presence of 1 mM Fc at 0.05 V s−1 under inert atmosphere. Increasingly anodic sweeps yield higher oxidation currents, and on the return sweeps, reduction of defect states and reduction of Fc+ created on the positive sweeps, the curves for each Eox, end being offset for clarity, according to an embodiment of the present invention.

FIG. 21E shows results of charge (Q) integration of all CVs (like in (a)) as a function of Eox, end separated into (▪) total oxidative charge (Qox), (▴) defect reduction charge (Qred, defects), and (●) Fc+ reduction charge (Qred,Fc/Fc+) following the procedure described in Fredlein et al., J. Electrochem. Soc., 1979, 126, 1892-1898, which is incorporated herein by reference in its entirety, the inset shows the expansion of the defect reduction region, according to an embodiment of the present invention.

FIG. 22A shows cyclic voltammograms of MAPbI3 as a function of anodic potential endpoints approaching EVB,onset (0.4 to 0.5 V) followed by cathodic sweep in presence of 2.5 mM Fc at 0.05 V/s under inert conditions (H2O<0.1 ppm: O2<0.1 ppm), according to an embodiment of the present invention.

FIG. 22B shows cyclic voltammograms of MAPbI3 as a function of anodic potential endpoints approaching EVB,onset (0.5 to 0.7 V) followed by cathodic sweep in presence of 2.5 mM Fc at 0.05 V/s under inert conditions (H2O<0.1 ppm: O2<0.1 ppm), according to an embodiment of the present invention.

FIG. 22C shows cyclic voltammograms of MAPbI3 as a function of anodic potential endpoints surpassing EVB,onset (0.7 to 0.9 V) followed by cathodic sweep in presence of 2.5 mM Fc at 0.05 V/s under inert conditions (H2O<0.1 ppm: O2<0.1 ppm), according to an embodiment of the present invention.

FIG. 23A shows cyclic voltammograms of CsFAMA as a function of anodic potential endpoints approaching EVB, onset (0.4 to 0.5 V) followed by cathodic sweep in presence of 2.5 mM Fc at 0.05 V/s under inert conditions (H2O<0.1 ppm: O2<0.1 ppm), according to an embodiment of the present invention.

FIG. 23B shows cyclic voltammograms of CsFAMA as a function of anodic potential endpoints approaching EVB,onset (0.5 to 0.7 V) followed by cathodic sweep in presence of 2.5 mM Fc at 0.05 V/s under inert conditions (H2O<0.1 ppm: O2<0.1 ppm), according to an embodiment of the present invention.

FIG. 23C shows cyclic voltammograms of CsFAMA as a function of anodic potential endpoints surpassing EVB, onset (0.7 to 0.9 V) followed by cathodic sweep in presence of 2.5 mM Fc at 0.05 V/s under inert conditions (H2O<0.1 ppm: O2<0.1 ppm), according to an embodiment of the present invention.

FIG. 25A shows differential pulse voltammograms for the reduction of Fc+ with a 0.001 V increment, 0.05 mV amplitude, 0.005 s sample width, 0.3 s pulse period and variable pulse width of 2.5 mM Fc in 0.1 M TBAPF6/propylene carbonate, according to an embodiment of the present invention.

FIG. 25B shows differential pulse voltammograms for the reduction of Fc+ with a 0.001 V increment, 0.05 mV amplitude, 0.005 s sample width, 0.3 s pulse period and variable pulse width of 2.5 mM Fc in the solid electrolyte, according to an embodiment of the present invention.

FIG. 26A shows differential pulse voltammograms for the reduction of Fc+ with a 0.001 V increment, 0.05 V amplitude, 0.05 s pulse width, 0.3 s pulse period and variable sample width of 2.5 mM Fc in 0.1 M TBAPF6/propylene carbonate, according to an embodiment of the present invention.

FIG. 26B shows differential pulse voltammograms for the reduction of Fc+ with a 0.001 V increment, 0.05 V amplitude, 0.05 s pulse width, 0.3 s pulse period and variable sample width of 2.5 mM Fc in the solid electrolyte, according to an embodiment of the present invention.

FIG. 27A shows differential pulse voltammograms for the reduction of Fc+ with a 0.001 V increment, 0.05 V amplitude, 0.05 s pulse width, 0.005 s sample width and variable pulse period of 2.5 mM Fc in 0.1 M TBAPF6/propylene carbonate, according to an embodiment of the present invention.

FIG. 27B shows differential pulse voltammograms for the reduction of Fc+ with a 0.001 V increment, 0.05 V amplitude, 0.05 s pulse width, 0.005 s sample width and variable pulse period of 2.5 mM Fc in the solid electrolyte, according to an embodiment of the present invention.

FIG. 29A shows differential pulse voltammograms of the reduction of CsFAMA as a function of anodic potential endpoints approaching EVB, onset (0.5 to 0.7 V) after prior oxidation in the presence of 2.5 mM Fc at 0.05 V/s under inert conditions, according to an embodiment of the present invention.

FIG. 29B shows differential pulse voltammograms of the reduction of CsFAMA as a function of anodic potential endpoints approaching EVB, onset (0.7 to 0.8 V) after prior oxidation in the presence of 2.5 mM Fc at 0.05 V/s under inert conditions, according to an embodiment of the present invention.

FIG. 29C shows differential pulse voltammograms of the reduction of CsFAMA as a function of anodic potential endpoints surpassing EVB, onset (0.8 to 0.9 V) after prior oxidation in the presence of 2.5 mM Fc at 0.05 V/s under inert conditions, according to an embodiment of the present invention.

FIG. 29D shows differential pulse voltammograms of the reduction of CsFAMA as a function of anodic potential endpoints approaching EVB, onset (0.9 to 1 V) after prior oxidation in the presence of 2.5 mM Fc at 0.05 V/s under inert conditions, according to an embodiment of the present invention.

FIGS. 31A-31C show residual plots of the exponential fit following y=A×exp(−x/t)+y0 for (a) QI/I3− (FIG. 16A), the Gaussian fit following y=A×exp(−1/2 ((x−xc)/w)2)+y0 for Qred, defects (FIG. 16B), and the exponential fit following y=A×exp(−x/t)+y0 for Qred, Fc/Fc+ (FIG. 16C), according to an embodiment of the present invention.

FIG. 32 shows the characterization of frontier orbital energetics for CsFAMA with UPS, onset in secondary edge is determined to be 13.9 eV in kinetic energy, or a work function of 4.1 eV, the (inset) corresponding to Linear extrapolation of the HKE edge affords the estimation of the EVB at 29.7 eV on the kinetic energy scale, or 1.4 eV below the Fermi level, using a photon energy of 21.22 eV yields an ionization energy of 5.49 eV with respect to surface vacuum, according to an embodiment of the present invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention.

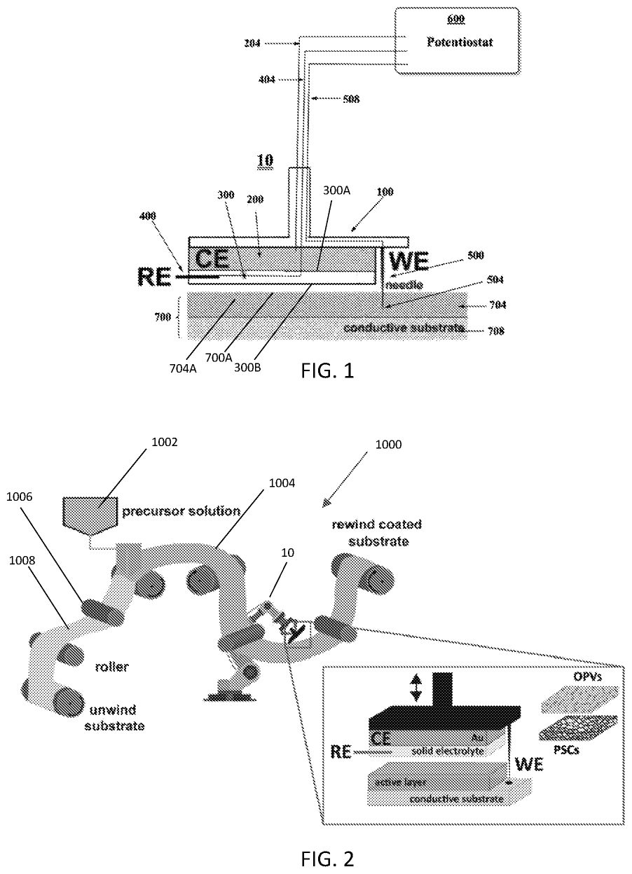

FIG. 1 is a schematic illustration of an apparatus 10 for characterizing a substructure of a semiconductor device 700 according to an embodiment of the present invention. The apparatus 10 includes a potentiostat 600. The apparatus (probe) 10 also a counter electrode 200 electrically connected to the potentiostat 600. The apparatus 10 also includes a solid electrolyte 300 attached to a surface of said counter electrode 200 at a first surface 300A of the solid electrolyte 300. The solid electrolyte 300 having a second surface 300B opposite the first surface 300A. The apparatus 10 includes a reference electrode 400 embedded within at least a portion of the solid electrolyte 300 and electrically connected to the potentiostat 600. The apparatus 10 also includes a probe 500 electrically connected to the potentiostat 600. The semiconductor device 700 comprises a device electrode 708 and at least one layer of material 704 formed on said device electrode 708. At least one layer of material 704 has a layer of a semiconductor 704A. The probe 500 is configured to be electrically connected to the device electrode 708 to provide a working electrode. The counter electrode 200 and the solid electrolyte 300 are configured so that the second surface 300B of the solid electrolyte 300 can be brought into contact with at least a portion of a surface 700A of the substructure of said semiconductor device 700. The solid electrolyte 300 includes a solid porous material and an ionic liquid disposed within the solid porous material.

Although the substructure 700 is an example of a substructure of one layer of material 704 and one device electrode 708, the general concepts of the current invention are not limited to this example. For example, there could be one or more additional layers of material on the surface 700A and/or between the device electrode 708 and the layer of material 704. These could include, but are not limited to, any one or more of electron transport layers, hole transport layers, buffer layers, etc.

In an embodiment, the porous material can be a polymer.

In an embodiment, the solid electrolyte 300 includes a redox probe compound.

In an embodiment, the polymer includes at least one of a chemically inert polymer or a copolymer of a chemically inert polymer with low oxygen transport, high solubility, low molecular weight, high dielectric constant (or high-K), or a combination thereof.

In an embodiment, the polymer includes poly (vinylidene fluoride) (PVDF), hexafluoropropylene (“HFP”), tetrafluoroethylene (TFE), poly (ethylene oxide) (PEO), poly(acrylonitrile) (PAN), poly(methyl methacrylate) (PMMA), or a combination thereof.

In an embodiment, the ionic liquid includes 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF6]”), 1-Ethyl-3-methylimidazolium tetrafluoroborate (“[EMIM][BF4]”) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

In an embodiment, the redox probe compound of the solid electrolyte 300 comprises metallocenes (e.g., ferrocene), benzoquinones, (hydro)quinones, phthalocyanines, ruthenium(II)/(III) complexes, or a combination thereof.

In an embodiment, redox probe comprises molecules which undergo one-electron oxidations or reductions to create stable products which can be electrochemically quantified, including metallocenes (e.g., ferrocene), benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from the semiconductor active layer, in the dark or under illumination, which can be subsequently quantified using simple electrochemical approaches, or a mixture thereof.

In an embodiment, the reference electrode includes Ag/AgCl, platinum, silver, a stable metallic or polymeric conductor that is capable of establishing electrochemical equilibrium with the ionic liquid/solid electrolyte material, or a combination thereof.

In an embodiment, the probe 500 is further configured to be disconnected from the device electrode and subsequently electrically reconnected to said device electrode to provide a working electrode. The counter electrode 200 and the solid electrolyte 300 are configured so that the second surface 300B of the solid electrolyte 300 can be removed from the portion of the surface 700A of said substructure of said semiconductor device 700 and brought into contact with at least a second portion of a second surface of said substructure of said semiconductor device 700.

Aspects of embodiments of the present invention include providing a method of characterizing a substructure of a semiconductor device (semiconductor device 700). The method includes contacting at least a portion of a surface 700A of the substructure of the semiconductor device 700 with a second surface 300B of the solid electrolyte 300. The solid electrolyte 300 has a first surface 300A opposite the second surface 300A and having a porous solid material. The solid electrolyte 300 is attached to a counter electrode 200. The solid electrolyte 300 includes a reference electrode 200 embedded therein. The semiconductor device 700 includes a working electrode 708. The method includes measuring a current between the counter electrode 200 and the working electrode 708, for an applied voltage to the reference electrode 200, and characterizing the substructure of the semiconductor device 700 based at least partially on the applied voltage and the measured current.

In an embodiment, the porous material is a polymer. In an embodiment, the solid electrolyte 300 further includes a redox probe compound.

In an embodiment, the polymer includes at least one of a chemically inert polymer or a copolymer of a chemically inert polymer with low oxygen transport, high solubility, low molecular weight, high dielectric constant (or high-K), or a combination thereof.

In an embodiment, the polymer includes poly (vinylidene fluoride) (PVDF), hexafluoropropylene (“HFP”), tetrafluoroethylene (TFE), poly (ethylene oxide) (PEO), poly (acrylonitrile) (PAN), poly(methyl methacrylate) (PMMA), or a combination thereof.

In an embodiment, the ionic liquid includes 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF6]”), 1-Ethyl-3-methylimidazolium tetrafluoroborate (“[EMIM][BF4]”) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

In an embodiment, the redox probe compound includes metallocenes (e.g., ferrocene), benzoquinones, (hydro)quinones, phthalocyanines, ruthenium(II)/(III) complexes, or a combination thereof.

In an embodiment the redox probe includes molecules which undergo one-electron oxidations or reductions to create stable products which can be electrochemically quantified, including metallocenes (e.g., ferrocene), benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from the semiconductor active layer, in the dark or under illumination, which can be subsequently quantified using simple electrochemical approaches, or a mixture thereof.

In an embodiment, the reference electrode includes Ag/AgCl, platinum, silver, a stable metallic or polymeric conductor that is capable of establishing electrochemical equilibrium with the ionic liquid/solid electrolyte material, or a combination thereof.

In an embodiment, the probe 500 is further configured to be disconnected from said device electrode and subsequently electrically reconnected to said device electrode to provide a working electrode. The counter electrode 200 and the solid electrolyte 300 are configured so that the second surface 300B of the solid electrolyte 300 can be removed from the portion of the surface 700A of said substructure of said semiconductor device 700 and brought into contact with at least a second portion of a second surface of the substructure of the semiconductor device.

FIG. 2 is a schematic illustration showing use of the apparatus 10 as a in situ sensor in the evaluation of a semiconductor layer during a roll-to-roll manufacturing process in a semiconductor production system, according to an embodiment of the present invention. The semiconductor production system 1000 includes a semiconductor depositing system 1002 arranged to deposit at least one of a semiconductor layer 1004 or a precursor to a semiconductor layer onto a device subassembly 1006 comprising a device substrate 1008 to produce a substructure of a semiconductor device. The production system 1000 also includes apparatus 10 for characterizing said substructure of the semiconductor device.

In an embodiment, the porous material is a polymer. In an embodiment, the solid electrolyte further comprises a redox probe compound.

In an embodiment, the polymer includes at least one of a chemically inert polymer or a copolymer of a chemically inert polymer with low oxygen transport, high solubility, low molecular weight, high dielectric constant (or high-K), or a combination thereof.

IN an embodiment, the polymer includes poly(vinylidene fluoride) (PVDF), hexafluoropropylene (“HFP”), tetrafluoroethylene (TFE), poly(ethylene oxide) (PEO), poly (acrylonitrile) (PAN), poly(methyl methacrylate) (PMMA), or a combination thereof.

In an embodiment, the ionic liquid includes 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF6]”), 1-Ethyl-3-methylimidazolium tetrafluoroborate (“[EMIM][BF4]”) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

In an embodiment, the redox probe compound includes metallocenes (e.g., ferrocene), benzoquinones, (hydro)quinones, phthalocyanines, ruthenium(II)/(III) complexes, or a combination thereof.

In an embodiment, the redox probe includes molecules which undergo one-electron oxidations or reductions to create stable products which can be electrochemically quantified, including metallocenes (e.g., ferrocene), benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from the semiconductor active layer, in the dark or under illumination, which can be subsequently quantified using simple electrochemical approaches, or a mixture thereof.

In an embodiment, the reference electrode comprises Ag/AgCl, platinum, silver, a stable metallic or polymeric conductor that is capable of establishing electrochemical equilibrium with the ionic liquid/solid electrolyte material, or a combination thereof.

In an embodiment, the probe 500 of the apparatus 10 is configured to be disconnected from the device electrode and subsequently electrically reconnected to the device electrode to provide a working electrode. The counter electrode 200 and the solid electrolyte 300 are configured so that said second surface of said solid electrolyte can be removed from said portion of the surface of the substructure of the semiconductor device and brought into contact with at least a second portion of a second surface of said substructure of said semiconductor device.

In an embodiment, there is also provided a method of producing a semiconductor device. The method includes using the system described above to produce at least a substructure of the semiconductor device; and completing a remaining structure of the semiconductor device.

In an embodiment, there is further provided a semiconductor device produced according to the above method of producing a semiconductor device.

Compositions and methods of the invention can provide a solvent-free analysis of electronic materials to determine various characteristics such as number of defects, electroactivity, migration/diffusion processes, stability, surface composition, band gap, physical structure, etc. Devices and methods of the invention can be useful in analyzing an electronic material such as a metal halide perovskite, an organic semiconductor, a nanocrystalline (quantum dot) thin film, metal oxides, a material blend or a device stack, as well as any other semiconductor materials known to one skilled in the art.

In some embodiments, devices and methods of the invention provide a solvent-free electrochemical analysis of electronic materials to determine various characteristics such as number (concentration) of defects (defect density) at a specified energy level with respect to vacuum (vs reference electrode) and a known redox reaction, electroactivity, charge migration/diffusion processes, stability, surface composition, band gap, physical structure, etc.

In the last decade, interest in the use of metal halide perovskites in optoelectronic materials has surged tremendously as a roll-to-roll coatable material in high-performance optoelectronic devices, ranging from solar cells, photodetectors, and ionizing radiation detectors to light-emitting diodes (LEDs) and lasers, as well as to memories and solar-to-fuel conversion fields.

Characterization of electronic defects in metal halide perovskite materials and at its interfaces is critical for the optimization and long-term stability of optoelectronic devices. Electrochemical approaches offer unprecedented limits of detection under relevant operando conditions, with a direct connection to underlying defect chemistry and energy levels.

Embodiments of the present invention provides methods and compositions for using a “peel and stick” solid electrolyte that can optionally include redox active species for a solvent-free electrochemical analysis. In some embodiments, solid electrolytes are optically transparent to visible and X-ray photons for simultaneous characterization of the electronic band structure and physical properties. In addition, solid electrolytes of the invention can be easily removed for quantification of near-surface composition and energetics using photoelectron or photoemission spectroscopies.

Various embodiments of the present invention will be described with regard to the accompanying drawings, which assist in illustrating various features of the invention. In this regard, the present invention generally relates to an electrochemical analysis method for determining various characteristics of electronic materials using a solid electrolyte. That is, the invention relates to methods and compositions for electrochemical analysis of various electronic materials such as metal halide perovskites, organic semiconductors, quantum dots, semiconductor materials, material blends, device stacks, etc. For the sake of clarity and brevity, the present invention will now be described in reference to methods and compositions for electrochemical analysis of metal halide perovskites. However, it should be appreciated that the scope of the invention is not limited to merely electrochemical analysis of metal halide perovskites. In fact, as stated above, methods and compositions of the invention can be used generally in any situation where characteristics and/or defects of electronic materials can be analyzed using electrochemical processes. As such discussion of analyzing metal halide perovskites electrochemically is provided solely for the purpose of illustrating the practice of the invention and do not constitute limitations on the scope thereof.

The ability to characterize defect energetics and densities in both stoichiometric and non-stoichiometric methylammonium lead triiodide (MAPbI3) films is demonstrated using a systematic modulation of potentials to control hole and electron injection. Inclusion of mid-gap redox probes (ferrocene) allows for probing density of states, whereby electron transfer reversibility is shown to be dependent upon the number of ionized defects at the perovskite's band edges. A detailed Coulombic analysis is provided to determine a defect density of ˜2×1017 cm−3 at 0.1 eV above the valence band. Collectively, this enabling three-electrode approach overcomes challenges in characterizing defects in printable electronic materials and is translatable to operando characterization of a variety of thin film perovskites, organic semiconductors, quantum dots, conventional semiconductor materials, material blends and device stacks, where the removable solid electrolyte functions as a “top contact”.

One particular embodiment of methods and compositions for electrochemical analysis of an electronic material is schematically illustrated in FIG. 1, which is provided for the purpose of illustrating the practice of the present invention and which do not constitute limitations on the scope thereof.

Printable metal halide perovskites have demonstrated remarkable advances in emerging optoelectronic platforms. While more defect tolerant than conventional semiconductors, mixed electronic-ionic conduction and limited stability impede its commercialization. Ion transport is strongly linked to defect propagation in perovskite materials, yielding changes to local chemical composition, electronic structure, and physical microstructure, all of which are exacerbated under photon flux, heat, humidity, and/or electrical bias. Advancements necessitate operando characterization of correlated chemical-electronic-physical properties at interfaces and in device stacks.

Three-electrode electrochemical measurement techniques have historical precedent for the quantification of mid-gap and near valence/conduction band (EVB/ECB) defects in semiconductor materials. Inclusion of redox probes facilitates operando mapping of electronic structure, including local density of states, elucidation of surface defect reactivity, and assessment of defect passivation strategies, as electron transfer events represent charge injection and charge extraction events in working optoelectronic platforms. Additional advantages include sub-parts-per-billion sensitivity for potentiometric and galvanic methods, translation from macro-to nanometer length scales, and direct connections to device performance. Alternatively, electron microscopy, absorption and/or photoelectron spectroscopies techniques typically have lower sensitivity (parts per thousand), lack operando capabilities, and require multiple techniques to make chemical-electronic-physical connections.

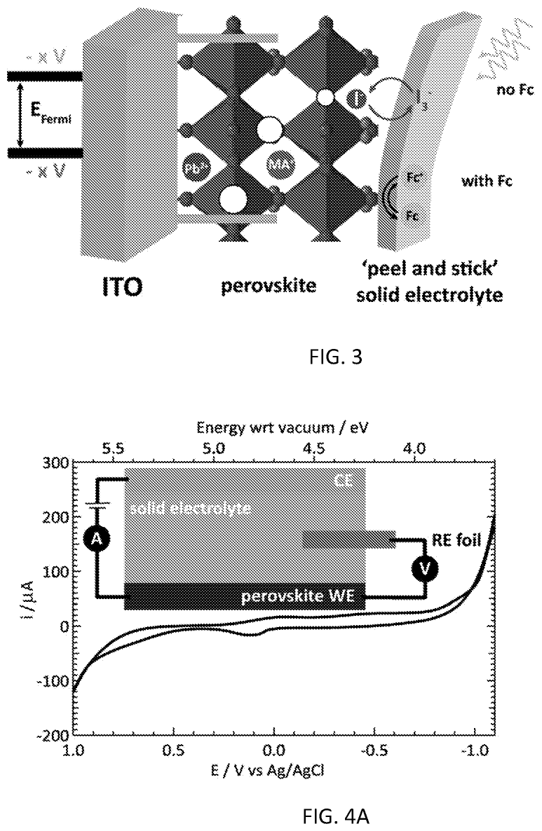

Some aspects of the invention leverage the advantages of (spectro)electrochemical techniques for defect quantification in metal halide perovskites by using a solvent-free electrolyte as illustrated in FIG. 3. Methods of the invention complement prior electrochemical characterization of defect chemistry on phase segregation and degradation by eliminating a need for solvents. Methods of the invention also circumvent challenges associated with perovskite solubility via a stick and peel solid electrolyte (SE). See FIG. 3.

In some embodiments, the SE layer provides optical and X-ray transparency, enhanced interface stability (evident in repeated potential cycling), and inclusion of redox species as electron or hole-collecting top contacts. Methylammonium lead triiodide (MAPbI3) is investigated as a benchmark system for the approach, as MAPbI3 is the most well-characterized metal halide perovskite. This strategic choice allowed for direct comparison with theory and proposed mechanisms for a well-established system.

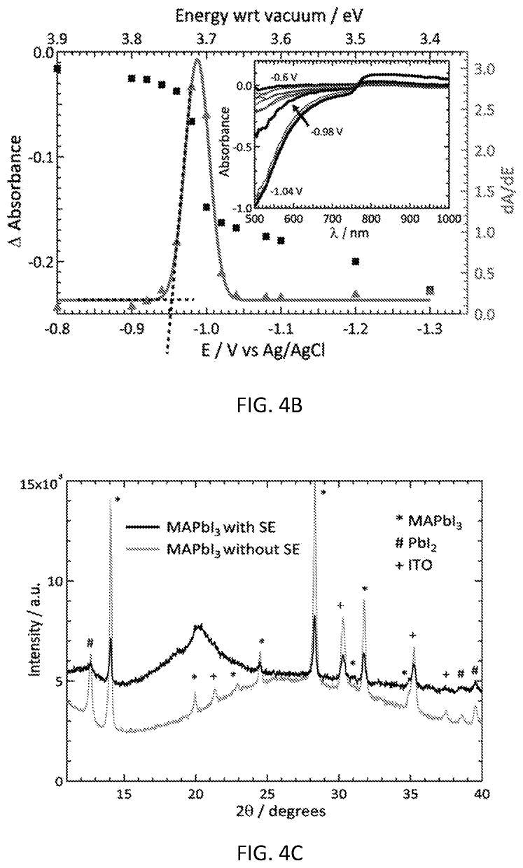

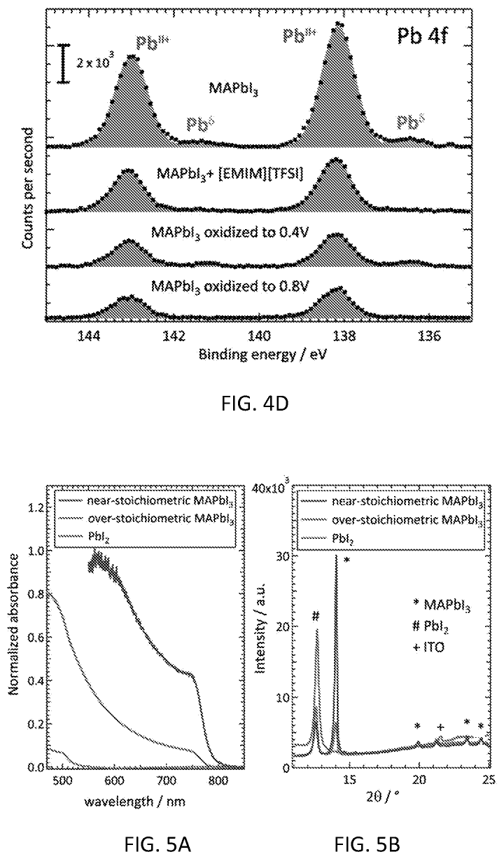

FIGS. 4A-4D summarize the capabilities, similar to half-cell configurations of (photo)electrochemical energy conversion and storage platforms, that are easily translatable to other semiconductor systems under device-relevant stress. In the inset of FIG. 2A, the working electrode (WE) is a material stack (e.g., transparent conductive oxide (TCO)/perovskite) interfaced with the peel and stick solid electrolyte (SE) included of a chemically inert polymer with low oxygen transport (poly (vinylidene fluoride) (PVDF)), an ionic liquid for conductivity, and if desired, a redox probe molecule. The reference electrode (RE, Ag/AgCl foil) is imbedded in the solid electrolyte, which sets a reference potential of 0.07 V (versus Fc+/Fc redox couple) and a gold or indium tin oxide (ITO) counter electrode (CE) modulates the electrochemical potential to inject holes or electrons into the perovskite. An in-plane geometry can be adopted for simultaneous UV-vis spectroscopic and X-ray characterization and addition of environmental stress (electric field, humidity, temperature, illumination) is straightforward. Charge selective layers can easily be included between the TCO and perovskite film.

In the cyclic voltammogram (CV) in FIG. 4A, a low background current was observed in the band gap of the perovskite between 0.7 V vs. Ag/AgCl (5.4 eV vs. surface vacuum) and −0.9 V (3.8 eV). Higher anodic (>0.7 V) and cathodic (<−0.9 V) overpotentials show an exponential increase in current, consistent with charge injection/extraction from valence and conduction bands of MAPbI3. The sensitivity of the approach is demonstrated in the spectroelectrochemical data in FIG. 4B, which shows the change in absorbance with injection of electrons into the conduction band. Typically, resolving energy and density of tail states (most often using UV-vis photoelectron spectroscopy) due to thermal, structural, impurity, and/or compositional disorder has proven challenging for printable electronics. Electron injection was detected via bleaching of the band-edge absorbance at 800 nm (inset) as a sigmoidal function of increasing cathodic potentials, consistent with a narrow distribution of states centered at 3.72 eV (and onset at 3.75 eV). A FWHM of 0.23±0.00(1) eV can be derived from the change in absorbance with potential (dA/dE). The feasibility of operando crystal structure measurements is provided in FIG. 4C, which shows the X-ray transparence of the electrolyte film using X-ray diffraction (XRD) of the MAPbI3 film with and without the solid electrolyte on top. Identifiable lattice spacings and detection of common degradation products such as PbI2 are readily observed in non-stoichiometric films.

The integrity of the near surface composition of the perovskite can be probed via X-ray photoelectron spectroscopy (XPS) post removal of the solid electrolyte, as shown in FIG. 4D. It is noted that the solid electrolyte peel-off method can also be used to remove undesired surface defects (top two spectra) or can be used to investigate changes in surface defects when potentials are applied (bottom two spectra). Briefly, the as cast MAPbI3 film shows a small concentration of Pb0, which has previously been ascribed to decomposition of PbI2 at the surface, consistent with the detected small fraction of PbI2 in FIG. 4C. The solid electrolyte provides a stabilizing effect, where upon removal, defects appear to be removed from the near-surface region, as indicated by the near-stoichiometric Pb/I ratio and removal of aliphatic carbon associated with residual solvent decompositions (SI Supplemental Note 1). Application of anodic potentials (hole injection processes at 0.4 and 0.8 V) show anion migration to the surface to compensate band bending and ion migration in the perovskite film.

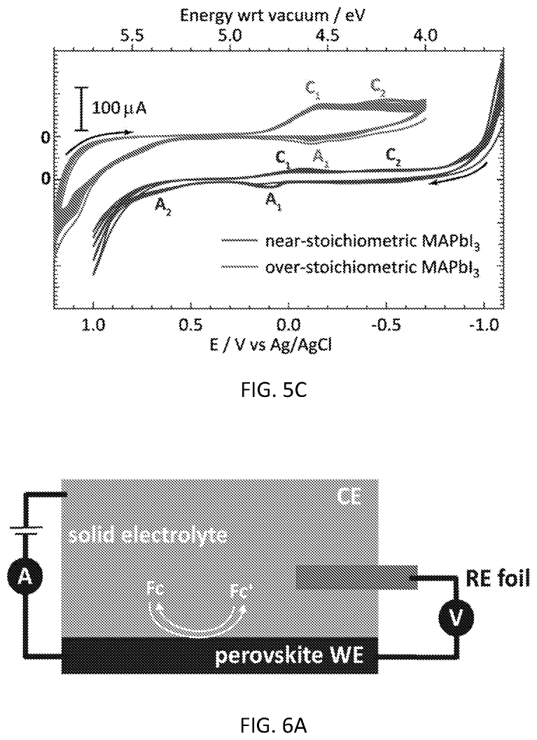

Without being bound by any theory, it is believed that in MAPbI3, iodide vacancies are the primary mobile defects, where redox-active iodide species can be readily detected by CV. FIGS. 5A-5C compare qualitatively highly defective MAPbI3 (red), with an appreciable concentration of residual PbI2 (absorption band near 500 nm, FIG. 5A) and weakly defective MAPbI3 (blue), with a sharp onset in absorption at 800 nm and only trace PbI2 detected by XRD (FIG. 5B). FIG. 5C and S4 show CVs of the two films. The hydrophobic properties of the PVDF-based copolymer provide a stable perovskite/electrolyte interface, with reproducible current-voltage behavior for five consecutive large potential window scans, even in air. In FIG. 5C, a non-Faradaic background current is observed within the bandgap for both films and Faradaic processes are dependent on initial film composition. Table S6 summarizes known electrochemical parameters for labeled peaks (A1/A2 and C1/C3). Peaks A1/C1 correlate with iodide/triiodide (I−/I3−). For the highly defective film, we observe significantly higher redox activity of I−/I3− and even low intensity ambient light is postulated to catalyze the formation of radical species such as I2−● (A3: oxidation of I−; C2: reduction of I3−), mitigated through defect sites.

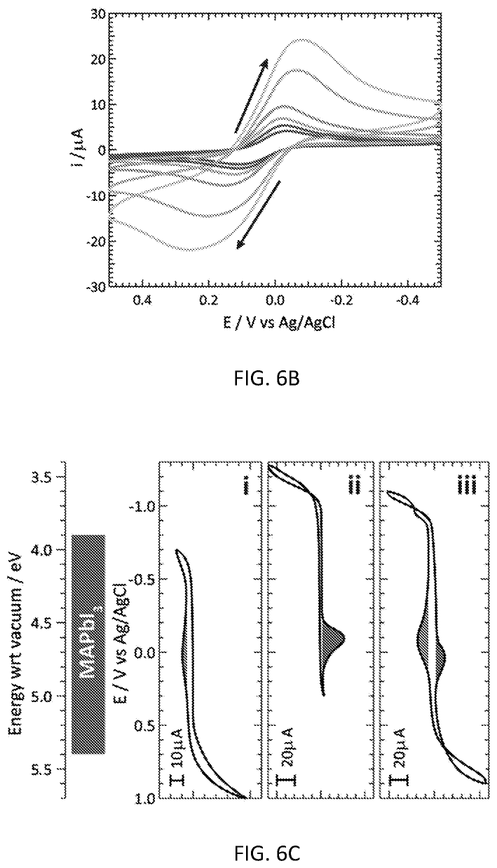

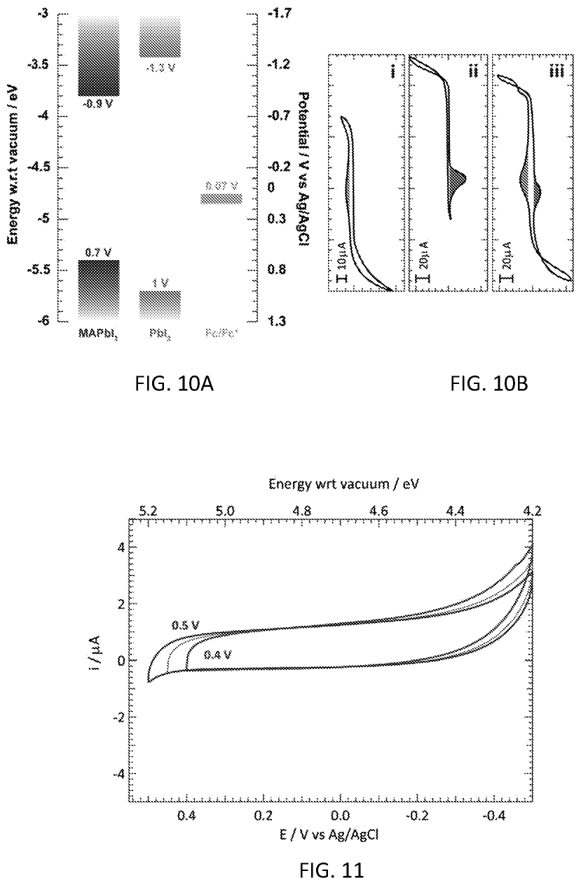

Mid-gap charge transfer in semiconductors was assessed using redox probes, such as prototypical ferrocene/ferrocenium (Fc/Fc+). The validity of inclusion of 1 mM Fc in the SE (FIG. 6A) and its charge transfer kinetics, diffusivity and stability at a metal (Au) electrode is demonstrated in FIG. 6B as a function of scan rate. From peak separation, a heterogeneous rate constant of k0≈7×10−5 cm s−1 was determined with a reductant diffusion coefficient of 1.11×10−8 cm2 s−1 at 50 mV s−1 in the SE: a diffusion coefficient of 2.65×10−7 cm2 s−1 was reported in pure [C4MIM][NTf2]. In FIG. 6C, the voltametric reversibility of Fc/Fc+ depends on the sweep direction and potential window, based on the number of ionic defects near EVB or ECB. Briefly, anodic injection of holes at voltages below EVB (E>5.4 eV: V>0.7 V) show Fc+reduction (green) on the reverse sweep (panel i) but no clear Fc oxidation peak. Injection of electrons above ECB (E<3.9 eV: V<−0.8 V) yields Fc oxidation (blue) in the reverse sweep (panel ii) but shows no evident Fc+ reduction peak. Reversible, near Nernstian Fc/Fc+ behavior is observed when the potential is systematically modulated between EVB and ECB (panel iii). These results indicate reversible charge transfer can only occur with sufficient overlap between the density-of-states of redox probe and valence or conduction states (i.e., band bending). In FIG. 6C and FIGS. 10A-10B, the CV responses are plotted with voltage on y-axis to demonstrate their correspondence to band edge energies for MAPbI3. Experiment includes (i) potential sweep anodic of EVB onset with no electron injection into ECB on cathodic sweep: (ii) potential sweep cathodic of ECB onset with no hole injection into EVB on anodic sweep: and (iii) excursions into both the VB and CB regions. The Fc reduction is highlighted in green, Fc+ oxidation in blue.

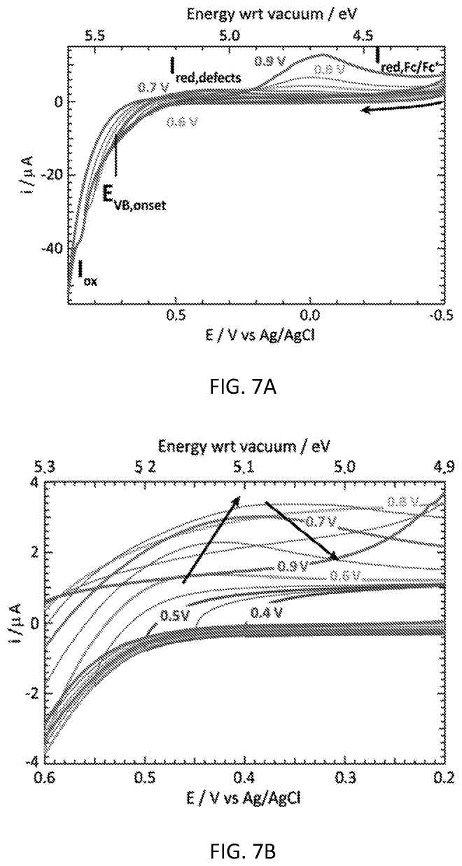

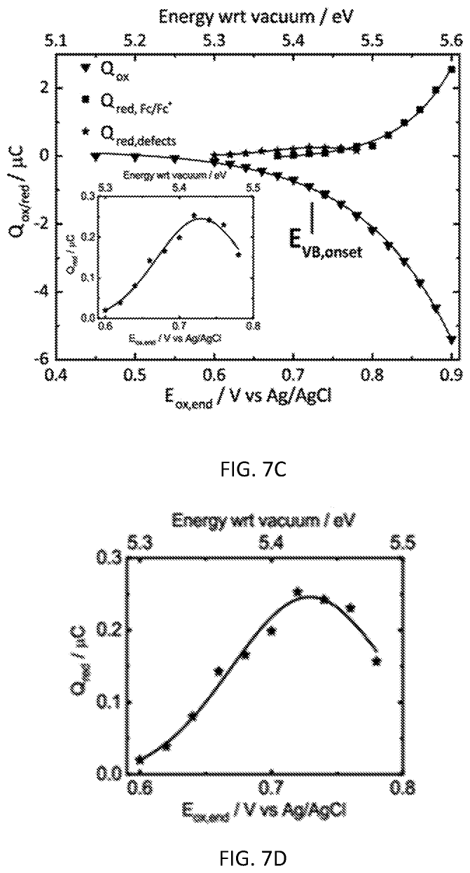

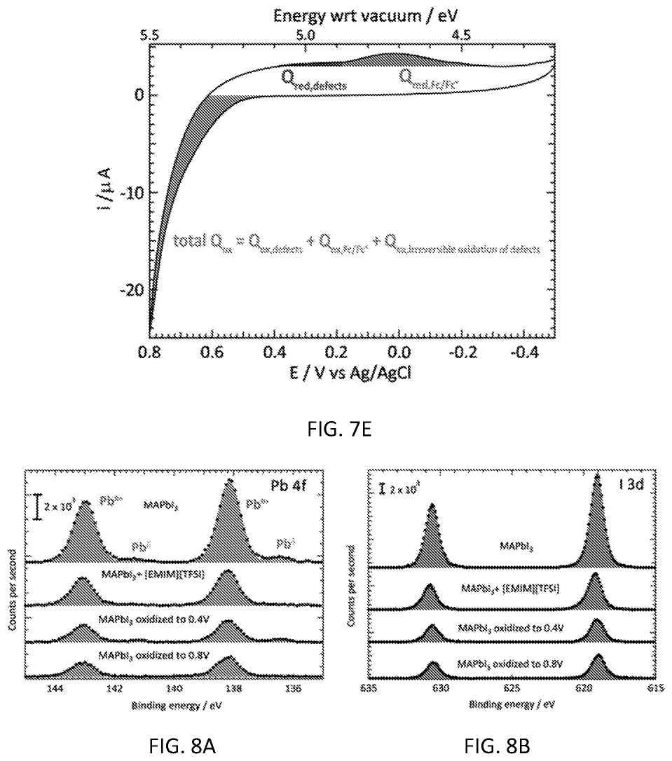

Charge integration, assuming all current above background is Faradaic, allows for defect quantification near EVB (FIG. 7A-7E). As shown in FIGS. 7A and 7B, systematic increase in oxidative current was observed due to defect and Fc oxidation as potential was shifted toward more anodic EVB (increasing end oxidation potential of linear sweep, Eox, end). At low Eox, end (<0.7 V˜EVB,onset), defects are partially reduced (Qred, defects) in the reverse cathodic scan (inset). When Eox,end>EVB,onset, Fc+ reduction appears at ˜0.0 V and depends on defect quantity formed in the anodic scan.

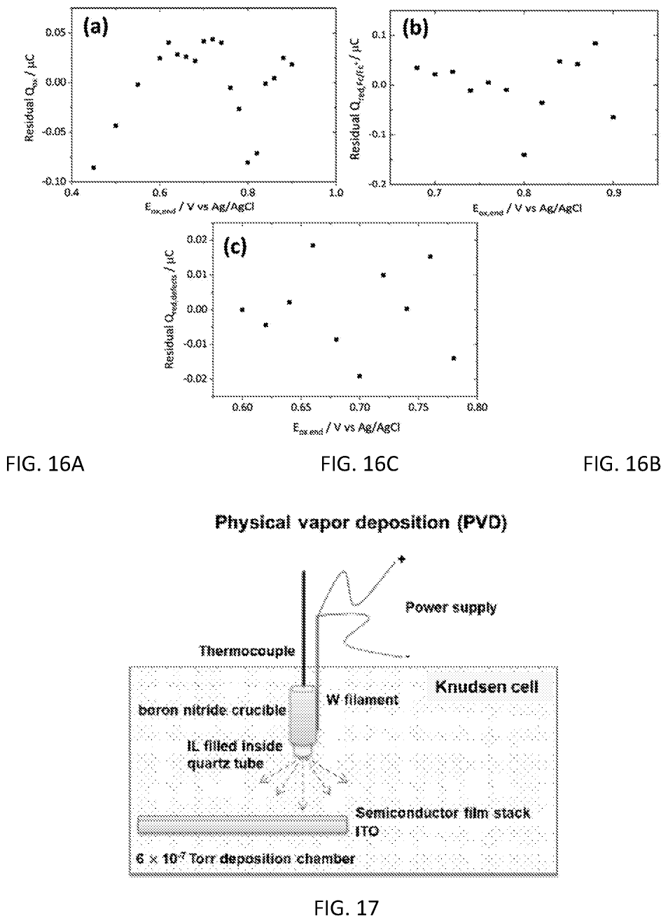

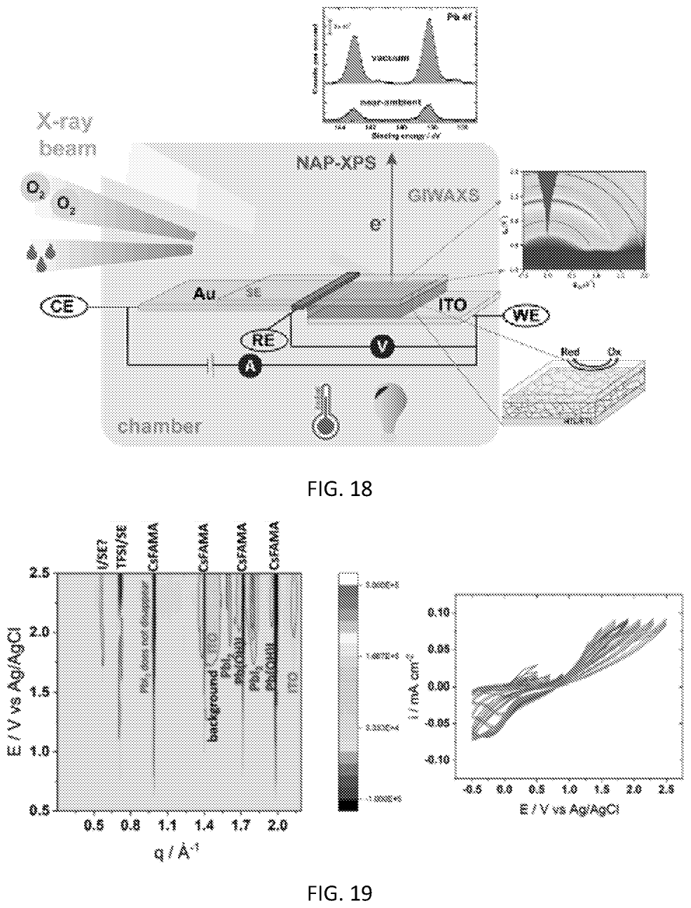

Energy-dependent defect quantification is given in FIGS. 7C and 7D, following the example in FIG. 7E and using the data collected in FIGS. 7A and 7B. It should be noted that the charge distribution for the oxidation process (Qox, ▾) follows an exponential increase with potential (y=A×exp(−x/t)+y0 fit is provided), indicative of Marcus-Gerischer theory for n-type materials at high anodic overpotentials (>0.8 V), supported by the complementary exponential behavior of Fc+ reduction (Qred,Fc/Fc+) as indicated in FIG. 7C. The shallow surface defects just above EVB (i.e. 5.3 to 5.4 eV) are only partly reduced reversibly (Qred, defects,*), following a Gaussian distribution (inset) with a maximum at 0.729 V (5.429 eV) and a defect density of 2.14×1017 cm−3, as described in Supplementary Note 2. When Eox, end>EVB, onset, defect density decreases, indicating the surface defects could be facilitating Fc+ reduction (▪), supported by the XPS. The residuals for the fitting are given in FIGS. 16A, 16B and 16C.

As disclosed herein, easily implemented electrochemical method of the invention enables estimations of band edge energies, defect quantification, accessible spectroscopic correlations, and operando capabilities for thin film perovskites over a wide potential range. This flexible approach to defect characterization in semiconductors, using a range of redox couples spanning the bandgap region, is difficult to implement with other conventional top contacts. Methods of the invention also enable quantification of defect energies and concentrations on a wide range of semiconductor materials, including material blends, where operando electrochemical and spectroscopic characterization is essential to design and support various optoelectronic platforms.

Additional objects, advantages, and novel features of this invention will become apparent to those skilled in the art upon examination of the following examples thereof, which are not intended to be limiting. In the Examples, procedures that are constructively reduced to practice are described in the present tense, and procedures that have been carried out in the laboratory are set forth in the past tense.

### EXAMPLES

The following provides some specific examples according to some embodiments of the current invention. However, the general concepts of the current invention are not limited to the specific examples.

Materials: Precursor solution solvents. N, N-dimethylformamide (DMF, anhydrous, 99.9%, Sigma Aldrich), dimethylsulfoxide (DMSO, 99+%, Alfa Aesar) and chlorobenzene (extra dry, 99.8%, Acros Organics). These precursor solution solvents were extensively dried over freshly activated molecular sieves before use and degassed for 30 minutes with argon before transferring to nitrogen glovebox (<1 ppm O2, <0.1 ppm H2O). The molecular sieves were activated in a muffle oven for 3 hours at 320° C.

Precursors. Lead iodide (PbI2, 99% trace metals basis, Acros), methylamine (MA, 40% in H2O, Sigma Aldrich), and hydroiodic acid (HI, 47+%/stabilized, ACS grade, Sigma Aldrich). All precursor materials were kept in a desiccator under vacuum to avoid water contamination.

Electrolyte. Poly(vinylidene fluoride-co-hexafluoropropylene) (PVDF-HFP, Sigma Aldrich), 1-Ethyl-3-methylimidazolium bis(trifluoromethylsulfonyl)imide ([EMIM][TFSI], 99%, IOLITEC), and acetone (ACS, 99.5%, Beantown Chemical). The ionic liquid was kept in a N2 glovebox.

Preparation of the MAI precursor: Methylammonium iodide (MAI) was prepared by adding ca. 25 mL of ice bath-cooled MA into ca. 100 mL of ethanol in a 250 mL round bottom flask (RBF) in air at room temperature. HI, cooled in an ice bath, was slowly added (ca. 10 mL) to the RBF. The solution was allowed to stir for ca. 24 hours in air at RT. Before rotary evaporation, the solution was dried with anhydrous magnesium sulfate and vacuum filtered in air to remove the magnesium sulfate-water complex. The MAI solution was then rotary evaporated lending a white precipitate. MAI was re-crystallized/purified by (1) re-dissolving orange precipitate in a minimal amount of ethanol, (2) supersaturating the solution with an applied heat gun to the RBF, (3) slowly cooling the RBF in an ice bath. The collected solid was then filtered in air and rinsed with ice bath-cooled ether that had been dried under activated molecular sieves for 1 hour in air. This recrystallization process was performed twice to collect white crystals. The collected crystals were then vacuum dried at 90° C. overnight before transferring to a desiccator under vacuum for storage until use in perovskite thin film deposition. All perovskite precursors are kept in a desiccator under vacuum to avoid water contamination.

Preparation of the perovskite active layer: ITO coated glass slides (sheet resistance 9-15 Ω/square, Colorado Concept Coatings LLC, 96041) were cut to individual samples (10×10×1.09 mm3). All ITO substrates were pre- rinsed and sonicated in solutions of sodium dodecyl sulfate-water, acetone (ACS, 99.5%, Beantown Chemical), and finally isopropanol (ACS, 99.5%, Beantown Chemical), and allowed to dry.

Preparation of PbI2-rich or highly defective MAPbI3 films: To deposit PbI2-rich MAPbI3 films, ca. 461 mg PbI2, and ca. 159 mg of MAI are weighed in air. Both salts were transferred in two separate hot 2-dram vial (stored at 150° C. in an oven to minimize water content) and then loaded into a N2 glovebox. In the box, 950 μL of DMF and 105 μL of DMSO were added to both vials and then mixed together in a third vial. This precursor solution was then stirred at 70° C. for 15 minutes. Subsequently, the solution was cooled down for 5 minutes and filtered with a 0.25 μm PTFE syringe filter to obtain the precursor solution. The precursor solution was dispensed onto the cleaned ITO substrates (120 μL) at room temperature and then spin-cast at 6000 RPM for 30 seconds (6000 acceleration). After 20 seconds of spinning, 300 μL of chlorobenzene (anti-solvent) was added. The film was left in the spin coater for 1 minute and then transferred to a preheated hot plate 100° C. to anneal for 60 minutes.

Preparation of stoichiometric or weakly defective MAPbI3 films: MAPbI3 films were deposited by weighing ca. 324 mg PbI2, and ca. 102 mg of MAI in air. Both salts were transferred to a hot 2-dram vial (stored at 150° C. in an oven to minimize water content) with a micro stir bar and then immediately loaded into a N2 glovebox. Within the N2 glovebox, 512 μL of DMF and 128 μL of DMSO were added to the vial (generating solution concentrations of ca. 1:1 M for MAI:PbI2, respectively) and then the precursor solution was stirred at 70° C. for 20 minutes. The yellow solution was then allowed to cool down to room temperature and then filtered with a 0.25 um PTFE syringe filter. The precursor solution was dispensed onto the cleaned ITO substrates (30 μL) at room temperature and then spin-cast at 1000 RPM for 10 seconds (6000 acceleration) followed immediately by 6000 RPM for 20 seconds (6000 acceleration). With five seconds remaining on the spin-coating cycle, 100 μL of chlorobenzene (anti-solvent) was added to the film in a clean dispensing motion as close to the center of the spinning film as possible. All MAPbI3 films were incubated for 1 minute at room temperature in a plastic petri dish with a plastic lid before being transferred to a hot plate for 60 minutes at 100° C. as the final thermal annealing step inside the N2 glovebox. This 1-minute incubation time, followed by the annealing step, ensures conversion to the perovskite product, avoiding excess PbI2 formation. Glovebox atmosphere circulation (i.e., over an internal purifying catalyst) was kept off throughout the film processing steps described above. After each day of experiments, the glovebox atmosphere was purged for ca. 20 minutes before turning back on the purifier circulation (i.e., until the next experiments involving film processing). MAPbI3 films are kept in the N2 glovebox until they are used for surface and electrochemical characterization.

Preparation of IL-based solid electrolyte with and without redox probe: The electrolyte was made by adding 1 g poly (vinylidene fluoride-co-hexafluoropropylene) or PVDF-HFP pellets to 10 g of acetone. The solution was stirred overnight in air on a hot plate set at 50° C. When dissolved, 1 mg of the redox probe (ferrocene) is added to the cooled solution. To make a 16 wt % IL containing electrolyte solution, 160 mg 1-ethyl-3-methylimidazolium bis(trifluoromethylsulfonyl)imide or [EMIM][TFSI] (stored in a glovebox) was dissolved in 1 g of the PVDF-HFP/acetone mixture. The entire mixture was then emptied in a rectangular watch glass (35 ×40 mm2) and was allowed to dry in air overnight. This solid-type electrolyte with this exact composition has been shown to be a non-solvent for most lead halide perovskite films.

Preparation of perovskite device structures: First, a silver foil (5×13 mm2, 99.9% metals basis, Alfa Aesar) was polished with 4000 grit sandpaper and sonicated in deionized water. Using a two-electrode cell filled with 1 M HCl (ACS, 36-38%, EMD) and a Pt counter electrode, we chlorodized the silver foil at 0.4 V for 2 minutes. Three-electrode sandwich-type perovskite device structures were constructed as a 5-layered stack consisting of an ITO film transparent electrode on glass, a MAPbI3 film as the active layer, a solid electrolyte film (with or without redox probe) wrapped around an Ag/AgCl foil and a gold electrode. The gold electrode was cleaned and sonicated in ethanol (anhydrous, >95%, Decon Laboratories Inc.) before use. The device stack was pressed and kept together using two thin metal plates tightened with four screws. All device structures were assembled and tested in ambient atmosphere.

θ/2θ X-Ray Diffraction (XRD): For θ/2θ-XRD experiments, MAPbI3 films on ITO were mounted on a clay holder in air and loaded into a Phillips X'PERT MPD system, with “PreFIX” source module and a “X'Celerator” detector module, using CuKα radiation (λmax=1.541874 Å) with electron gun cathode-anode power settings of 45 kV at 40 mA). Films were analyzed from 5o to 9o in 2θ with 0.0167o step size, scanning symmetrically (i.e., source and detector at same angle with respect to the surface normal—thus preferentially detecting scattering from crystal planes parallel to the substrate plane) with a total scan time of approximately 35 minutes. Optical hardware settings include a 0.04 rad soller slit (source and detector side), a 2o divergence slit at 140 mm from sample (source side), a 11.6 mm horizontal mask (source side), a 0.02 mm-thick Nickel filter (source side), and an overhead sample beam knife. Processing/Analysis of XRD patterns were performed with X'Pert HighScore (for background subtraction) and Mercury 2020.3.0 software (for identifying Bragg peaks from crystal structure).

X-ray photoelectron spectroscopy (XPS): XPS (monochromatic AlKα excitation at 1486.3 eV, 10 mA, 15 kV, pass energy of 20 eV) spectra are acquired at a photoelectron take-off angle of 0o, 30o and 60o (normal to the surface) using a Kratos Axis Ultra PES system (Kratos Analytical, USA) in ultra-high vacuum with a base pressure around 2×10−9 Torr. All samples are fixed using carbon tape and grounded to stainless steel stubs. The non-polarized samples are introduced in the spectrometer through an argon-filled glovebox and the polarized samples through a fast port with minimal ambient (ca. 5 min) and light exposure. The XPS binding energy scale is calibrated with sputter-cleaned Cu, Au, and Ag foils. The XPS spectra are processed using the CasaXPS software package (Casa Software Ltd). The raw XPS data undergo a Shirley background correction and all remaining core level peaks are fit to known chemical components using a 70% Gaussian/30% Lorentzian line shape. In order to minimize random errors, relative peak shape, width and shifts are held constant, which is extremely important when multiple species are used to fit a single peak. Comparisons are made by calculating peak area ratios for each element considering their KE-dependent analyzer transfer functions and orbital cross sections, which is basically done by using the instrument-dependent relative sensitivity factors.

Ultraviolet-visible (UV-Vis) spectrophotometry: Absorbance data of the perovskite films were measured using an Ocean Optics Balanced Deuterium Tungsten Source (210-2500 nm) and an OCEAN-FX-XRI fiber optic spectrometer (200-1025 nm) with a 25 μm slit controlled with the Oceanview software package. The perovskite film spectra were collected relative to a bare ITO substrate.

Electrochemistry: The perovskite film was evaluated using a three-electrode configuration using a gold film and an Ag/AgCl foil as a counter and reference electrode, respectively. All voltammograms were recorded using a CH Instruments Electrochemical Analyzer Model 660C potentiostat controlled with the corresponding software package. Prior to evaluating the perovskite devices, the redox probes were evaluated by cyclic voltammetry at different scan rates (10-500 mV s−1 for 10 cycles) to determine their mass transport and kinetic behavior in the solid electrolyte. Those redox probe test structures consisted of a solid electrolyte film with redox probe wrapped around an Ag/AgCl foil pressed in between two gold electrodes used as a counter and working electrode. These test device stacks were pressed and kept together using two thin metal plates tightened with four screws. All device structures were assembled and tested in ambient atmosphere.

Spectroelectrochemistry: Potential-controlled (CH Instruments Electrochemical Analyzer Model 660C potentiostat) spectroelectrochemical measurements of perovskite films on ITO working electrodes (1 cm2) are recorded using the three-electrode device configuration. The complete device, including the lead halide perovskite film, is placed in the path of the UV-vis spectrophotometer (Ocean Optics system as described above) and a background spectrum is taken after a fixed waiting period (t=5 min) at a potential of −0.5 V vs Ag/AgCl where the perovskite is expected to show the optical and electrical properties of the as-deposited film. Steady-state absorption spectra are acquired after 5 min at defined potentials (20 mV intervals in the bleaching regime around the conduction band) between −0.5 V vs Ag/AgCl to −1.3 V vs Ag/AgCl using the bulk electrolysis feature in the control software.

### EXPERIMENTAL PROCEDURES

Materials: Precursor solution solvents. N, N-dimethylformamide (DMF, anhydrous, 99.9%, Sigma Aldrich), dimethylsulfoxide (DMSO, 99+%, Alfa Aesar) and chlorobenzene (extra dry, 99.8%, Acros Organics). These precursor solution solvents were extensively dried over freshly activated molecular sieves before use and degassed for 30 minutes with argon before transferring to nitrogen glovebox (<1 ppm O2, <0.1 ppm H2O). The molecular sieves were activated in a muffle oven for 3 hours at 320° C.

Precursors. Lead iodide (PbI2, 99% trace metals basis, Acros), methylamine (MA, 40% in H2O, Sigma Aldrich), and hydroiodic acid (HI, 47+%/stabilized, ACS grade, Sigma Aldrich). All precursor materials were kept in a desiccator under vacuum to avoid water contamination.

Electrolyte. Poly(vinylidene fluoride-co-hexafluoropropylene) (PVDF-HFP, Sigma Aldrich), 1-Ethyl-3-methylimidazolium bis(trifluoromethylsulfonyl)imide ([EMIM][TFSI], 99%, IOLITEC), and acetone (ACS, 99.5%, Beantown Chemical). The ionic liquid was kept in a N2 glovebox.

Preparation of the MAI precursor: Methylammonium iodide (MAI) was prepared by adding ca. 25 mL of ice bath-cooled MA into ca. 100 mL of ethanol in a 250 mL round bottom flask (RBF) in air at room temperature. HI, cooled in an ice bath, was slowly added (ca. 10 mL) to the RBF. The solution was stirred for ca. 24 hours in air at RT. Before rotary evaporation, the solution was dried with anhydrous magnesium sulfate and vacuum filtered in air to remove the magnesium sulfate-water complex. The MAI solution was then rotary evaporated lending a white precipitate. MAI was re-crystallized/purified by 1) re-dissolving orange precipitate in a minimal amount of ethanol, 2) supersaturating the solution with an applied heat gun to the RBF, 3) slowly cooling the RBF in an ice bath. The collected solid was then filtered in air and rinsed with ice bath-cooled ether that had been dried under activated molecular sieves for 1 hour in air. This recrystallization process was performed twice to collect white crystals. The collected crystals were then vacuum dried at 90° C. overnight before transferring to a desiccator under vacuum for storage until use in perovskite thin film deposition. All perovskite precursors are kept in a desiccator under vacuum to avoid water contamination.

Preparation of the perovskite active layer: ITO coated glass slides (sheet resistance 9-15 Ω □−1, Colorado Concept Coatings LLC, 96041) were cut to individual samples (10×10×1.09 mm3). All ITO substrates were pre- rinsed and sonicated in solutions of sodium dodecyl sulfate-water, acetone (ACS, 99.5%, Beantown Chemical), and finally isopropanol (ACS, 99.5%, Beantown Chemical), and allowed to dry.

Preparation of PbI2-rich or over-stoichiometric MAPbI3 films: To deposit PbI2-rich MAPbI3 films, ca. 461 mg PbI2, and ca. 159 mg of MAI are weighed in air. Both salts were transferred in two separate hot 2-dram vial (stored at 150° C. in an oven to minimize water content) and then loaded into a N2 glovebox. In the box, 950 μL of DMF and 105 μL of DMSO were added to both vials and then mixed in a third vial. This precursor solution was then stirred at 70° C. for 15 minutes. Subsequently, the solution was cooled down for 5 minutes and filtered with a 0.25 μm PTFE syringe filter to obtain the precursor solution. The precursor solution was dispensed onto the cleaned ITO substrates (120 μL) at room temperature and then spin-cast at 6000 RPM for 30 seconds (6000 acceleration). After 20 seconds of spinning. 300 μL of chlorobenzene (anti-solvent) was added. The film was left in the spin coater for 1 minute and then transferred to a preheated hot plate 100° C. to anneal for 60 minutes.

Preparation of PbI2-poor or near-stoichiometric MAPbI3 films: MAPbI3 films were deposited by weighing ca. 324 mg PbI2, and ca. 102 mg of MAI in air. Both salts were transferred to a hot 2-dram vial (stored at 150° C. in an oven to minimize water content) with a micro stir bar and then immediately loaded into a N2 glovebox. Within the N2 glovebox, 512 μL of DMF and 128 μL of DMSO were added to the vial (generating solution concentrations of ca. 1:1 M for MAI:PbI2, respectively) and then the precursor solution was stirred at 70° C. for 20 minutes. The yellow solution was then allowed to cool down to room temperature and then filtered with a 0.25 μm PTFE syringe filter. The precursor solution was dispensed onto the cleaned ITO substrates (30 μL) at room temperature and then spin-cast at 1000 RPM for 10 seconds (6000 acceleration) followed immediately by 6000 RPM for 20 seconds (6000 acceleration). With five seconds remaining on the spin-coating cycle, 100 μL of chlorobenzene (anti-solvent) was added to the film in a clean dispensing motion as close to the center of the spinning film as possible. All MAPbI3 films were incubated for 1 minute at room temperature in a plastic petri dish with a plastic lid before being transferred to a hot plate for 60 minutes at 100° C. as the final thermal annealing step inside the N2 glovebox. This 1-minute incubation time, followed by the annealing step, ensures conversion to the perovskite product, avoiding excess PbI2 formation. Glovebox atmosphere circulation (i.e., over an internal purifying catalyst) was kept off throughout the film processing steps described above. After each day of experiments, the glovebox atmosphere was purged for ca. 20 minutes before turning back on the purifier circulation (i.e., until the next experiments involving film processing). MAPbI3 films are kept in the N2 glovebox until they are used for surface and electrochemical characterization.

Preparation of IL-based solid electrolyte with and without redox probe: The electrolyte was made by adding 1 g poly (vinylidene fluoride-co-hexafluoropropylene) or PVDF-HFP pellets to 10 g acetone. The solution was stirred overnight in air on a hot plate set at 50° C. When dissolved, 1 mg of the redox probe (ferrocene) is added to the cooled solution. To make a 16 wt % IL containing electrolyte solution, 160 mg 1-ethyl-3-methylimidazolium bis(trifluoromethylsulfonyl)imide or [EMIM][TFSI] (stored in a glovebox) was dissolved in 1 g of the PVDF-HFP/acetone solution. The entire solution was then emptied in a rectangular watch glass (35×40 mm2) and was allowed to dry in air overnight. This solid-type electrolyte with this exact composition has been shown to be a non-solvent for most lead halide perovskite films.

Preparation of perovskite device structures: First, a silver foil (5×13 mm2, 99.9% metals basis, Alfa Aesar) was polished with 4000 grit sandpaper and sonicated in deionized water. Using a two-electrode cell filled with 1 M HCl (ACS, 36-38%, EMD) and a Pt counter electrode, we chlorodized the silver foil at 0.4 V for 2 minutes. Three-electrode sandwich-type perovskite device structures were constructed as a 5-layered stack consisting of an ITO film transparent electrode on glass, a MAPbI3 film as the active layer, a solid electrolyte film (with or without redox probe) wrapped around an Ag/AgCl foil and a gold electrode. The gold electrode was cleaned and sonicated in ethanol (anhydrous, >95%, Decon Laboratories Inc.) before use. The device stack was pressed and kept together using two thin metal plates tightened with four screws. All device structures were assembled and tested in ambient atmosphere.

Perovskite film characterization: θ/2θ X-Ray Diffraction (XRD): For θ/2θ-XRD experiments, MAPbI3 films on ITO were mounted on a clay holder in air and loaded into a Phillips X PERT MPD system, with “PreFIX” source module and a “X'Celerator” detector module, using CuKα radiation (λmax=1.541874 Å) with electron gun cathode-anode power settings of 45 kV at 40 mA). Films were analyzed from 5o to 90o in 2θ with 0.0167o step size, scanning symmetrically (i.e., source and detector at same angle with respect to the surface normal—thus preferentially detecting scattering from crystal planes parallel to the substrate plane) with a total scan time of approximately 35 minutes. Optical hardware settings include a 0.04 rad soller slit (source and detector side), a 2o divergence slit at 140 mm from sample (source side), a 11.6 mm horizontal mask (source side), a 0.02 mm-thick Nickel filter (source side), and an overhead sample beam knife. Processing/Analysis of XRD patterns were performed with X'Pert HighScore (for background subtraction) and Mercury 2020.3.0 software (for identifying Bragg peaks from crystal structure).

Photoelectron spectroscopy: XPS (monochromatic AlKα excitation at 1486.3 eV, 10 mA, 15 KV, pass energy of 20 eV) spectra are acquired at a photoelectron take-off angle of 00, 300 and 600 (normal to the surface) using a Kratos Axis Ultra PES system (Kratos Analytical, USA) in ultra-high vacuum with a base pressure around 2×10−9 Torr. All samples are fixed using carbon tape and grounded to stainless steel stubs. The non-polarized samples are introduced in the spectrometer through an argon-filled glovebox and the polarized samples through a fast port with minimal ambient (ca. 5 min) and light exposure. The XPS binding energy scale is calibrated with sputter-cleaned Cu, Au, and Ag foils. The XPS spectra are processed using the CasaXPS software package (Casa Software Ltd). The raw XPS data undergo a Shirley background correction and all remaining core level peaks are fit to known chemical components using a 70% Gaussian/30% Lorentzian line shape. In order to minimize random errors, relative peak shape, width and shifts are held constant, which is extremely important when multiple species are used to fit a single peak. Comparisons are made by calculating peak area ratios for each element considering their KE-dependent analyzer transfer functions and orbital cross sections, which is basically done by using the instrument-dependent relative sensitivity factors.

UPS (He I excitation at 21.22 eV, pass energy of 5 eV) spectra are acquired at a photoelectron takeoff angle of 90° (normal to the surface). The He discharge lamp (SPECS UVS 10/35, 25 mA) and a chamber pressure of 1×10−7 Torr using ultra high purity (UHP) He that is run through a liquid nitrogen-cooled trap to remove impurities. The sample is biased at −10.0 V to enhance the photoelectron yield at the low kinetic energy edge (LKE). The Fermi energy (EF) is calibrated with sputter-cleaned Au.

Ultraviolet-visible (UV-Vis) spectrophotometry: Absorbance data of the perovskite films were measured using an Ocean Optics Balanced Deuterium Tungsten Source (210-2500 nm) and an OCEAN-FX-XRI fiber optic spectrometer (200-1025 nm) with a 25 μm slit controlled with the Oceanview software package. The perovskite film spectra were collected relative to a bare ITO substrate.

Electrochemistry: The perovskite film is evaluated using a three-electrode configuration using a gold film and an Ag/AgCl foil as a counter and reference electrode, respectively. All voltammograms were recorded using a CH Instruments Electrochemical Analyzer Model 660C potentiostat controlled with the corresponding software package.

Prior to evaluating the perovskite devices, the redox probes were evaluated by cyclic voltammetry at different scan rates (10-500 mV s−1 for 10 cycles) to determine their mass transport and kinetic behavior in the solid electrolyte. Those redox probe test structures consisted of a solid electrolyte film with redox probe wrapped around an Ag/AgCl foil pressed in between two gold electrodes used as a counter and working electrode. These test device stacks were pressed and kept together using two thin metal plates tightened with four screws. All device structures were assembled and tested in ambient atmosphere.

Spectroelectrochemistry: Potential-controlled (CH Instruments Electrochemical Analyzer Model 660C potentiostat) spectroelectrochemical measurements of perovskite films on ITO working electrodes (1 cm2) are recorded using the previously described three-electrode device configuration. The complete device, including the lead halide perovskite film, is placed in the path of the UV-vis spectrophotometer (Ocean Optics system as described above) and a background spectrum is taken after a fixed waiting period (t=5 min) at a potential of −0.5 V vs Ag/AgCl where the perovskite is expected to show the optical and electrical properties of the as-deposited film. Steady-state absorption spectra are acquired after 5 min at defined potentials (20 mV intervals in the bleaching regime around the conduction band) between −0.5 V vs Ag/AgCl to −1.3 V vs Ag/AgCl using the bulk electrolysis feature in the control software.

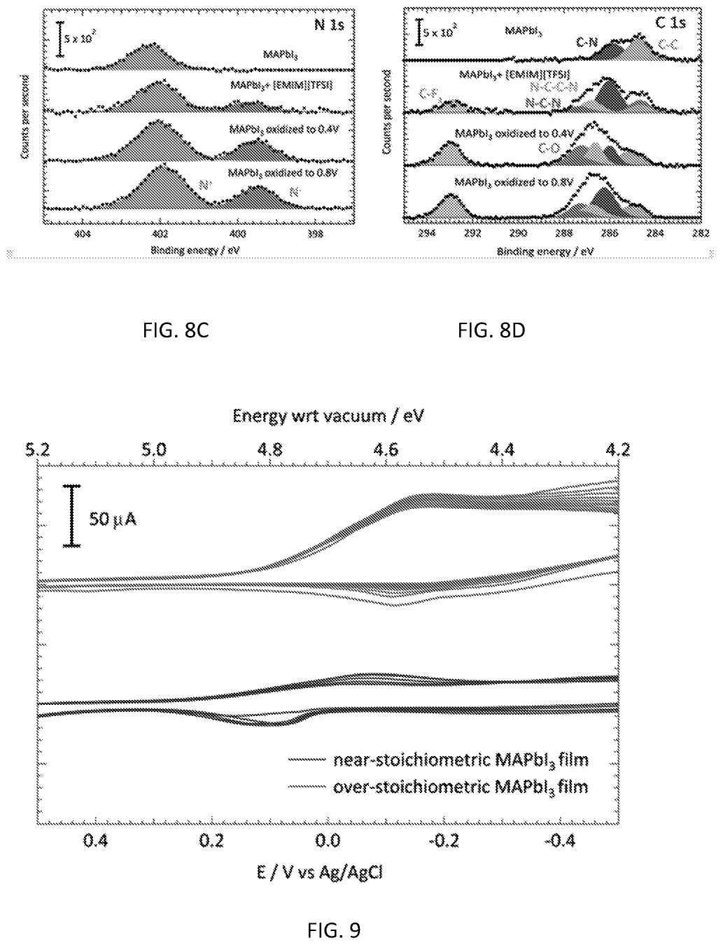

In FIGS. 8A-68, XPS Pb 4f, I 3d, N Is, and C Is core level spectra are recorded for the following, from top to bottom: i) an as-deposited near-stoichiometric MAPbI3 film: ii) a similar MAPbI3 film after a stick and peel with the SE (MAPbI3+[EMIM][TFSI]): iii) a similar MAPbI3 film after oxidation to 0.4 V (˜−5.1 eV wrt vacuum, within the band gap) which is representative of the region where we observe reduction of electrochemically-formed defects in FIG. 7E; and iv) 0.8 V (˜−5.4 eV, at the valence band edge) consistent with Qox region of FIG. 7E. We note the latter two samples also used the peel method to remove the electrolyte after poising at these applied potentials.

Table I provides binding energies, FWHM, chemical origins and elemental concentration for all Pb 4f, I 3d, N Is and C Is high-resolution core level spectra at 0o incident angle shown in Figure S3. Pbδ refers to under-coordinated valence state of Pb, where (0≤δ<2).

TABLE 1

| | | | | | elemental |
|---|---|---|---|---|---|
| sample | photoelectron | BE/eV | FWHM | chemical origin | concentration |
| MAPbI₃ | Pb 4f_{7/2} | 138.1 | 0.891 | Pb^{⊥⊥+} | 9.97 |
| MAPbI₃ + | Pb 4f_{7/2} | 136.6 | 0.891 | Pb^{δ} | 0.64 |
| peel and stick | I 3d_{5/2} | 619.1 | 1.061 | I⁻ | 31.20 |
| electrolyte | N 1s | 402.1 | 1.151 | ammonium salt | 12.20 |
| | C 1s | 284.8 | 1.132 | aliphatic carbon | 25.94 |
| | | 286.1 | 1.132 | C—N | 20.05 |
| | Pb 4f_{7/2} | 138.2 | 0.896 | Pb^{⊥⊥+} | 2.25 |
| | Pb 4f_{7/2} | 136.6 | 0.896 | Pb^{δ} | 0.09 |
| | I 3d_{5/2} | 619.0 | 1.160 | I⁻ | 6.40 |
| | N 1s | 401.6 | 1.277 | ammonium salt | 9.77 |
| | | 399.3 | 1.277 | N⁻ | 3.11 |
| | C 1s | 284.8 | 1.052 | aliphatic carbon | 6.55 |
| | | 286.2 | 1.052 | C—N | 17.75 |
| | | 286.8 | 1.052 | N—C—C—N | 6.55 |
| | | 287.5 | 1.052 | N—C—N | 3.28 |
| | | 293.1 | 1.000 | C—F₃ | 6.55 |
| | F 1s | 689.1 | 1.740 | C—F₃ | 20.58 |
| | S 2p_{3/2} | 169.3 | 1.125 | O—S—O | 3.37 |
| | O 1s | 532.9 | 1.564 | O—S—O | 13.72 |
| MAPbI₃ | Pb 4f_{7/2} | 138.2 | 0.909 | Pb^{⊥⊥+} | 0.89 |
| oxidized to | Pb 4f_{7/2} | 136.5 | 0.909 | Pb^{δ} | 0.12 |
| 0.4 V | I 3d_{5/2} | 619.1 | 1.117 | I⁻ | 2.41 |
| | N 1s | 402.0 | 1.366 | ammonium salt | 8.53 |
| | | 399.5 | 1.084 | N⁻ | 3.57 |
| | C 1s | 285.0 | 1.224 | aliphatic carbon | 5.31 |
| | | 286.3 | 1.224 | C—N | 9.45 |
| | | 286.8 | 1.224 | N—C—C—N | 5.31 |
| | | 287.3 | 1.224 | N—C—N | 2.66 |
| | | 287.3 | 1.224 | C—O | 4.04 |
| | | 293.0 | 1.224 | C—F₃ | 8.63 |
| | F 1s | 689.0 | 1.716 | C—F₃ | 29.92 |
| | S 2p_{3/2} | 169.1 | 0.987 | O—S—O | 3.84 |
| | O 1s | 532.8 | 1.271 | O—S—O | 15.30 |
| MAPbI₃ | Pb 4f_{7/2} | 138.2 | 0.866 | Pb^{⊥⊥+} | 0.78 |
| oxidized to | I 3d_{5/2} | 619.0 | 1.072 | I⁻ | 2.48 |
| 0.8 V | N 1s | 401.9 | 1.378 | ammonium salt | 9.39 |
| | | 399.5 | 1.125 | N⁻ | 4.00 |
| | C 1s | 284.9 | 1.150 | aliphatic carbon | 4.76 |
| | | 286.2 | 1.150 | C—N | 11.09 |
| | | 286.8 | 1.150 | N—C—C—N | 4.76 |
| | | 287.3 | 1.150 | N—C—N | 2.38 |
| | | 287.3 | 1.150 | C—O | 5.17 |
| | | 293.0 | 1.150 | C—F₃ | 8.20 |
| | F 1s | 689.0 | 1.720 | C—F₃ | 28.95 |
| | S 2p_{3/2} | 169.0 | 0.995 | O—S—O | 3.66 |
| | O 1s | 532.8 | 1.329 | O—S—O | 14.39 |

Complementary data for Ols and Fls core levels were also collected. In FIGS. 8A-8D peaks are fit to known chemical components following a 70% Gaussian/30% Lorentzian line shape. The C ls deconvolution is based on the N—C—N:C—N:N—C—C—N:C—C ratios, which are 1:2:2:1 in the EMIIM cation. For the solid electrolyte pool, the C—C peak was based on the N—C—N peak area and carbon contamination. After oxidation, the C—C peak is reduced compared to the N—C—N contribution, which suggests formation of oxidized species so that the N—C—N peak is based on the C—C peak area and an extra C—O contribution. Table 1 provides peak assignments, relative binding energies, full width half maximums of the fitted peaks, and percent composition after correction for relative sensitivity factors for the XPS instrumentation as described above.

Table 2 provides relative atomic ratios from Pb 4f, I 3d, N ls and C ls core level spectra for an as-deposited MAPbI3 film, as a function of take-off angle in the XPS experiment (angle-resolved XPS, AR-XPS). The atomic ratios for Pb 4f core level spectra are calculated using Pb=Pbperovskite+Pbδ.

TABLE 2

| | | | | expected |
|---|---|---|---|---|
| | ratio/0° | ratio/30° | ratio/60° | ratio |
| I/Pb | 3.13 | 3.02 | 2.44 | 3 |
| Pb^{δ}/Pbₚₑᵣₒᵥₛₖᵢₜₑ | 0.06 | 0.09 | 0 | — |
| N/Pb | 1.22 | 1.19 | 1.12 | 1 |
| C/N | 1.64 | 1.55 | 1.48 | 1 |

Table 3 provides relative atomic ratios from Pb 4f, I 3d, N ls, F ls, O ls and C ls core level spectra of an as-deposited MAPbI3 film after stick and peel with the solid electrolyte, as a function of take-off angle in the XPS experiment (angle-resolved XPS, AR-XPS). The atomic ratios for Pb 4f core level spectra are calculated using Pb=Pbₚₑᵣₒᵥₛₖᵢₜₑ+Pb^{δ}.

TABLE 3

| | | | expected |
|---|---|---|---|
| | ratio/0° | ratio/60° | ratio |
| I/Pb | 2.84 | 3.18 | 3 |
| Pb^{δ}/Pbₚₑᵣₒᵥₛₖᵢₜₑ | 0.04 | 0 | — |
| F/O | 1.49 | 1.45 | 1.5 |
| F/C | 3.14 | 2.54 | 3 |
| O/C | 2.09 | 1.75 | 2 |
| N⁻/O | 0.23 | 0.13 | 0.25 |
| MA^{a}/Pb | 1.51 | 2.55 | 1 |

More detailed comparisons are described based on the calculation of the elemental ratios for all samples for AR-XPS spectra at 0° , 30° and 60° take-off angle in Tables 3-5. First, the Pb/I ratio for the as-deposited MAPb₃ film shows a low surface iodide ratio, which suggests slow corrosion of iodide defects to gaseous I2 leaving behind reduced, under-coordinated Pb^{δ.S2} Here, δ refers to a valence state for lead that is greater than zero but less than two (0≤δ<2). This is consistent with the observed PbI2 signatures in the XRD and UV-vis data in FIG. 5A and 5B. When we stick and peel the SE to/from the MAPbI3, the absolute intensities of the Pb and I CL spectra are attenuated—a residual SE/IL film is left behind with a thickness estimated to be ca. 25 Å following equation (1).

$$t = - ln ( \frac{I}{{I}_{0}} ) λ cos θ \qquad ( 1 )$$

with I₀ is the maximum intensity of element in the substrate, I is the maximum intensity of element in the substrate and top layer, t is the thickness, θ is the take-off angle normal to the surface and λ is the electron inelastic mean free path based on calculations in literature. The Pb/I elemental ratios at the surface are closer to those expected for as-deposited MAPbI₃, suggesting removal of a non-stoichiometric region from the as-deposited thin film. A near 1:1 EMIM/TFSI ratio is also observed using the N ls, C ls, and F ls signatures in Table 1, and we propose that the post-peel residual ionic liquid thin film is interacting strongly enough with the nearly stoichiometric MAPbI₃ film to be retained, and could be stabilizing the surface (ex. stabilizing grain boundaries).

With the knowledge that the SE itself is not degrading the surface, we have created a reliable method to study electrochemical processes at the perovskite interface. For example, by matching the i/V curves in FIG. 6C (panel i) with the calculated elemental ratios measured at the MAPbI₃ surface after controlled oxidation (observations only after the forward scan) gives clear evidence of iodide movement from the near-surface region to the bulk, as previously described. Tables 4 and 5 show a reduction in the surface concentration of iodide. Indeed, the Pb/I ratio at 0° is highest for the film oxidized to 0.8 V. The oxidation process within the valence band might also explain the loss in Pb^{δ} species. We validate this band bending and ion migration mechanism with a direct link to the hole injection process in the CV in FIG. 7A. Specifically, the electroactive defects are able to move to and from the perovskite/electrolyte interface depending on the electric field. From the MA/Pb ratio, we conclude that simultaneously MA cations at the interface are pushed into the electrolyte with almost none left at 60⁰ take-off angle. After oxidation, the 1:1 EMIM/TFSI ratio shifts due to an increase in the C-F₃ peak compared to the N—C—N and N—C—C—N contributions in the C ls spectrum, indicating that the electric field pushes TFSI anions towards the MAPbI3 surface. Contrarily, (N)—C—(C)—N contributions of EMIM cations decrease, which could suggest cations are either repelled at anodic potentials from the semiconductor surface and/or are located in a buried interface (ex. grain boundary). Lastly, this oxidation process in ambient conditions generates an extra C—O contribution in combination with a drop in C—C contribution. As gel was removed in ambient, we cannot conclude if the reaction is associated with the redox activity of the semiconductor with the gel or due to ambient gas reactions post gel removal. However, this contribution is low, and we can still conclude our electrochemical approach with photoelectron spectroscopy measurements has allowed us to do a detailed post-mortem characterization of these MAPbI₃ films under stress.

Table 4 provides relative atomic ratios from Pb 4f, I 3d, N ls, F ls, O ls and C ls core level spectra of an as-deposited MAPbI₃ film oxidized to 0.4 V, as a function of take-off angle in the XPS experiment (angle-resolved XPS, AR-XPS). The atomic ratios for Pb 4f core level spectra are calculated using Pb=Pbₚₑᵣₒᵥₛₖᵢₜₑ+Pb^{δ}. The contribution for MA is calculated by assuming a 2:1 N⁺/N⁻ area ratio in the N ls core level peak, which considers a 1:1 EMIM/TFSI ratio which is rough estimate.

TABLE 4

| | | | | expected |
|---|---|---|---|---|
| | ratio/0° | ratio/30° | ratio/60° | ratio |
| I/Pb | 2.67 | 2.78 | 2.06 | 3 |
| Pb^{δ}/Pbₚₑᵣₒᵥₛₖᵢₜₑ | 0.13 | 0.22 | 0.15 | — |
| F/O | 1.95 | 2.02 | 1.99 | 1.5 |
| F/C | 3.47 | 4.05 | 2.91 | 3 |
| O/C | 1.77 | 2.01 | 1.46 | 2 |
| N⁻/C | 0.41 | 0.47 | 0.46 | 0.5 |
| MA^{a}/Pb | 1.38 | 1.49 | 0.17 | 1 |

Table 5 provides relative atomic ratios from Pb 4f, I 3d, N ls, F ls, O ls and C ls core level spectra of an as-deposited MAPbI₃ film oxidized to 0.8 V, as a function of take-off angle in the XPS experiment (angle-resolved XPS, AR-XPS). The contribution for MA is calculated by assuming a 2:1 N⁺/N⁻ area ratio in the N Is core level peak, which considers a 1:1 EMIM/TFSI ratio which is rough estimate.

TABLE 5

| | | | | expected |
|---|---|---|---|---|
| | ratio/0° | ratio/30° | ratio/60° | ratio |
| I/Pb | 3.20 | 2.16 | 2.07 | 3 |
| F/O | 2.01 | 1.83 | 1.99 | 1.5 |
| F/C | 3.53 | 2.55 | 2.91 | 3 |
| O/C | 1.75 | 1.39 | 1.46 | 2 |
| N⁻/C | 0.48 | 0.35 | 0.46 | 0.5 |
| MA^{a}/Pb | 1.78 | 1.49 | 0.17 | 1 |

Relevant redox potentials (vs Fc/Fc⁺ and Ag/AgCl QRE) of the iodide/triiodide redox system. ^{a}The pseudo reference electrode potential was calibrated against the formal potential of the IUPAC recommended Fc/Fc⁺ process in the electrolyte of interest, taking into consideration the difference in the diffusion coefficients of Fc and Fc⁺. ^{b}An overall shift of +0.15 V vs Fc/Fc⁺ is seen in the solid electrolyte compared to the reference potential in acetonitrile.

TABLE 6

| | E⁰ vs | E⁰ vs | | E_{ref}/V | |
|---|---|---|---|---|---|
| | Fc/Fc⁺/V | Ag/AgCl/V^{a} | reaction | (in ACN)^{b} | references |
| E⁰(I₃⁻/I₂⁻) | −0.6 | −0.5 | I₃⁻ + e⁻ ↔ I₂⁻ + I⁻ | <−0.95 | Boschloo |
| | | | | | and Hagvelt |
| E⁰(I₃⁻/I⁻) | −0.1 | 0 | I₃⁻ + 2e⁻ ↔ 3I⁻ | −0.25 | Bentley |
| | | | | | et al. |
| E⁰(I₂⁻/I⁻) | 0.55 | 0.65 | I₂⁻ + e⁻ ↔ 2I⁻ | 0.3 | Wang et al. |
| E⁰(I⁻/I⁻) | 0.8 | 0.9 | I⁻ + e⁻ ↔ 2I⁻ | 0.6 | Boschloo |
| | | | | | and Hagvelt |
| | | | I₃⁻ + hν ↔ I₂⁻ + I⁻ | | Roy et al. |

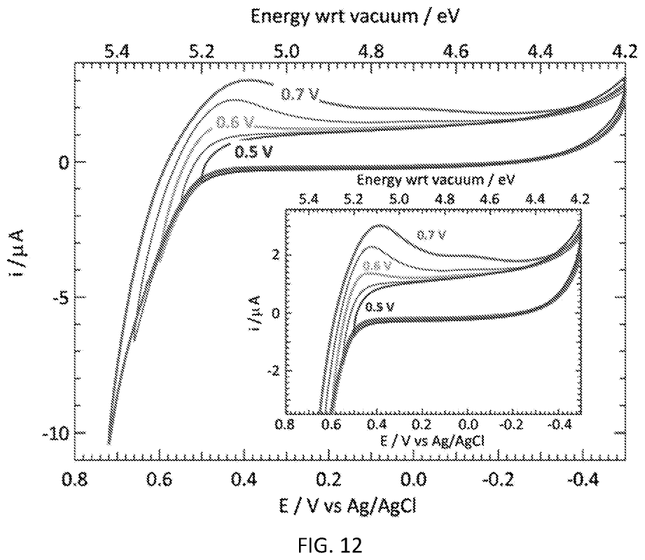

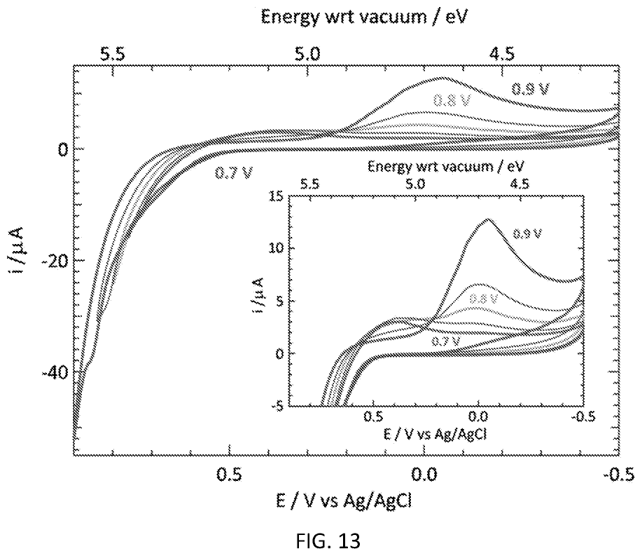

Valence band electrochemistry: Defect quantification requires a systematic comparison in currents based on applied potential. To do this using cyclic voltammograms, we systematically increased the size of the potential window. We note all “endpoints” for cathodic potentials in this experiment were fixed at −0.5 V (vs. Ag/AgCl). A specific anodic “end potential” was set, starting first with 0.4 V vs. Ag/AgCl. In FIGS. 7A-D and in FIG. 11, FIG. 12 and FIG. 13, we conducted five consecutive cyclic voltammograms between cathodic and anodic end potentials. Then the anodic potential was increased by 50 mV, and the experiment was conducted again, for anodic end potentials from 0.4 to 0.9 V. The total cyclic voltammograms conducted was then 55 CVs, all at a scan rate of 0.05 V/s. We note that in the presence of the redox probe Fc within the solid electrolyte, no hysteresis was observed between the five consecutive CVs for each potential window, clearly indicating the analysis was not inducing additional defects other than what exists in the active layer. It is possible that some defects could have been passivated and/or slight changes the surface chemistry could have occurred prior to the cyclic voltammetry experiments, as indicated in Supplementary Note 1. FIGS. 11, 12 and 13 show three different ranges of potential windows, described as the anodic potential endpoints relative to the onset in the valence band (0.7 V vs Ag/AgCl):

1. Above valence band anodic end potentials (0.4 to 0.5 V vs. Ag/AgCl): There is no observation of defect reduction and no observation of Fc+reduction.

2. Near valence band anodic end potentials (0.5 to 0.7 V vs. Ag/AgCl): There is clear evidence of defect reduction on the cathodic sweep, but minimal observation of Fc+reduction. A small Fc⁺ reduction peak is observed for the 0.7 V anodic end potential CV (green curve).

3. Valence state oxidation (0.7 to 0.9 V vs. Ag/AgCl): Increasing the number of valence states that are oxidized shows a systematic increase in reduction current of Fc⁺ as well as a decrease in the reduction of defects.

Defect quantification: In FIGS. 7A-E, 11, 12 and 13, the collective data indicates that oxidation includes charges (Q) extracted from three events, depending on potential: oxidation of defects (Q_{ox,defects}), oxidation of ferrocene (Q_{ox,Fc}) and oxidation of valence states (Q_{ox,valence}). From FIGS. 11, 12 and 13, defect oxidation occurs first (at lowest oxidation potentials), followed by oxidation of ferrocene and valence band states. We note that one cannot assume that oxidation is purely reversible, but one can quantify the amount of carriers in the reductive waves (Q_{red}), which includes the reduction of defects (Q_{red,defects}) and reduction of ferrocenium (Q_{red,Fc+}) to approximate defects. In FIG. 7E, we show one CV scan as measured in FIG. 7A which includes color shading to highlight key regions of interest, including distinguishing between Faradaic and non-Faradaic contributions. In FIG. 7E, the non-Faradaic charging in the perovskite band gap is indicated in white and is considered background current due to double-layer capacitive contributions. In the forward scan, surface defects are (ir)reversibly oxidized and are pinned to Fc with the formation of Fc⁺ together in a single oxidation peak (Qₒₓ, green). Interestingly, in the reverse scan, reductive peaks appear as energy-separated cathodic peaks. Briefly, at low anodic potentials, Faradaic current is ascribed to defect reactions, most likely I⁻ oxidation events. Fermi-level pinning refers to the equilibrium condition of a semiconductor surface which is different from the equilibrium condition in the bulk. This free surface, or interface, of the semiconductor contains a continuum of localized energy states within the band gap that are either occupied by electrons or empty. Because, in equilibrium, the Fermi level must be a constant throughout the semiconductor, the semiconductor bands bend at the surface.

From FIG. 7E, a fraction of the defects can be reversibly reduced in the cathodic sweep, assumed to be due to hole transfer from the valence band. The shallow lying level of the defects is consistent with the defect tolerant MAPbI₃ energy diagram (Q_{red,defects}, blue), where the valence band lies at 5.5 eV and the defect density is centered at 5.4 eV. When enough defects are generated, band bending occurs within the near-surface region of the perovskite and facilitates Fc reduction (Q_{red,Fc+/Fc}, magenta). For all CV scans, the total oxidation charge is higher compared to the individual contributions, which means that all extra charge is considered to be part of an irreversible oxidation process.

By shifting the maximum oxidation potential, E_{ox.end}, as shown in FIG. 6A, all these individual Faradaic processes can be quantified by calculating the charge under the curve by integrating the current equation (1) to provide the following equation (2).

$$Q = {\int }_{{t}_{0}}^{{t}_{1}} i dt = \frac{{\int }_{{V}_{0}}^{{V}_{1}} i dV}{v} \qquad ( 2 )$$

In FIG. 7E, the calculated charge contributions are plotted as a function of E_{ox.end} revealing very interesting relationships. In FIGS. 16A, 16B and 16C, we show the residuals after fitting Qₒₓ and Q_{red,Fc/Fc+} with an exponential fit and Qred.defects with a Gaussian distribution. In what follows, we explain the choice for these distributions. The oxidation process follows an exponential increase with potential, consistent with Marcus-Gerischer theory for n-type materials, where the exponential term originates from the assumption that the fluctuation of the solvent molecules or dipoles is assumed to behave like a harmonic oscillator. Shifting E_{ox,end} continuously probes an increased number of defects are immediately reduced back in the reverse scan unless they pin to the Fc⁺ in the electrolyte. Indeed, around 0.7 V vs Ag/AgCl, generated defects pin to Fc⁺ causing a drop in the Q_{red,defects} contribution, which eventually disappears, explaining the fitted Gaussian distribution. From the maximum, with the assumption of a dielectric constant of 18, a carrier density of 2.8×10²³ m⁻³, and an estimate of the contact area (0.8 cm²), we calculate a depletion width of 9.23×10⁻⁶ cm using equation (3).

$$t = \sqrt{\frac{2 {ε}_{r} {ε}_{0}}{e} {V}_{0} \frac{1}{{N}_{D}}} \qquad ( 3 )$$

with dielectric constant ϵᵣ, vacuum permittivity ϵ₀, elemental charge e and built-in voltage V₀ for a device to measure carrier density N_{D}. We note that the carrier density depends on the MAI:PbI₂ precursor ratio and varies between 10¹⁴ to 10¹⁸ cm⁻³.^{S16,S17} Finally, we predict a defect density N_{defect} of 2.14×1017 cm⁻³ at 0.72 V using equation (4).

$${N}_{defect} = \frac{number of defects}{At} \qquad ( 4 )$$

with the number defects=Q_{red,defects}/e and area A. Because defects are pinning to Fc⁺ to form Fc, this reduction process depends on the defects formed in the oxidation process, which explains why both redox reactions follow the same exponential distribution.

Another aspect of various embodiments of the present invention generally relates to a device and a method for an in situ and/or operando electrochemical analysis for determining various characteristics of electronic materials and semiconductor materials. However, for the sake of clarity and brevity, the present invention will now be described with respect to determining various characteristics of metal halide perovskites during its roll-to-roll manufacturing process. It should be appreciated: however, devices and methods of the invention are applicable to electrochemically analyzing any electronic devices and semiconductor materials during manufacturing or in operando conditions. Accordingly, the scope of the invention includes using devices and methods of the invention for characterizing via electrochemical analysis of any and all suitable electronic devices and semiconductor material manufacturing processes.

In the last decade, interest in the use of metal halide perovskites in optoelectronic materials has surged tremendously as a roll-to-roll coatable material in high-performance optoelectronic devices, ranging from solar cells, photodetectors, and ionizing radiation detectors to light-emitting diodes (LEDs) and lasers, as well as to memories and solar-to-fuel conversion fields.

Characterization of electronic defects in metal halide perovskite materials and at its interfaces is critical for the optimization and long-term stability of optoelectronic devices. Electrochemical approaches offer unprecedented limits of detection under relevant in situ and operando conditions, with a direct connection to underlying defect chemistry and energy levels.

Embodiments of the present invention provides devices and methods using a solid electrolyte that can optionally include a redox active specie for a solvent-free electrochemical analysis. Suitable solid electrolytes are disclosed in a commonly assigned U.S. provisional patent application No. 63/209,339, filed Jun. 10, 2021, which is incorporated herein by reference in its entirety.

In general, devices and methods according to embodiments of the present invention allow one to measure various characteristics, such as the number of defects (point or planar defects), where (spatially) they reside, what chemical signature they have, if they move around in dislocations or at surfaces, and influence performance loss through radiative recombination or recombination through defect levels, etc., of electronic devices and semiconductor materials during manufacturing processes and during their use. These characteristics can be readily determined during the application of stress to the active layer, including but not limited to, demanding temperatures and rapid temperature changes, mechanical stress, changes in ambient environments, and other harsh conditions, which are integral components of high throughput manufacturing. At present, answering these types of questions is difficult because of limited spatial and temporal resolution and (electro)chemical sensitivity of available in situ and operando characterization tools, and because those approaches may be sensitive to defects which are not necessarily relevant to device performance and device lifetime, whereas the approach and technologies described here specifically characterize reactive defects which ultimately limit device lifetime and performance.

Devices and methods according to embodiments of the present invention provide a solid-state-based electrochemical technique that is able to provide various characteristics and measure film quality in device manufacturing. In some embodiments, devices and methods of the invention are used in combination with X-ray and PL characterization.

As illustrated herein, in one particular embodiment, devices according to embodiments of present invention utilize a solid electrolyte and a three-electrode based electrochemical cell for characterization and analysis of semiconductor materials during manufacturing process or in operando conditions. Accordingly, devices and methods according to embodiments of the present invention provide one to replicate real-time operating conditions, study chemical processes under load, measure the influence of external factors (such as temperature, light, H2O and O2) and evaluate photoactive layers or photoactive/transport layer device stacks off-line, but also as an inline sensor. Additionally, devices and methods of the invention allow one to study microstructural responses and changes at the local scale (with nanometer special resolution) under process conditions using electrochemical cells.

For inline quality control, a removable stamp or electrochemical probe (10), can be placed at any point in time and space along the roll-to-roll manufacturing line, as illustrated in FIG. 1. The probe or stamp (10) includes a counter electrode (200) attached to a thin film of a solid electrolyte (300), which is pressed onto the film or a semiconductor active layer (700) under study. By introducing a reference electrode (400) in contact with the solid electrolyte (300), measured electrochemical potentials are correlated to orbital energy levels with appropriate approximations, which allows mapping of the electronic structure and density of states of semiconductive materials (704) including surface defects. A needle, pushpin, or pipette (504) is used as a working electrode (500) connecting the underlying conductive substrate (708) to complete the electrochemical cell. A voltametric scan allows direct detection of defects and layer quality, measurement of electrical properties to ensure proper functionality and thus the possibility for repair/correction, product testing, etc., which are crucial elements in the inspection and quality control of roll-to-roll manufactured perovskite solar devices. Pulse-based voltammetry enhances the energetic resolution and brings the sensitivity for defect detection (limit of detection, LOD) down to ca. 1014 cm−3 under optimal measurement conditions, and LODs under all conditions of ca. 1015 cm−3, and often to less than about 1015 cm−3, thereby allowing the manufacturing of photovoltaic devices be further optimized for semiconductor materials with low defect concentrations.

By placing this removable stamp or probe (10)) at different positions within the roll-to-roll coating system, quality control, under the form of electrochemical properties, is enabled for all individual films or film stacks in photovoltaic devices before the devices are fully completed. In one particular embodiment, the quality of individually coated HTLs/ETLs, HTL/perovskite or ETL/perovskite film stacks and HTL/perovskite/ETL or ETL/perovskite/HTL device stacks can be analyzed in situ during their manufacturing process. These electrochemical measurements provide important electronic and chemical information about the semiconductor film/stack under study, such as going from number of defects and density of states to chemically active and mobile species and interfacial and/or surface interactions. Additionally, the physical processes such as drying, ordering, crystallization and surface tension can also be analyzed as a function of position and solution processing method all within real-time manufacturing operation. Since devices and methods of the invention provide heretofore untenable levels of quality analysis, devices and methods of the invention can be used to improve all parameters during manufacturing process, including but not limited to, oven temperature, substrate speed and distance from oven, ambient environments, etc.

In one particular embodiment, devices of the invention include a “peel-and-stick” electrochemical probe (10) that includes a solid-electrolyte layer (300) comprising an ionic liquid (SE/IL), combined with voltage control and analysis of resultant current/time responses. This analysis technique enables unique characterization of extremely low concentrations of chemically reactive defects in thin film semiconductors. In addition, the SE/IL probe provides for rapid quantification of efficiency- and stability-relevant defect densities at levels below those achievable with either photoelectron or optical (UV/VIS/NIR) spectroscopies. Furthermore, the SE/IL probe, in combination with an integrated reference electrode (400) and counter electrode (200), connected to a potentiostat (600), acts as a device top contact during real-time, in-line processing of semiconductor active layers (700), allowing for defect characterization under bias, and added stress such as light exposure, exposure to low levels of water (H2O) and oxygen (O2), thermal gradients, and changes in shape of the device platform (mechanical stress).

In another embodiment, the SE/IL probe also characterizes injection and extraction barriers between multi-layer stacks (e.g., metal oxide and a printed semiconductor, which may be a metal halide perovskite, a pi-conjugated polymer or molecular material or blend, colloidal quantum dots, nanoparticles, etc.).

An electrolyte filled nano-pipette or needle tipped (504) working electrode (500), connected to an external potentiostat (600) and appropriate piezo-control of x,y position, provide for characterization of spatial heterogeneities in defect density and energetics, at nanometer length scales (e.g., about 500 nm or less, typically about 250 nm or less, often about 100 nm or less, more often about 50 nm or less, and most often about 25 nm or.

Applications for methods and devices of the invention include, but are not limited to, in situ manufacturing analysis of and in operando analysis of various (opto)electronic and/or (photo)electrochemical devices and/or systems, such as but not limited to solar cells, photodetectors, light emitting diodes, fuel cells, transistors, sensors, batteries, and capacitors.

One particular embodiment of the invention is directed to in-line quality control using a device and/or a method of the invention. Such quality control includes fixed position electrochemical analysis as well as a removable, portable electrochemical probe, which can be placed at any point in time and space along the roll-to-roll manufacturing line as illustrated in FIG. 2. This method is also amenable with ultra-high or moderate vacuum-based deposition techniques including, but not limited to, chemical or physical vapor deposition, atomic layer deposition, or sputtering approaches.

Briefly, in operation, referring to FIG. 1, the electrochemical probe (10) includes a counter electrode (200) attached to a thin film of a solid electrolyte (300), which is pressed onto the semiconductor film (700) or multilayer stack of interest. A reference electrode (400) is in contact with the solid electrolyte (300). A needle/pushpin (504) is used as a working electrode (500) connects the underlying conductive substrate (708) to complete the electrochemical cell. The measured electrochemical potentials are then correlated to orbital energy levels, which allows mapping of the energetics, electronic structure and density of states of semiconductive materials (700) including surface and near-surface defects. Typically, a simple voltametric scan (e.g., linear change of and/or pulsed applied potential with time) then allows direct detection of defects and layer quality, measurement of electrical properties to ensure proper functionality and thus the possibility for repair/correction, product testing, etc., which are some of the important elements in the inspection and quality control of roll-to-roll manufacturing process of perovskite solar devices.

As discussed in more detail below; voltage-pulse-based voltammetry, which enhances sensitivity to charge transfer versus charge displacement events, enhances the energetic resolution and brings the sensitivity for defect detection down to about 1015 cm−3, so that the manufacturing of (opto)electronic devices can be further optimized for semiconductor materials with low defect densities.

The electrochemical probe (10) of the invention can be put at different positions within the roll-to-roll coating system or deposition system. Quality control, in the form of measured electrochemical properties, is enabled for individual films or film stacks in opto-electronic devices before the devices are fully completed. In addition, devices and methods of the invention can be used to analyze the quality of individually coated layers or multilayer stacks of materials, such as for example. a metal halide perovskite solar cell which consists of a transparent conductive oxide (TCO), a hole-transport layer (HTL), a buffer layer, metal halide perovskite, second buffer layer, electronic transport layer and top metal contact.

Devices and methods according to embodiments of the present invention provide both electronic and chemical information about the semiconductor film/stack under study going from number of defects and density of states to chemically active and mobile species and interfacial and/or surface interactions. When coupled with other spectroscopy methods (e.g., X-ray photoelectron spectroscopy and/or photoluminescence spectroscopy), methods of the invention can provide addition information such as chemical and electronic information.

Devices and methods according to embodiments of the invention can also be used to study physical processes such as drying (loss of processing solvents), crystallization, enhancement in crystal coherence over nanometer to micron length scales, and surface tension (tensile and compressive stress). Such information can be studied as a function of position and solution processing method all within real-time manufacturing operation. Other parameters such as oven temperature, substrate speed and distance from oven can be optimized by using devices and methods of the invention as a quality control. Devices and methods of the invention can also be used in post-deposition processes and failure analysis under stress. Examples of additional stressors can include ambient gasses, oxidants, temperature, light, etc.

Devices and methods according to embodiments of the invention have many advantages including, but not limited to, enabling in-line quality control and non-destructive analysis of semiconductor materials and (opto)electronic devices, providing information that allows rapid commercialization of laboratory benchtop processes, allowing observation of processes under conditions that replicate real-world and real-time conditions, allowing operando characterization (i.e., direct visualization and characterization of processes in real time). Furthermore, as stated herein, devices and methods according to embodiments of the invention can be used in combination with complementary techniques for degradation and failure analysis of materials and layers.

In other embodiments, devices and methods of the invention provide an analytical tool that can follow chemical reactions, physical processes, microstructural changes, and interfacial phenomena in environments that mimic real-world conditions, as illustrated in FIG. 19, which shows degradation analysis of the valence band of a triple cation perovskite (CsFAMA) film using operando setup in combination with grazing incidence wide angle X-ray scattering. Still in other embodiments, devices and methods of the invention provide state-of-the-art multi-model characterization capability to follow (electro)chemical (intermolecular interactions, interfacial processes, defects) and physical (drying, crystal formation, surface tension) processes during the roll-to-roll manufacturing operation across length and time scales or to understand device-transport layer interactions. Some of the information that can be produced using devices and methods of the invention include, but are not limited to, how many defects (point or planar defects) are present, where they reside, what chemical signature they have, if they move around in dislocations or at surfaces, and influence performance loss through radiative recombination or recombination through defect levels. Such information can be valuable in adjusting various parameters in manufacturing processes to reduce the concentration of defects as well as serving as a quality control for producing a higher quality of (opto)electrical devices. Other conditions such as stress and temperature differences, which are integral part of high throughput manufacturing, can also be studied and optimized. Devices and methods of the invention can also provide information about material impurities or defects, and its data can be used to optimize existing production processes by looking at the photoactive layer, which helps set blade or slot-die coating parameters such as blade speed and height or pumping rate and coating speed.

Another aspect of embodiments of the present invention provides a method for determining defects in semiconductor materials at a level of at greater than about 1013 cm−3, typically at least about 1014 cm−3, and often at least about 1015 cm−3.

Quantification of performance- and stability-defining defects in semiconductor materials (e.g., hybrid organic-inorganic metal halide perovskites) is of significant interest in materials and device development but can be incredibly challenging as defect concentrations are typically well below levels of sensitivity for many spectroscopic, electrical and computational approaches. Critical to viable defect quantification approaches are energy-resolution, connections to chemical origins, and under operando conditions or during device processing at commercially viable speeds and scale. Electrochemical methods offer unprecedented levels of sensitivity, with prior results on methyl ammonium lead triiodide having defects of 0.1 eV above the valence band at a concentration 2×1017 cm−3. For more stable, defect-tolerant and device relevant triple cation perovskites, where chemically reactive defect densities are much lower, an alternative approach is required.

Methods of the invention include putting perovskites “under stress” by applying a linearly changing potential, and then using differential pulse voltammetry on the return sweep to differentiate defect-associated Faradaic redox processes from charging currents due to ion migration. This approach studies dark hole injection and quantifies free I3-generated at these defect sites by enhancing the energetic resolution in defect identification and bringing the sensitivity for reactive defect detection down to at least about 1×1015 cm−3, thereby allowing further device optimization. Differential pulse voltammetry detects defects at 1 to 3 orders of magnitude below typical electrical and spectroscopic measurements. Methods of the invention lends itself to operando and in situ defect characterization during processing, at scale, of variety of semiconductor materials including, but not limited to, perovskite and related optoelectronic platforms.

Additional features and benefits of the present invention will become apparent to those skilled in the art upon examination of the following examples thereof, which are not intended to be limiting. In the Examples, procedures that are constructively reduced to practice are described in the present tense, and procedures that have been carried out in the laboratory are set forth in the past tense.

### EXAMPLES

Lead halide perovskite materials have demonstrated viability in multiple next-generation flexible optoelectronic (energy conversion) devices due to ease in bandgap engineering, their high-power conversion efficiencies, and their amenability for large-scale processing through solution and/or vacuum deposition approaches. One major materials challenge is that the materials are metastable and highly sensitive to local processing conditions. Defects exist often within the bandgap and in equilibrium with the stoichiometric, quasi-stable bulk perovskite, and can only be detected by putting the active layer “under stress” away from equilibrium conditions. For example, triple cation lead halide perovskites based on a combination of inorganic (i.e., cesium) and organic (i.e., methyl ammonium and formamidinium: MA and FA, respectively) in the B-site consistently demonstrate highly monolithic crystalline grains with increased absorption, fewer apparent grain boundaries and physical dislocations than single B-site cation perovskites. CsFAMA is demonstrated to be two orders of magnitude lower than in MAPbI3 perovskites, this ion movement is likely to be coupled to dark or photoinduced redox activity leading to long-term degradation and performance limitations. These unique properties have been associated with decreased interfacial charge recombination rates, improved stability, and PCEs consistently above 20%. More broadly across optoelectronic device platforms, defects are generally associated with phase instabilities and ion movement that are exacerbated under photon flux, heat, humidity, and/or electrical bias.

Without being bound by any theory, it is believed that once ions such as the halides (I-, Br-) leave the lattice, they propagate through the active layer not only as defects which can increase recombination velocities, but also as (redox) active (long term stability defining) chemical species. Regardless of end-use, techniques are needed to characterize and control reactive defect populations at extremely low concentrations, in order to improve device performances and long-term stability.

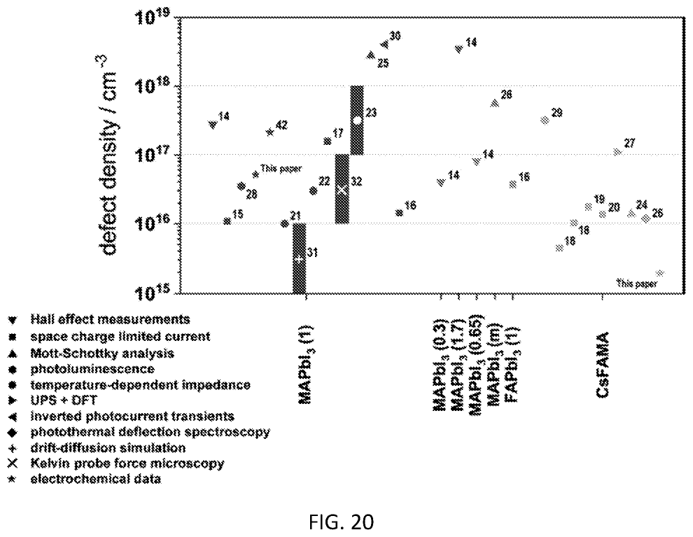

Quantifying the concentration and energetics of defects in the most stable perovskite active layers is one of the key factors in optimizing performance. To achieve this goal, there has been a surge in the number of reported methodologies for defect quantification or theoretically predict chemical origins. An overview of modeled and measured defect densities in relevant solution processed and polycrystalline perovskite films is illustrated in FIG. 20. For clarity, discussions of defect quantification in FIG. 20 is restricted to polycrystalline films. It should be noted that single crystal perovskites exhibit extremely low defect densities (3.3× 1010 cm−3 for MAPbI3) compared to their polycrystalline counterparts (between 1016-1018 cm−3 for MAPbI3).

In FIG. 20, polycrystalline films defects in MAPbI3 and in double and triple cation perovskites have been quantified using DC analysis such as Hall effect, inverted photocurrent transients and space charge limited current measurements, AC analysis including temperature-dependent capacitance data, and Mott-Schottky analysis, spectroscopic methods such as photothermal deflection, ultraviolet photoelectron, and photoluminescence spectroscopies and others like drift-diffusion simulations or Kelvin probe force microscopy. Additionally, given the wide variation in techniques and sample preparation (devices vs individual films), large differences are reported in defect density numbers as detailed further in Table 1.

Overall, the methods illustrated in FIG. 20 do not distinguish between chemically reactive defects that lead to degradation of polycrystalline films and those that only impact electronic properties. It is believed that once ions such as the halides (I-, Br-) leave the lattice, they propagate through the active layer not only as defects which can increase recombination rate, but also as (redox) active chemical species leading to degradation of films. Interestingly, many of the spectroscopic methods, which allow for correlation with chemical processes, do not exhibit sensitivities for defects below 1016 cm−3. Many of these approaches require a prospective model, which usually only predicts a range of defect densities. If the desire is to directly probe reactive defects for perovskites under operando, characterization techniques are needed to correlate chemical, electronic and physical properties at individual interfaces and in device stacks.

Historically, electrochemical methodologies have demonstrated important insights into hole (electron) injection/extraction events from the valence (conduction) bands of semiconductor materials in operando at a chosen interface of any device stack. On perovskites, direct electrochemical quantification of redox active defect states has been attempted using non-solvents, but clearly suffered from long-term instabilities, phase segregation and ultimately degradation. In the commonly assigned U.S. Provisional Patent Application No. 63/209,339, which has previously been incorporated herein by reference in its entirety, the present inventors demonstrated methods that employ solid electrolyte/ionic liquid (SE/IL) “top contacts” that equilibrate electrochemically with the perovskite to stabilize the film. Together with a reference and counter electrode combination, the perovskite is stressed under device-relevant bias, inducing ion movement and defect reactivity. By introducing a reference electrode, electrochemical potentials for these processes can be correlated to energy levels on the vacuum scale, which allows mapping of the electronic structure and density of states of semiconductive materials including (near-) surface defects. Adding redox probe molecules such as ferrocene/ferricenium (Fc/Fc+) to the SE/IL, allowed the present inventors to probe reactive defect concentrations, as well as the energetics of defect formation and reactivity. It was discovered by the present inventors that a defect density of 2.14×1017 cm−3 showed a Gaussian distribution with a maximum at 5.4 eV (approximately 0.1 eV above the onset in the valence band) for MAPbI3, measured in air.

To further demonstrate the power of electrochemical methodologies for defect quantification, surface defects in defect-rich MAPbI3 and much lower defect density CsFAMA are shown in this disclosure at sensitivities not observed by previous electrical or spectroscopic approaches. For CsFAMA active layers with low defect densities, the number of defects is not resolved using conventional cyclic voltammetry (CV) alone because the defect redox process is obscured by the non-Faradaic double-layer background measured at the electrolyte/perovskite interface. An innovative solution in the form of a linear sweep/pulse voltammetry technique (LSV/DPV) is presented to significantly improve the detection limit by a factor >100. The method of the invention includes a linear sweep voltametric oxidation step to mimic device-relevant electric fields as a direct connection to current-voltage (J/V) behavior in optoelectronic platforms. This combined LSV/DPV approach significantly improved sensitivity, signal-to-noise and energetic resolution for characterization of iodide defects, compared to CV alone. A quantitative analysis of peak charge, as a function of the anodic applied potential in the three-electrode SE/IL platform, enabled defect density determination as low as about 1015 cm−3 at energies 0.1 eV above the valence band, as summarized in FIG. 20 (bottom right). It is believed that this LSV/DPV approach is applicable for the operando characterization of redox-active defect densities and energetics in a broad array of printable opto-electronic device platforms, even for materials with inherently low defect densities, as well as lend itself to defect characterization in relevant device stacks.

### Results and Discussion

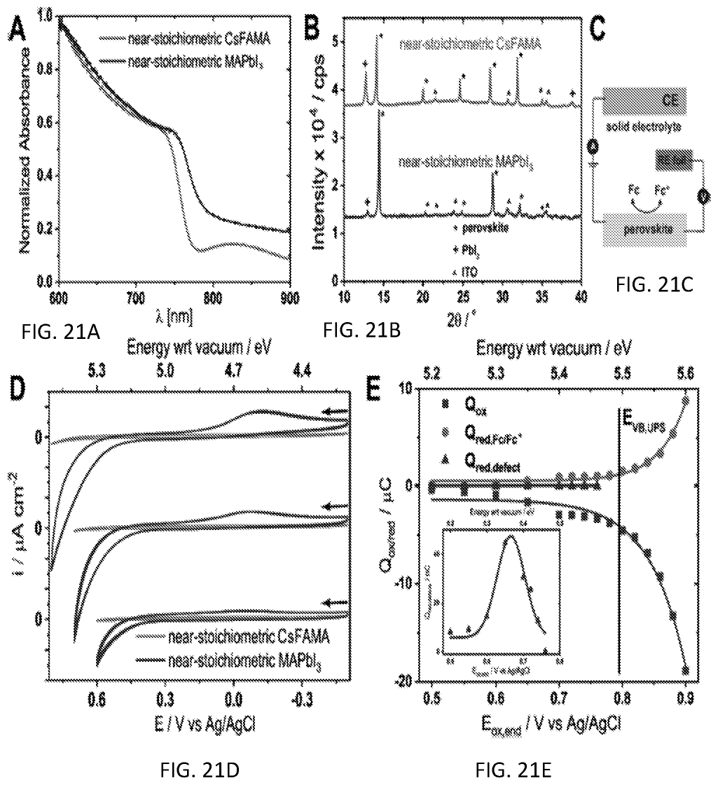

The characterization and distinct electrochemical behavior of a near-stoichiometric MAPbI3 and CsFAMA perovskite film are shown in FIGS. 21A-21E. The UV-vis data in FIG. 21A shows a characteristically sharp onset in absorption around 800 nm explaining the slight difference in optical band gap between 1.57 eV for MAPbI3 and 1.59 eV for CsFAMA. In both films, trace amounts of PbI2 were detected by X-ray diffraction (XRD), shown in FIG. 21B. PbI2 has been demonstrated to slow down non-radiative electron-hole recombination and to give rise to long carrier lifetimes to ultimately improve device performance. These perovskite films were electrochemically characterized using a half-cell material stack shown in FIG. 21C in contact with solid electrolyte (SE), included of a chemically inert polymer with low oxygen transport (poly (vinylidene fluoride)—PVDF) and 1-ethyl-3-methylimidazolium bis(trifluoromethyl-sulfonyl)imide ([EMIM][TFSI]) as an ionic liquid for ionic conductivity, filled with a Fc/Fc+ redox probe in inert conditions (H2O<0.1 ppm; O2<0.1 ppm). The reference electrode (RE, Ag/AgCl foil) was imbedded in the SE and set a reference potential of 0.1 V (versus Fc+/Fc redox couple at −4.8 eV vs vacuum level) and a gold counter electrode (CE). The present inventors have previous shown that the SE specifically probes surface defects at the contact interface without damaging the bulk perovskite structure in air and the added Fc/Fc+ redox probe acts as a mid-gap hole capturing molecule. The cyclic voltammograms in FIG. 21D demonstrate the anodic injection of holes at voltages beyond EVB (E<−5.5 eV: Vapplied>0.8 V), which creates a Fc+ reduction peak around 0 V on the reverse sweep but no clear Fc oxidation peak. Interestingly, no Fc+ reduction is observed until the EVB, onset is surpassed. This is more evident in the CV data reproduced in FIGS. 11, 12 and 13, where potential ranges were individually considered for both perovskites within (a), near (b) and below (c) the valence band. Four regions of interest within these voltammograms are: i) the non-Faradaic charging currents for potentials applied within the perovskite band gap, due to ion motion: ii) an oxidative wave attributed to defect oxidation (at the most positive oxidation potentials, deeper into the valence band region), followed by oxidation of Fc and valence band states, and: iii) two individual waves representing the reversible (partial) defect reduction and reduction of Fc+ formed from the reaction with oxidized defects (e.g. I3-). A fraction of the surface defects is oxidized (and subsequently reduced reversibly), and another sub-population is coupled to the redox chemistry of Fc/Fc+, in a single oxidation peak. Surface defect reduction, and reduction of Fc+ formed on the positive bias sweep, is resolved in the reverse sweep as two reduction peaks, demonstrating the power of this electrochemical methodology.

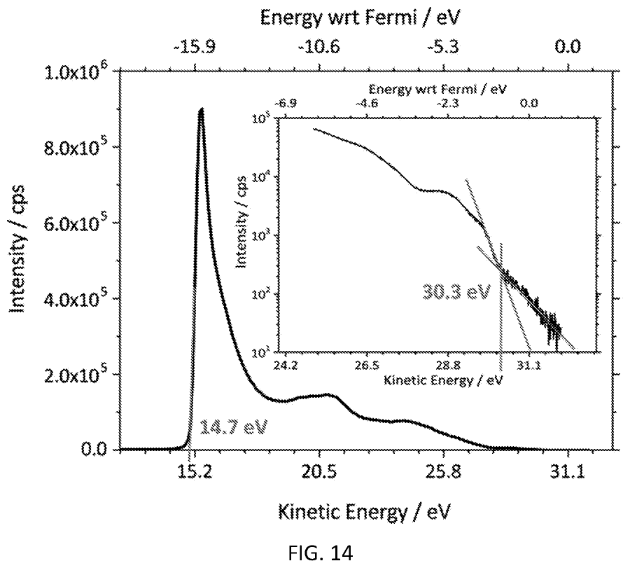

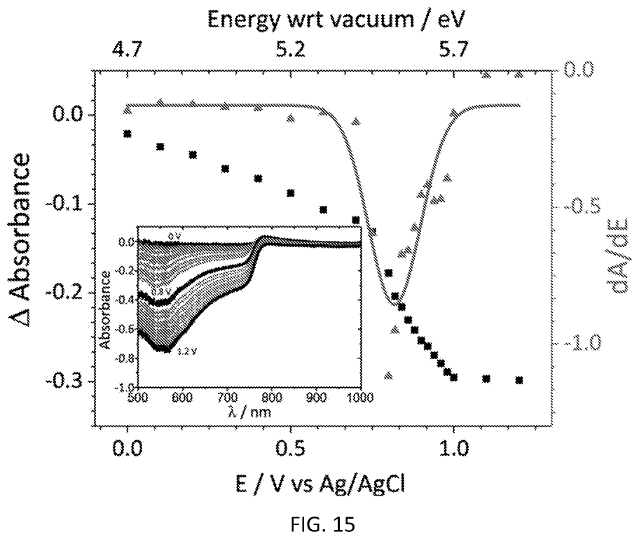

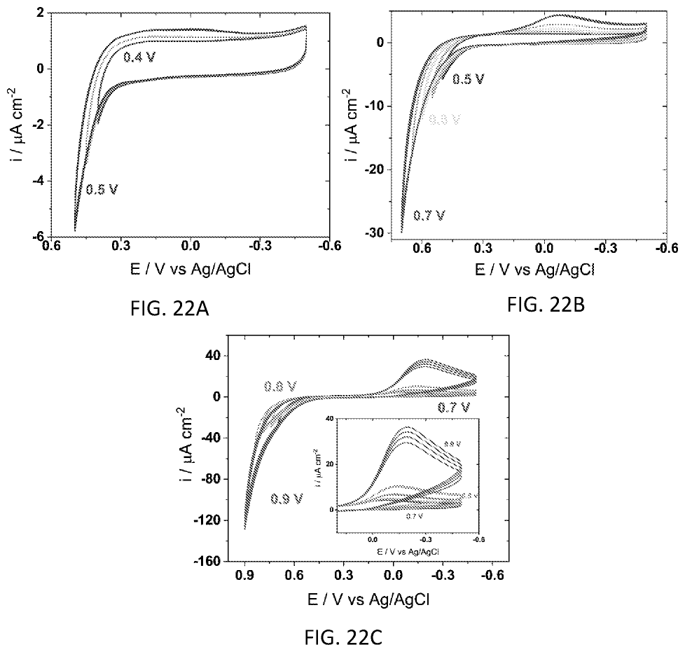

Based on the CVs in FIGS. 22A-22C, the Coulombic energy-dependent defect quantification and band edge determination is given in the charge distributions shown in FIG. 21E. The oxidation (Qox, ▪) and Fc+ reduction (Qred,Fc/Fc+, ●) process follows an exponential increase as a function of potential (y=A exp(−x/t+y0 fit is added) as expected from Marcus-Gerischer theory (E>5.5 eV; V>+0.8 V). The electrochemical data align closely with complementary ultraviolet photoelectron spectroscopy (UPS) data taken for the determination of the valence band of MAPbI3 shown in FIG. 14. Most shallow surface defects are reduced reversibly (Qred,defects, ▴), following a Gaussian distribution (inset) (y=A exp(−1/2 ((x−xc)/2)2)+y0 fit is added) around 5.36 eV (0.1-0.15 eV above EVB) with a calculated defect density of 5.13×1016 cm−3. By comparing the defect density in air and inert atmosphere in FIG. 21E, it can be seen that ambient gasses such as water and O2 cause acid-base and redox reactions at the perovskite interface, which increase the number of surface defects. The fact that these acceptor-type defects lie very close to or within the valence band is known to result in the defect tolerant nature of perovskites.

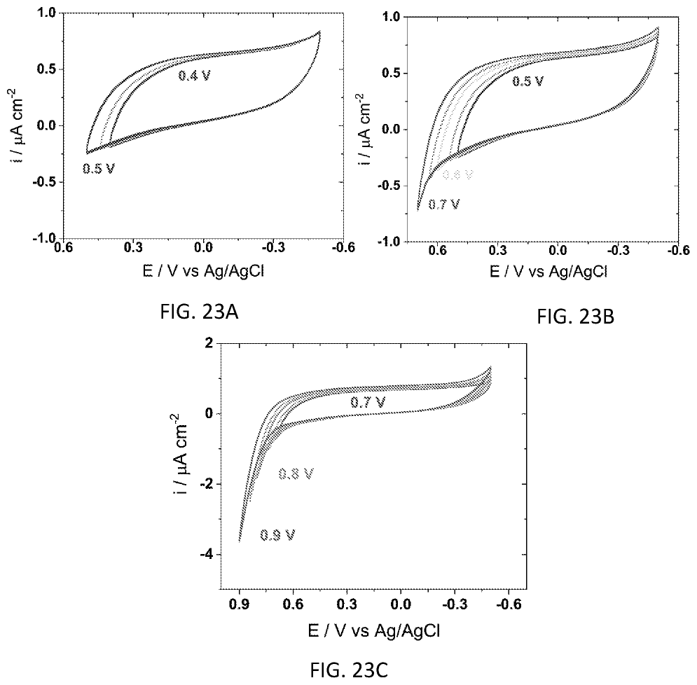

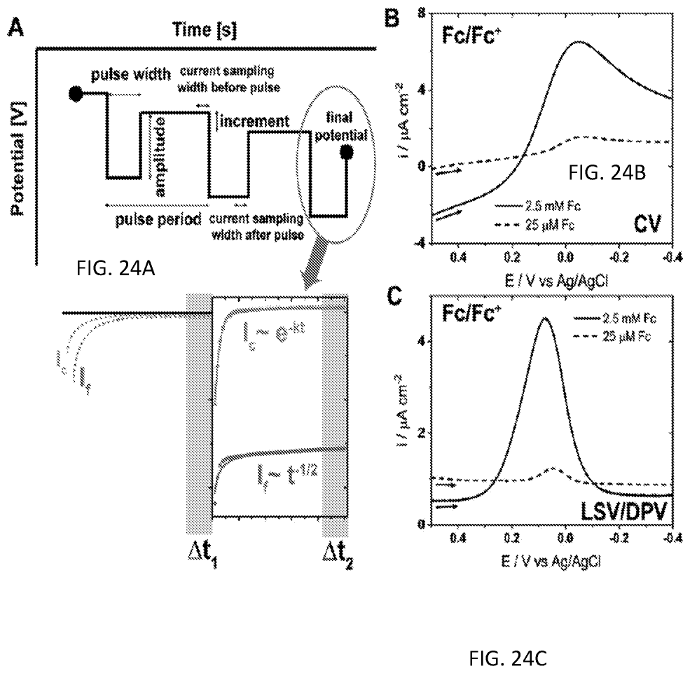

In FIGS. 23A-23C, the oxidation process introduces no Fc+ and/or defect reduction peaks, which suggests that CsFAMA has a much lower intrinsic defect density compared to MAPbI3. However, cyclic voltammetry is commonly used for exploratory purposes, but during the potential sweep, ions in the electrolyte and dipolar molecules of the solvent are oriented at the interface to form a double layer and contribute to an accumulated charge, namely a capacitive or non-Faradaic current. Ion displacement within the perovskite layer also contributes to this type of charging currents. Ultimately, the defect-coupled redox processes are obscured by this non-Faradaic background: therefore, sensitivity was increased by decreasing the background noise. To do this, the difference in time dependence between Faradaic and capacitive currents was used. This time dependency difference can be controlled using potential step techniques such as stair-case and differential pulse voltammetry (or DPV) as illustrated in FIG. 24A. DPV is suitable for distinguishing Faradaic and non-Faradaic events, and has been demonstrated to quantitate electroactive compounds in common solvents down to concentrations of 10-12 cm−3. In DPV, small voltage pulses are superimposed on a linear voltage ramp and currents measured at the end of a potential step are subtracted from currents measured before the step, which provides for enhanced contrast between Faradaic and charging currents, each of which has a unique temporal dependence as indicated in FIG. 24A. Each pulse is considered one measuring point, which means the differential pulse voltammogram consists of discrete ΔIn,dpv data plotted as a function of potential according to the Equation (1):

In2−In1=ΔIn,dpv (I)

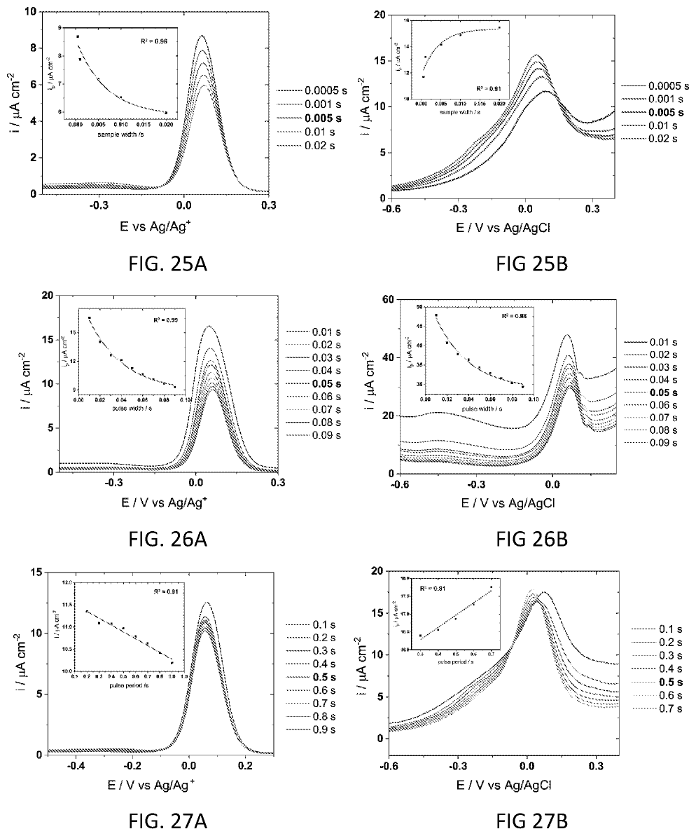

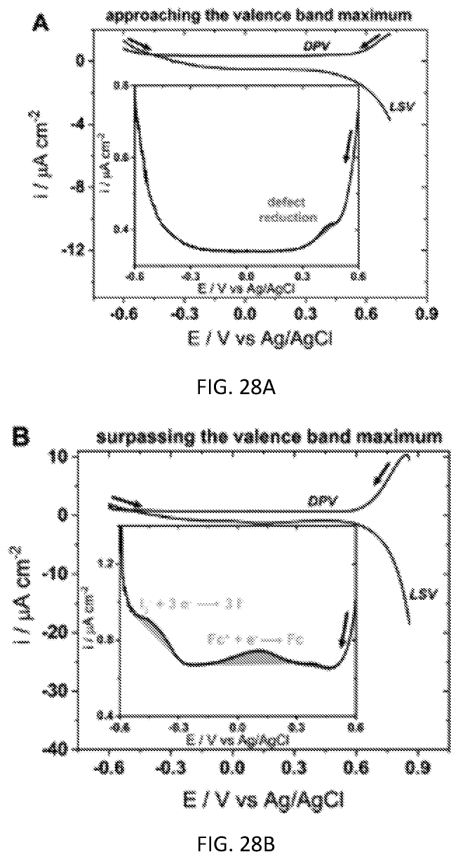

with n being the pulse number. Sampling periods are chosen to allow sufficient time for the non-Faradaic current to decay such that currents arising from Faradaic reactions dominate the DPV signal. Using this combined approach, the perovskite film is first biased to specific potentials using linear sweep voltammetry (LSV) controllably taking the perovskite/SE/IL stack into reverse bias, but avoiding over-oxidation of the material. Subsequently, the second step reduces surface defects in the reverse scan using differential pulse voltammetry (FIG. 24A). The principle is demonstrated for an Fc/Fc+ probe in SE/IL by comparing a CV in FIGS. 24B and 24C. From the curves, it is clear the oxidation process is retained, but during the reduction sweep the capacitive background current is greatly suppressed, and the voltametric peak maximum presents the E1/2 of the Fc/Fc+ redox process. In FIGS. 25A-B, 26A-B, and 27A-B, time parameters for the differential pulse method such as the pulse period, pulse width and sampling width are described and tested for the Fc/Fc+ probe in the SE and 0.1 M TBAPF6/propylene carbonate. FIGS. 25A-B, 26A-B, and 27A-B and related description can serve as a validation for differential pulse voltammetry for the purpose of reducing the non-Faradaic background and improving signal-to-noise and sensitivity.

Next, the LSV/DPV technique was used to characterize defect-poor CsFAMA films in FIGS. 28A and 28B and compared with the results from the CV technique in FIG. 22A-C by similarly choosing the end oxidation potential (or Eox,end) relative to EVB,onset. The LSV oxidation demonstrates an exponential current increase depending on Eox,end comparable with the CV result and consistent with charge extraction from the valence band of CsFAMA, while the reverse DPV curve starts the charge injection process with an exponential decrease. To distinguish the peaks, however, the insets in FIGS. 28A and 28B show the expansion of the reverse DPV curve focused on the relevant mid-gap potential range. These peaks are used in the assessment of mid-gap charge transfer in the perovskite semiconductor due to Fc+ reduction, as well as defect quantification and their electrochemical activity as a function of the anodic potential Eox, end. This means that reduction peaks are identified as either surface defects or redox-active species, while the exponential rise is indicative for the start of the valence band. When approaching EVB,onset in FIG. 28A, only a small defect concentration is detected depending on Eox,end chosen within the band gap of the perovskite. It should be noted that in the DPV scan, as in the CV scan, only surface defects that can be reversibly oxidized and then reduced are detected, while other defects oxidize irreversibly on the positive sweep. Once EVB, onset is surpassed in FIG. 28B, it is believed that mobile iodide anions undergo reversible redox chemistry and simultaneously mid-gap charge transfer starts to gain importance. Through polarization, the iodide anions migrate within the perovskite crystal structure and are able to reach the perovskite/electrolyte interface where they are oxidized to triiodide in the LSV scan and reduced back in the reverse DPV curve as indicated in FIG. 28B. To verify iodide defects are specifically responsible for the redox peak around −0.4 V vs Ag/AgCl, the presence of the iodide/triiodide probe in the SE is characterized using DPV on an ITO electrode. This data confirms that triiodide formation can occur in perovskite solar cells under bias, where iodide anions are oxidized to triiodide at the electron transport layer. When oxidizing the perovskite film, the Fc/Fc+ hole capturing probe present in the electrolyte is pinned to the surface defects and/or valence band states at the perovskite/electrolyte interface. In turn, Fc is oxidized to Fc+ following an outer sphere electron transfer reaction comparable to a redox reaction at a light-absorbing semiconductor electrode in a photoelectrochemical cell. In the reverse DPV scan, the Fc+ formed at the perovskite/electrolyte interface is reduced back to Fc at its known redox potential around 0 V vs Ag/AgCl. This Fc/Fc+ outer sphere electron transfer has the advantage that the reaction happens in the middle of the perovskite's band gap as well as that before, during and after the electron transfer event, Fc and the perovskite remain chemically separate and intact.

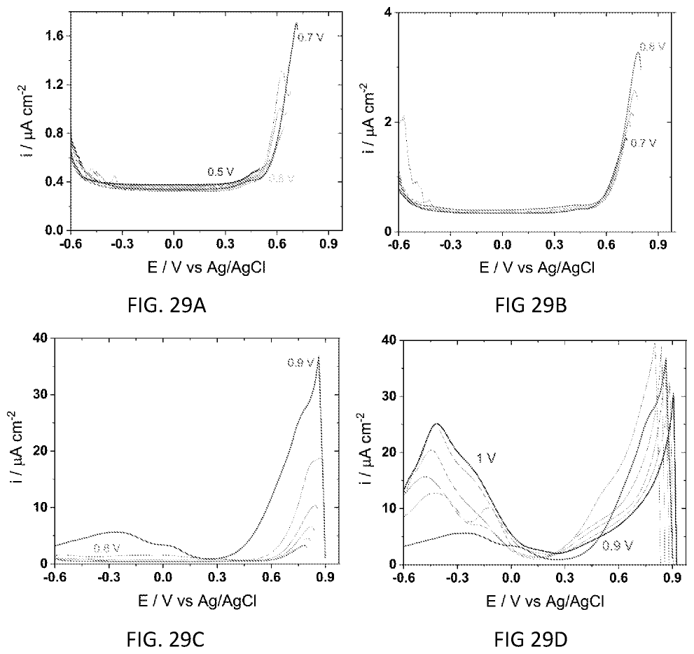

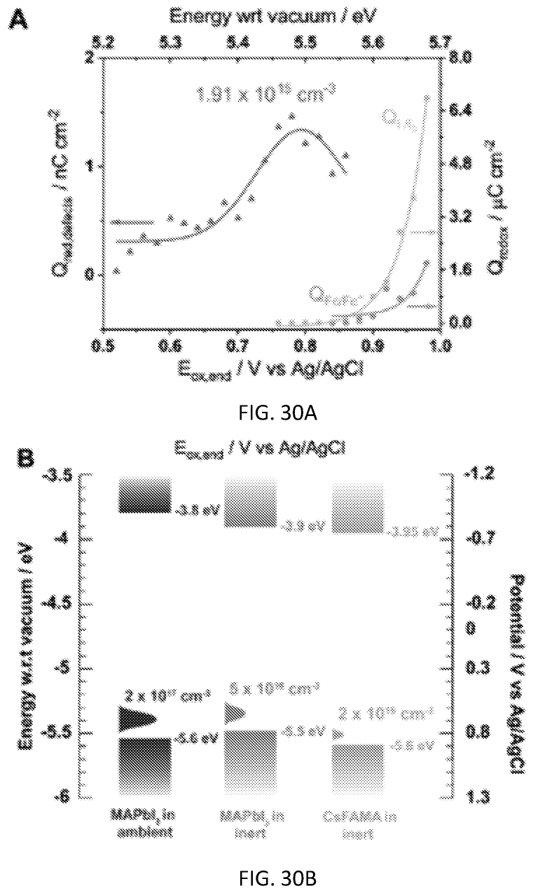

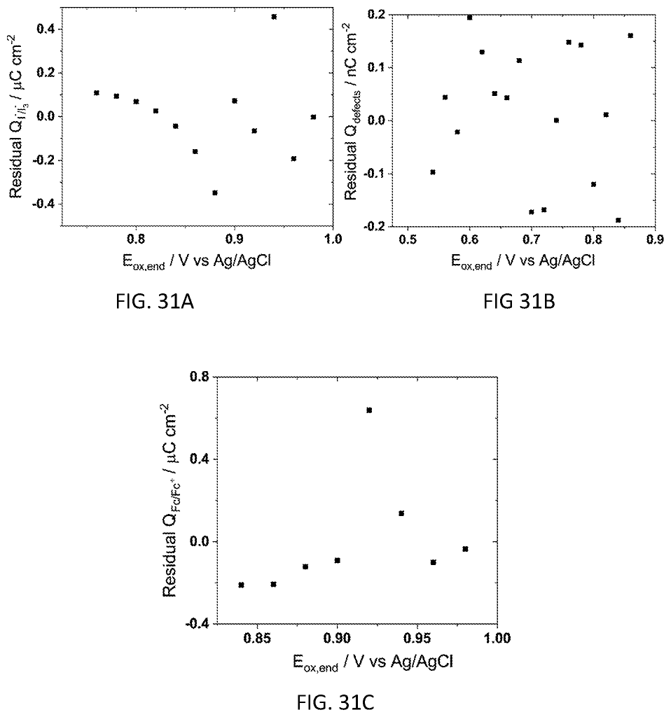

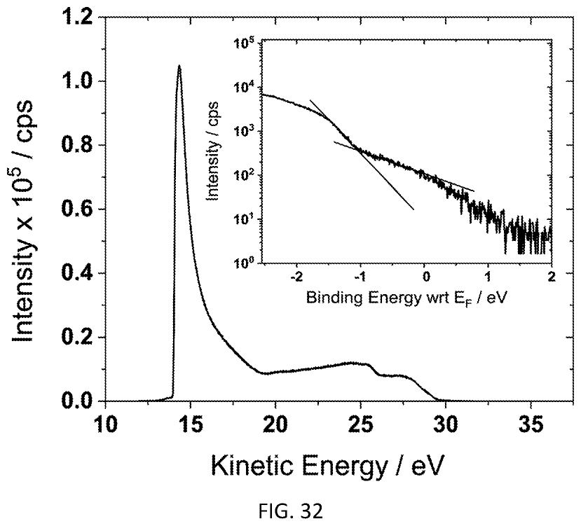

For the defect quantification of CsFAMA, the ΔIn,dpv is monitored by systematically increasing the oxidative window by shifting Eox, end for the LSV/DPV method as seen in FIG. 28. A more complete data set is reproduced in FIGS. 29A-29D for more clarity and individually considers potential ranges within (a), near (b) and above (c and d) the valence band. FIG. 30A shows the Coulombic analysis of all reductive DPV peaks in the data set in FIGS. 29A-29D as a function of Eox,end. The signal-to-noise increase and the decrease in defect density benefits the resolution of the voltametric scan as it allows us to differentiate between the Fc+ and I3− reduction. In FIG. 21D, the peak in the reverse scan is considered to be only Fc+ reduction, but from the DPV it is clear that a combination of both Fc+, but mainly I3− reduction is measured. It is noted that both charge distributions follow an exponential increase with potential by providing a y=A exp(−x/t)+y0 fit for both Fc+ (QFc/Fc+●) and I3− (QI−/I3−, ▪) with the residuals shown in FIG. 31A-CE. This may be explained by the anodical polarization of the perovskite film, which causes I3− anions to move through the crystalline film towards the working electrode. This process is limited by the ion drift velocity within the crystal, which depends on the initial number of defects, the activation energy for ionic exchange, the band structure of the material and the electric field. With applied voltages in the order of a few volts and films a few hundred of nanometers thick, the applied electric field in this device stack can be extremely high, which reduces activation energy to support nonlinear ionic transport that mostly depends on the band structure of the material. For the reduction of Fc+, the exponential distribution is expected from Marcus-Gerischer theory for n-type materials at high anodic overpotentials (E>5.6 eV; V>+0.9 V), which is in good agreement with the UPS data for CsFAMA in FIG. 32. Like in the case of MAPbI3 in FIG. 21E, the reduction of the reversible shallow defects (Qred, defects, ▴) follows a Gaussian distribution for the DPV with the residuals shown in FIG. 31A-C. The distribution demonstrates a maximum at 0.792 V (5.492 eV) just above the EVB with a defect density of 1.91×1015 cm−3.

By shifting the maximum oxidation potential, Eox, end, as shown in FIG. 29A-D, all these individual Faradaic processes can be quantified by calculating the charge under the curve by integrating the current equation (1) to provide the following equation (2).

In FIG. 30A, the calculated charge contributions are plotted as a function of Eox, end revealing very interesting relationships. In FIGS. 31A, 31B and 31C, we show the residuals after fitting Qred, I−/I3− and Qred, Fc/Fc+ with an exponential fit and Qred, defects with a Gaussian distribution. In what follows, we explain the choice for these distributions. The Fc+ and I3− reduction processes follow an exponential increase with potential, consistent with Marcus-Gerischer theory for n-type materials. Shifting Eox, end continuously probes an increased number of defects are immediately reduced back in the reverse scan unless they pin to the Fc+ in the electrolyte. Indeed, generated defects pin to Fc+ causing a drop in the Qred, defects contribution, which eventually disappears, explaining the fitted Gaussian distribution. From the maximum, with the assumption of a dielectric constant of 18, a carrier density of 2.8×1023 m−3, and an estimate of the contact area (0.8 cm2), we calculate a depletion width of 9.23×10−6 cm using equation (3). We note that the carrier density depends on the MAI:PbI2 precursor ratio and varies between 1014 to 1018 cm−3.S16,S17 Finally, we predict a defect density Ndefect of 1.91×1015 cm−3 using equation (4).

In FIG. 30B, electrochemical methodology based on CV has allowed drawing the most complete energy band diagrams to date for MAPbI3 measured in air and in an inert atmosphere, which clearly demonstrates that the presence of O2 and H2O increases the number of defects in a perovskite film. Switching to differential pulse voltammetry is necessary to draw energy diagrams for device-relevant defect-poor perovskites, thereby allowing electrochemically detect defects within the depletion layer (about 20% of the total film thickness) of a triple cation perovskite in order of 1015 cm−3. In other words, this defect density relates to the detection of 10 defects per perovskite crystal face considering 10 nm3 cubic size grains.

This LSV/DPV approach is able to directly detect defects to test the quality of the perovskite, any type of other printable semiconductor film or device stack prior to investing in device optimization. Even in the case of very low defect densities, methods of the invention have been able to demonstrate an unprecedented detection limit (see, FIG. 30A). Because this electrochemical technique is cheap and fast, as well as simple and versatile in terms of cell modification, it is an important asset in in-line defect diagnostics and in-situ testing of defects for quality control during the development of high-rate roll-to-roll manufacturing technologies. Electrochemical methodologies have shown great potential as an attractive tool in the quality control, in-line diagnostics and inspection processes for the transition from laboratory-scale production platforms.

One particular aspect of embodiments of the present invention provides a pulse-based electrochemical methodology for quantification of surface defects in device-relevant defect-poor triple cation perovskite films. In one particular, differential pulse voltammetry significantly improves sensitivity, signal-to-noise ratio and resolution, as well as facilitating data analysis. This method allows identification of both surface defects and/or mobile redox-active species. Methods of the invention provide an easy-to-apply electrochemical tool to screen manufactured perovskite films for optoelectronic applications.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter. All references cited herein are incorporated by reference in their entirety.

As it must be appreciated from the above paragraphs, aspects of embodiments of the present invention include, but not limited to, a method for determining a characteristic of an electronic material, wherein the electronic material includes a metal halide perovskite, an organic semiconductor, a quantum dot, a semiconductor material, a material blend or a device stack, the method comprising:
a) conducting an electrochemical experiment of a composition comprising:
   (i) a working electrode (“WE”) comprising the electronic material;
   (ii) a solid electrolyte (“SE”) comprising a reference electrode (“RE”), wherein the solid electrolyte is removably attached to the working electrode: and
   (iii)) a counter electrode (“CE”) operatively connected to the working electrode, and
b) analyzing the result of the electrochemical experiment to determine a characteristic of the electronic material.

The method further includes the step of conducting a spectroscopic analysis of the composition.

The spectroscopic experiment includes UV-Vis(-NIR) spectroscopy, Fourier Transform Infrared spectroscopy (FTIR), X-ray photoelectron spectroscopy (“XPS”), UV photoelectron spectroscopy (UPS), photoluminescence spectroscopy (PL), photoemission spectroscopy (PES), Raman spectroscopy, wide angle X-ray scattering (WAXS), Deep-level transient spectroscopy (DLTS), or a combination thereof.

The characteristic includes a defect, stability, surface composition, band gap, physical structure, electroactivity, band bending, migration/diffusion processes, charging effects, or a combination thereof.

The solid electrolyte includes a polymer, an ionic liquid, and optionally a redox probe compound.

The polymer includes (i) a chemically inert polymer or (ii) copolymer of a chemically inert polymer with low oxygen transport, high solubility, low molecular weight, high dielectric constant (or high-K), or a combination thereof.

The polymer includes poly (vinylidene fluoride) (PVDF), hexafluoropropylene (“HFP”), tetrafluoroethylene (TFE), poly(ethylene oxide) (PEO), poly(acrylonitrile) (PAN), poly(methyl methacrylate) (PMMA), or a combination thereof.

The ionic liquid includes 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF6]”), 1-Ethyl-3-methylimidazolium tetrafluoroborate (“[EMIM][BF4]”) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

The redox probe compound includes metallocenes (e.g., ferrocene), benzoquinones, (hydro)quinones, phthalocyanines, ruthenium(II)/(III) complexes, or a combination thereof.

The electronic material is a thin film. The electronic material includes a thin film of printable metal halide perovskite.

Other aspects of embodiments of the present invention include a method for reducing defects in an electronic material comprising a metal halide perovskite. The method includes:
(i) attaching a solid electrolyte to a surface of the metal halide perovskite to produce an electronic component:
(ii) subjecting the electronic component to an electrochemical process: and
(iii) removing the solid electrolyte from the electronic component, thereby producing the electronic material with a reduced number of defects.

An electronic device including an electronic material produced using the above method. The electronic device includes a solar cell, a light-emitting diode (“LED”), an X-ray detector, a photodiode, a laser, a transistor, or a battery.

Other aspects of embodiments of the present invention include a composition including:
(i) an electronic component comprising a metal halide perovskite layer, an organic semiconductor, a quantum dot, a semiconductor material, a material blend, or a device stack; and
(ii) a solid electrolyte removably attached to the electronic component, wherein the solid electrolyte includes:
   (a) a polymer,
   (b) an ionic liquid, and
   (c) optionally a redox probe compound.

The polymer includes (i) a chemically inert polymer or (ii) copolymer of a chemically inert polymer with low oxygen transport, high solubility, low molecular weight, high dielectric constant (or high-K), or a combination thereof.

The polymer includes poly (vinylidene fluoride) (PVDF), hexafluoropropylene (“HFP”), tetrafluoroethylene (TFE), poly(ethylene oxide) (PEO), poly(acrylonitrile) (PAN), poly(methyl methacrylate) (PMMA), or a combination thereof.

The ionic liquid includes 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF6]”), 1-Ethyl-3-methylimidazolium tetrafluoroborate (“[EMIM][BF4]”) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

The redox probe compound includes metallocenes (e.g., ferrocene), benzoquinones, (hydro)quinones, phthalocyanines, ruthenium(II)/(III) complexes, or a combination thereof.

Other aspects of embodiments of the present invention include a method for reducing defects in a metal halide perovskite. The method includes:
(i) attaching a solid electrolyte to a surface of the metal halide perovskite, wherein the solid electrolyte includes a polymer, and an ionic liquid: and
(ii) removing the solid electrolyte from the metal halide perovskite, thereby reducing the number of defects in the metal halide perovskite.

Further aspects of embodiments of the present invention include an electrochemical probe (10) for analyzing a semiconductor active layer, the electrochemical probe having a base unit (100): a counter electrode layer (200) having a top surface and a bottom surface, wherein the top surface of the counter electrode layer (200) is attached to the base unit (100) and wherein the counter electrode layer (200) includes a CE electrical connector (204) that is adapted to electrically connecting the counter electrode (200) to a potentiostat (600); a solid electrolyte layer (300) having a top surface and a bottom surface, wherein the top surface of the solid electrolyte layer (300) is attached to the bottom surface of the counter electrode layer (200), wherein the solid electrolyte layer (300) includes an embedded reference electrode (400), wherein the reference electrode (400) includes a RE electrical connector (404) that is adapted to electrically connecting the reference electrode (400) to the potentiostat (600); a probe (500) attached to the base unit (100) and comprising a needle/pushpin/pipette tip (504), wherein the probe (500) further includes a WE electrical connector (508) that is adapted to electrically connecting the probe (500) to the potentiostat (600); wherein when the solid electrolyte layer (300) of the electrochemical probe (10) contacts a semiconductor active layer (700), the needle tip (504) penetrates a semiconductor layer (704) and contacts a conductive substrate (708) thereby forming a closed electrical circuit.

The solid electrolyte layer further includes a conductive salt in an ionic liquid.

The ionic liquid includes a large non-volatile organic cation and a corresponding nonvolatile anion.

The ionic liquid includes 1-ethyl-3-methylimidazolium bis(trifluoromethylsulfonyl)imide (“[EMIM][TFSI]”), 1-butyl-3-methylimidazolium bis(trifluoromethylsulfonyl)imide (“[BMIM][TFSI]”), 1-ethyl-3-methylimidazolium hexafluorophosphate (“[EMIM][PF6]”), 1-Ethyl-3-methylimidazolium tetrafluoroborate (“[EMIM][BF4]”) 1-hexyl-3-methylimidazolium bis(trifluoromethanesulfonyl)-imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

The solid electrolyte layer further includes a molecular redox probe.

The redox probe includes molecules which undergo one-electron oxidations or reductions to create stable products which can be electrochemically quantified, including metallocenes (e.g., ferrocene), benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from the semiconductor active layer, in the dark or under illumination, which can be subsequently quantified using simple electrochemical approaches , or a mixture thereof.

The solid electrolyte layer further includes a polymer.

The polymer includes (i) a chemically inert polymer or (ii) copolymer of a chemically inert polymer with low oxygen transport, high solubility, low molecular weight, high dielectric constant (or high-K), or a combination thereof.

The polymer includes poly(vinylidene fluoride) (PVDF), hexafluoropropylene (“HFP”), tetrafluoroethylene (TFE), poly(ethylene oxide) (PEO), poly(acrylonitrile) (PAN), poly(methyl methacrylate) (PMMA), or a combination thereof.

The counter electrode (200) includes gold, indium tin oxide (ITO), glassy carbon, platinum, or any highly conductive (i.e., conductivity of at least 4000 S/cm) metal, metal oxide or polymer conductor, or a combination thereof.

The reference electrode (400) includes Ag/AgCl, platinum, silver, a stable metallic or polymeric conductor that is capable of establishing electrochemical equilibrium with the ionic liquid/solid electrolyte material, or a combination thereof.

An other aspect of embodiments of the present invention include a method for analyzing a semiconductor active layer. The method includes contacting an electrical probe (10) to a semiconductor (704) surface of the semiconductor active layer (700), wherein the step of contacting the electrical probe (10) to the semiconductor (704) surface results in a needle tip (504) penetrating the semiconductor layer (704) and contacting a conductive substrate (708) thereby forming a closed electrical circuit: and determining current flow as a function of potential using a potentiostat (600) to analyze at least one characteristic of the semiconductor active layer (700).

The characteristic includes surface composition and deviations from expected stochiometries, defect energetics, defect concentrations, band edge energies (conduction and valence band energy), band gap, migration/diffusion processes of reactive species, current or voltage excursions due to displacement of ions or reactions at interfaces (charging effects), degradation mechanisms, and changes in physical structure at nanometer to micron length scales that correlate with these characteristics, or a combination thereof.

The semiconductor (704) includes inorganic semiconductors such as Si, Ge, CdTe, Ga, As, GaxAly AszNzz compositions, metal oxide semiconductors such as TiO2, ZnO and NiOx, p- and n-doped semiconductors, conducting and semiconducting polymers such as substituted polythiophenes, quantum dots, semiconductor nanomaterials, donor/acceptor blends of semiconducting polymers, or a hybrid organic-inorganic metal halide perovskite.

The hybrid organic-inorganic metal halide perovskite includes a combination of organic and inorganic cations, including single, double and triple cation perovskites, with additives designed to control microstructure and enhance performance and stability, and to control crystalline polytypes, including conversion from three-dimensional to two-dimensional motives, or a combination thereof in the form of material blends or multilayered stacks.

The conductive substrate includes indium tin oxide (ITO), fluorine- or antimony-doped tin oxide (FTO or ATO), ZnO and its compound oxides such as ZnITO (ZITO), or a combination thereof.

The step of determining current flow as a function of potential includes linear sweep voltammetry, differential pulse voltammetry, an electrochemical technique which uses transient voltage or current pulse on micro-second to second time scales to enhance contrast between detection of Faradaic and non-Faradaic (ion displacement) electrochemical events, including impedance spectroscopies, or a combination thereof.

The method includes an oxidation step during the step of determining current flow as a function of potential includes linear sweep voltammetry.

The method includes a reduction step during the step of determining current flow as a function of potential includes differential pulse voltammetry or related techniques which rely upon voltage or current pulses to cause transient electrochemical events.

The semiconductor active layer is analyzed during a manufacturing process.

The manufacturing process includes a roll-to-roll, or blade coating manufacturing process.

The method also includes measuring a current flow using a linear sweep voltammetry during one of a reduction or an oxidation step and measuring a current flow using a differential pulse voltammetry during an opposite or reverse step.

The semiconductor active layer (700) includes inorganic semiconductors such as Si, Ge, CdTe, Ga, As, GaxAlyAszNzz compositions, metal oxide semiconductors such as TiO2, ZnO and NiOx, p- and n-doped semiconductors, conducting and semiconducting polymers such as substituted polythiophenes, quantum dots, semiconductor nanomaterials, donor/acceptor blends of semiconducting polymers, or a hybrid organic-inorganic metal halide perovskite.

The hybrid organic-inorganic metal halide perovskite includes a combination of organic and inorganic cations, including single, double and triple cation perovskites, with additives designed to control microstructure and enhance performance and stability, and to control crystalline polytypes, including conversion from three-dimensional to two-dimensional motives, or a combination thereof in the form of material blends or multilayered stacks.

### REFERENCES

Hofft, O.; Bahr, S.; Himmerlich, M.; Krischok, S.; Schaefer, J. A.; Kempter, V. Electronic Structure of the Surface of the Ionic Liquid [EMIM][Tf₂N] Studied by Metastable Impact Electron Spectroscopy (MIES), UPS, and XPS. Langmuir 2006, 22, 7120-7123.

Juarez-Perez, E. J.; Ono, L. K.; Maeda, M.; Jiang, Y.; Hawash, Z.; Qi, Y. Photodecomposition and Thermal Decomposition in Methylammonium Halide Lead Perovskites and Inferred Design Principles to Increase Photovoltaic Device Stability. Journal of Materials Chemistry A 2018, 6, 9604-9612.

Tanuma, S.; Powell, C. J.; Penn, D. R. Calculations of Electron Inelastic Mean Free Paths. IX. Data for 41 Elemental Solids over the 50 eV to 30 keV range. Surface and Interface Analysis 2011, 43, 689-713.

Seah, M.P .: Dench W.A., Quantitative Electron Spectroscopy of Surfaces. Surface and Interface Analysis 1979, 1, 2.

Chen, Y.; Zhou, H. Defects Chemistry in High-Efficiency and Stable Perovskite Solar Cells. Journal of Applied Physics 2020, 128.

Boschloo, G.; Hagfeldt, A. Characteristics of the Iodide/Triiodide Redox Mediator in Dye-Sensitized Solar Cells. Accounts of Chemical Research 2009, 42, 1819-1826.

Bentley, C. L.; Bond, A. M.; Hollenkamp, A. F.; Mahon, P. J.; Zhang, J. Electrochemistry of Iodide, Iodine, and Iodine Monochloride in Chloride Containing Nonhaloaluminate Ionic Liquids. Analytical Chemistry 2016, 88, 1915-1921.

Wang, X.; Stanbury, D. M. Oxidation of Iodide by a Series of Fe(III) Complexes in Acetonitrile. Inorganic Chemistry 2006, 45, 3415-3423.

Roy, J. C.; Hamill, W. H.; Williams, R. R. Diffusion Kinetics of the Photochemical and Thermal Dissociation-Recombination of Trihalide Ions. Journal of the American Chemical Society 1955, 77, 2953-2957.

Bertoluzzi, L.; Lopez-Varo, P.; Jiménez Tejada, J. A.; Bisquert, J. Charge Transfer Processes at the Semiconductor/Electrolyte Interface for Solar Fuel Production; Insight from Impedance Spectroscopy. Journal of Materials Chemistry A 2016, 4, 2873-2879.

Even, J.; Pedesseau, L.; Jancu, J. M.; Katan, C. Importance of Spin-orbit Coupling in Hybrid Organic/Inorganic Perovskites for Photovoltaic Applications. Journal of Physical Chemistry Letters 2013, 4, 2999-3005.

Xiong, L.; Guo, Y.; Wen, J.; Liu, H.; Yang, G.; Qin, P.; Fang, G. Review on the Application of SnO₂ in Perovskite Solar Cells. Advanced Functional Materials 2018, 28, 1-18.

Samiee, M.; Konduri, S.; Ganapathy, B.; Kottokkaran, R.; Abbas, H. A.; Kitahara, A.; Joshi, P.; Zhang, L.; Noack, M.; Dalal, V. Defect Density and Dielectric Constant in Perovskite Solar Cells. Applied Physics Letters 2014, 105

Zhao, T.; Shi, W.; Xi, J.; Wang, D.; Shuai, Z. Intrinsic and Extrinsic Charge Transport in CH₃NH₃PbI₃ Perovskites Predicted from First Principles. Scientific Reports 2016, 7, 1-8.

Wang, Q.; Shao, Y.; Xie, H.; Lyu, L.; Liu, X.; Gao, Y.; Huang, J. Qualifying Composition Dependent p and n Self-doping in CH₃NH₃PbI₃. Applied Physics Letters 2014, 105.

DeQuilettes, D. W.; Vorpahl, S. M.; Stranks, S. D.; Nagaoka, H.; Eperon, G. E.; Ziffer, M. E.; Snaith, H. J.; Ginger, D. S. Impact of Microstructure on Local Carrier Lifetime in Perovskite Solar Cells. Science 2015, 348, 683-686.

Bi, C.; Shao, Y.; Yuan, Y.; Xiao, Z.; Wang, C.; Gao, Y.; Huang, J. Understanding the Formation and Evolution of Interdiffusion Grown Organolead Halide Perovskite Thin Films by Thermal Annealing. Journal of Materials Chemistry A 2014, 2, 18508-18514.

The foregoing discussion of the invention has been presented for purposes of illustration and description. The foregoing is not intended to limit the invention to the form or forms disclosed herein. Although the description of the invention has included description of one or more embodiments and certain variations and modifications, other variations and modifications are within the scope of the invention, e.g., as may be within the skill and knowledge of those in the art, after understanding the present disclosure. It is intended to obtain rights which include alternative embodiments to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter. All references cited herein are incorporated by reference in their entirety.

1. An apparatus for characterizing a substructure of a semiconductor device, comprising:
a potentiostat;
a counter electrode electrically connected to said potentiostat;
a solid electrolyte attached to a surface of said counter electrode at a first surface of said solid electrolyte, said solid electrolyte comprising a second surface opposite said first surface;
a reference electrode embedded within at least a portion of said solid electrolyte and electrically connected to said potentiostat; and
a probe electrically connected to said potentiostat,
wherein said substructure of said semiconductor device comprises a device electrode and at least one layer of material formed on said device electrode, said at least one layer of material comprising a layer of a semiconductor,
wherein said probe is configured to be electrically connected to said device electrode to provide a working electrode,
wherein said counter electrode and said solid electrolyte are configured to contact said second surface of said solid electrolyte with at least a portion of a surface of said substructure of said semiconductor device, and
wherein said solid electrolyte comprises a solid porous material and an ionic liquid disposed within said solid porous material.

2. The apparatus of claim 1, wherein said porous material is a polymer.

3. The apparatus of claim 1, wherein said solid electrolyte further comprises a redox probe compound.

4. The apparatus of claim 2, wherein said polymer comprises at least one of a chemically inert polymer or a copolymer of a chemically inert polymer with low oxygen transport, high solubility, low molecular weight, high dielectric constant, or a combination thereof.

5. The apparatus of claim 2, wherein said polymer comprises poly(vinylidene fluoride) (PVDF), hexafluoropropylene (HFP), tetrafluoroethylene (TFE), poly(ethylene oxide) (PEO), poly(acrylonitrile) (PAN), poly(methyl methacrylate) (PMMA), or a combination thereof.

6. The apparatus of claim 2, wherein said ionic liquid comprises 1-ethyl-3-methylimidazolium bis(trifluoromethylsulfonyl)imide ([EMIM][TFSI]), 1-butyl-3-methylimidazolium bis(trifluoromethylsulfonyl)imide ([BMIM][TFSI]), 1-ethyl-3-methylimidazolium hexafluorophosphate ([EMIM][PF6]), 1-Ethyl-3-methylimidazolium tetrafluoroborate ([EMIM][BF4]) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

7. The apparatus of claim 3, wherein said redox probe compound comprises metallocenes, benzoquinones, (hydro)quinones, phthalocyanines, ruthenium(II)/(III) complexes, or a combination thereof.

8. The apparatus of claim 3, wherein said redox probe comprises molecules which undergo one-electron oxidations or reductions to create stable products which can be electrochemically quantified, including metallocenes, benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from the layer of the semiconductor, in the dark or under illumination, which can be subsequently quantified using simple electrochemical approaches, or a mixture thereof.

9. The apparatus of claim 1, wherein said reference electrode comprises Ag/AgCl, platinum, silver, a stable metallic or polymeric conductor that is capable of establishing electrochemical equilibrium with the ionic liquid/solid porous material, or a combination thereof.

10. The apparatus of claim 1, wherein said probe is further configured to be disconnected from said device electrode and subsequently electrically reconnected to said device electrode to provide a working electrode, and
wherein said counter electrode and said solid electrolyte are configured so that said second surface of said solid electrolyte can be removed from said portion of said surface of said substructure of said semiconductor device and brought into contact with at least a second portion of a second surface of said substructure of said semiconductor device.

11. A method of characterizing a substructure of a semiconductor device, comprising:
contacting at least a portion of a surface of said substructure of said semiconductor device with a second surface of a solid electrolyte, said solid electrolyte comprising a first surface opposite said second surface and comprising a porous solid material,
wherein of said solid electrolyte is attached to a counter electrode,
wherein said solid electrolyte comprises a reference electrode embedded therein, and
wherein said semiconductor device comprises a working electrode;
applying a voltage to said reference electrode;
measuring a current between said counter electrode and said working electrode; and
characterizing said substructure of said semiconductor device based at least partially on said applied voltage and said measured current.

12. The method of claim 11, wherein said porous material is a polymer.

13. The method of claim 11, wherein said solid electrolyte further comprises a redox probe compound.

14. The method of claim 12, wherein said polymer comprises at least one of a chemically inert polymer or a copolymer of a chemically inert polymer with low oxygen transport, high solubility, low molecular weight, high dielectric constant, or a combination thereof.

15. The method of claim 12, wherein said polymer comprises poly(vinylidene fluoride) (PVDF), hexafluoropropylene (HFP), tetrafluoroethylene (TFE), poly(ethylene oxide) (PEO), poly(acrylonitrile) (PAN), poly(methyl methacrylate) (PMMA), or a combination thereof.

16. The method of claim 12, wherein said solid electrolyte further comprises a ionic liquid comprises 1-ethyl-3-methylimidazolium bis(trifluoromethylsulfonyl)imide ([EMIM][TFSI]), 1-butyl-3-methylimidazolium bis(trifluoromethylsulfonyl)imide ([BMIM][TFSI]), 1-ethyl-3-methylimidazolium hexafluorophosphate ([EMIM][PF6]), 1-Ethyl-3-methylimidazolium tetrafluoroborate ([EMIM][BF4]) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

17. The method of claim 13, wherein said redox probe compound comprises metallocenes, benzoquinones, (hydro)quinones, phthalocyanines, ruthenium(II)/(III) complexes, or a combination thereof.

18. The method of claim 13, wherein said redox probe comprises molecules which undergo one-electron oxidations or reductions to create stable products which can be electrochemically quantified, including metallocenes, benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from a semiconductor active layer, in the dark or under illumination, which can be subsequently quantified using simple electrochemical approaches, or a mixture thereof.

19. The method of claim 11, wherein said reference electrode comprises Ag/AgCl, platinum, silver, a stable metallic or polymeric conductor that is capable of establishing electrochemical equilibrium with the ionic liquid/solid porous material, or a combination thereof.

20. The method of claim 11, wherein a probe is further configured to be disconnected from said device electrode and subsequently electrically reconnected to said device electrode to provide the working electrode, and
wherein said counter electrode and said solid electrolyte are configured so that said second surface of said solid electrolyte can be removed from said portion of said surface of said substructure of said semiconductor device and brought into contact with at least a second portion of a second surface of said substructure of said semiconductor device.

21. A semiconductor production system, comprising:
a semiconductor depositing system arranged to deposit at least one of a semiconductor layer or a precursor to a semiconductor layer onto a device subassembly comprising a device substrate to produce a substructure of a semiconductor device; and
an apparatus for characterizing said substructure of said semiconductor device, said apparatus comprising:
a potentiostat;
a counter electrode electrically connected to said potentiostat;
a solid electrolyte attached to a surface of said counter electrode at a first surface of said solid electrolyte, said solid electrolyte comprising a second surface opposite said first surface;
a reference electrode embedded within at least a portion of said solid electrolyte and electrically connected to said potentiostat; and
a probe electrically connected to said potentiostat,
wherein said semiconductor device comprises a device electrode and at least one layer of material formed on said device electrode, said at least one layer of material comprising a layer of a semiconductor,
wherein said probe is configured to be electrically connected to said device electrode to provide a working electrode,
wherein said counter electrode and said solid electrolyte are configured so that said second surface of said solid electrolyte can be brought into contact with at least a portion of a surface of said substructure of said semiconductor device, and
wherein said solid electrolyte comprises a solid porous material and an ionic liquid disposed within said solid porous material.

22. The system of claim 21, wherein said porous material is a polymer.

23. The system of claim 21, wherein said solid electrolyte further comprises a redox probe compound.

24. The system of claim 22, wherein said polymer comprises at least one of a chemically inert polymer or a copolymer of a chemically inert polymer with low oxygen transport, high solubility, low molecular weight, high dielectric constant, or a combination thereof.

25. The system of claim 22, wherein said polymer comprises poly(vinylidene fluoride) (PVDF), hexafluoropropylene (HFP), tetrafluoroethylene (TFE), poly(ethylene oxide) (PEO), poly(acrylonitrile) (PAN), poly(methyl methacrylate) (PMMA), or a combination thereof.

26. The system of claim 22, wherein said ionic liquid comprises 1-ethyl-3-methylimidazolium bis(trifluoromethylsulfonyl)imide ([EMIM][TFSI]), 1-butyl-3-methylimidazolium bis(trifluoromethylsulfonyl)imide ([BMIM][TFSI]), 1-ethyl-3-methylimidazolium hexafluorophosphate ([EMIM][PF6]), 1-Ethyl-3-methylimidazolium tetrafluoroborate ([EMIM][BF4]) 1-hexyl-3-methylimidazolium bis(trifluoromethanesulfonyl)imide ([HMIM][TFSI]), N-methyl-N-propylpiperidinium bis(trifluoromethanesulfonyl)imide ([PPI3][TFSI]), N,N,N-trimethyl-N-propylammonium bis(trifluoromethanesulfonyl) imide ([TMPA][TFSI]), or a combination thereof.

27. The system of claim 23, wherein said redox probe compound comprises metallocenes, benzoquinones, (hydro)quinones, phthalocyanines, ruthenium(II)/(III) complexes, or a combination thereof.

28. The system of claim 23, wherein said redox probe comprises molecules which undergo one-electron oxidations or reductions to create stable products which can be electrochemically quantified, including metallocenes, benzoquinones, (hydro)quinones, phthalocyanines, ruthenium(II)/(III) complexes, and any organic or organometallic complex with extended conjugation which forms stable cation/cation radical, anion/anion radical products as a result of charge transfer to/from the layer of the semiconductor, in the dark or under illumination, which can be subsequently quantified using simple electrochemical approaches, or a mixture thereof.

29. The system of claim 21, wherein said reference electrode comprises Ag/AgCl, platinum, silver, a stable metallic or polymeric conductor that is capable of establishing electrochemical equilibrium with the ionic liquid/solid porous material, or a combination thereof.

30. The system of claim 21, wherein said probe is further configured to be disconnected from said device electrode and subsequently electrically reconnected to said device electrode to provide a working electrode, and
wherein said counter electrode and said solid electrolyte are configured so that said second surface of said solid electrolyte can be removed from said portion of said surface of said substructure of said semiconductor device and brought into contact with at least a second portion of a second surface of said substructure of said semiconductor device.

31. (canceled)

32. (canceled)
